(19) United States
(12) Patent Application Publication
(10) Pub. No.: US 2026/0020294 A1
(43) Pub. Date: Jan. 15, 2026

(54) SEMICONDUCTOR DEVICE

(71) Applicant: ROHM CO., LTD., Kyoto-shi (JP)

(72) Inventor: Nobutaka OI, Kyoto-shi (JP)

(73) Assignee: ROHM CO., LTD., Kyoto-shi (JP)

(21) Appl. No.: 19/337,946

(22) Filed: Sep. 24, 2025

Related U.S. Application Data
(63) Continuation of application No. PCT/JP2024/008808, filed on Mar. 7, 2024.

(30) Foreign Application Priority Data
Mar. 30, 2023 (JP) 2023-056392

(51) Int. Cl. H10D 62/10; H10D 12/00

(52) U.S. Cl. CPC H10D 62/107; H10D 12/415; H10D 12/481

(57) ABSTRACT

A semiconductor device includes a drift region of a first conductivity type that is formed in an interior of a chip and a plurality of FLRs that are formed in a surface layer portion of a first principal surface in an outer peripheral region such as to surround an active region, each FLR has FLR curve portions, each being of a curve shape in plan view shape, in four corner portions, each FLR has FLR rectilinear portions, each being of a rectilinear shape in plan view shape, between the four corner portions, and each FLR curve portion has a double-diffused structure including a first diffusion region at an inner side and a second diffusion region at an outer side that is lower in impurity concentration of a second conductivity type than the first diffusion region.

### CROSS-REFERENCE TO RELATED APPLICATIONS

The present application is a continuation application of PCT Application No. PCT/JP2024/008808, filed on Mar. 7, 2024, which corresponds to Japanese Patent Application No. 2023-056392 filed on Mar. 30, 2023, with the Japan Patent Office, and the entire disclosure of these applications are incorporated herein by reference.

### TECHNICAL FIELD

The present disclosure relates to a semiconductor device.

### BACKGROUND ART

A semiconductor device including an active region and an edge termination region that surrounds the active region is disclosed in Japanese Patent Application Publication No. 2022-882. An IGBT and a free wheeling diode are formed in the active region. A plurality of guard rings (field limiting rings (FLRs)) and field plate electrodes (FLR electrodes) that are respectively disposed on the plurality of guard rings and are each electrically connected to the corresponding guard ring are formed in the edge termination region.

### BRIEF DESCRIPTION OF DRAWINGS

FIG. 1 is a plan view showing a semiconductor device according to a preferred embodiment.

FIG. 2 is a plan view showing a layout of a first principal surface.

FIG. 3 is an enlarged plan view showing an active region and an outer peripheral region.

FIG. 4 is a sectional view taken along line IV-IV shown in FIG. 3.

FIG. 5 is a sectional view taken along line V-V shown in FIG. 3.

FIG. 6 is a sectional view taken along line VI-VI shown in FIG. 3.

FIG. 7 is an enlarged plan view showing the active regions and a boundary region.

FIG. 8 is a sectional view taken along line VIII-VIII shown in FIG. 7.

FIG. 9 is a sectional view taken along line IX-IX shown in FIG. 7.

FIG. 10A is a sectional view taken along line XA-XA shown in FIG. 1.

FIG. 10B is a sectional view taken along line XB-XB shown in FIG. 1.

FIG. 10C is a sectional view showing a modification example of an FLR curve portion and is a sectional view corresponding to the sectional view of FIG. 10B.

FIG. 11 is an enlarged plan view showing a pad region.

FIG. 12 is an enlarged plan view showing a gate resistive structure shown in FIG. 11.

FIG. 13 is an enlarged plan view showing an inner portion of the gate resistive structure shown in FIG. 12.

FIG. 14 is an enlarged plan view showing one end portion of the gate resistive structure shown in FIG. 12.

FIG. 15 is an enlarged plan view showing another end portion of the gate resistive structure shown in FIG. 12.

FIG. 16 is a sectional view taken along line XVI-XVI shown in FIG. 13.

FIG. 17 is a sectional view taken along line XVII-XVII shown in FIG. 13.

FIG. 18 is a sectional view taken along line XVIII-XVIII shown in FIG. 13.

FIG. 19 is a sectional view taken along line XIX-XIX shown in FIG. 13.

FIG. 20 is a sectional view taken along line XX-XX shown in FIG. 14.

FIG. 21 is a sectional view taken along line XXI-XXI shown in FIG. 15.

FIG. 22 is a sectional view taken along line XXII-XXII shown in FIG. 12.

FIG. 23 is a plan view showing a layout of a resistive film, a gate electrode film, and a gate wiring film.

FIG. 24 is an electric circuit diagram showing the gate resistive structure, a gate terminal electrode, and a gate wiring electrode.

FIG. 25 is an illustrative plan view for describing a modification example of FLRs, FLR electrodes, and FLR connection electrodes and is an illustrative plan view mainly showing a structure of a second corner portion of the outer peripheral region.

FIG. 26 is an illustrative sectional view taken along line XXVI-XXVI shown in FIG. 25.

FIG. 27 is an illustrative plan view for describing a modification example of the FLR curve portion of FIG. 25.

FIG. 28 is an illustrative plan view for describing another modification example of the FLRs, the FLR electrodes, and the FLR connection electrodes and is an illustrative plan view mainly showing the structure of the second corner portion of the outer peripheral region.

FIG. 29 is an illustrative plan view for describing a modification example of the FLR curve portion of FIG. 28.

FIG. 30A is an illustrative plan view showing a structure of a first corner portion in yet another modification example of the FLRs, the FLR electrodes, and the FLR connection electrodes.

FIG. 30B is an illustrative plan view showing the structure of the second corner portion in the same modification example as FIG. 30A.

FIG. 30C is an illustrative plan view showing a structure of a third corner portion in the same modification example as FIG. 30A.

FIG. 30D is an illustrative plan view showing a structure of a fourth corner portion in the same modification example as FIG. 30A.

FIG. 31 is an illustrative sectional view taken along line XXXI-XXXI shown in FIG. 30B.

FIG. 32 is an illustrative plan view for describing a modification example of the FLR curve portion of FIG. 30B.

### DESCRIPTION OF EMBODIMENTS

Hereinafter, a preferred embodiment shall be described in detail with reference to attached drawings. The attached drawings are schematic views and are not drawn precisely, and scales and the like thereof do not always match. Also, identical reference signs are given to corresponding structures among the attached drawings and duplicate descriptions thereof shall be omitted or simplified. For the structures whose description have been omitted or simplified, the description given before the omission or simplification shall apply.

When the wording “substantially equal” is used in a description in which a comparison target is present, the wording includes a numerical value (shape) equal to a numerical value (shape) of the comparison target and also includes numerical errors (shape errors) in a range of ±10% on a basis of the numerical value (shape) of the comparison target. Although the wordings “first,” “second,” “third,” etc., are used with the embodiments, these are symbols attached to names of respective structures in order to clarify the order of description and are not attached with an intention of restricting the names of the respective structures.

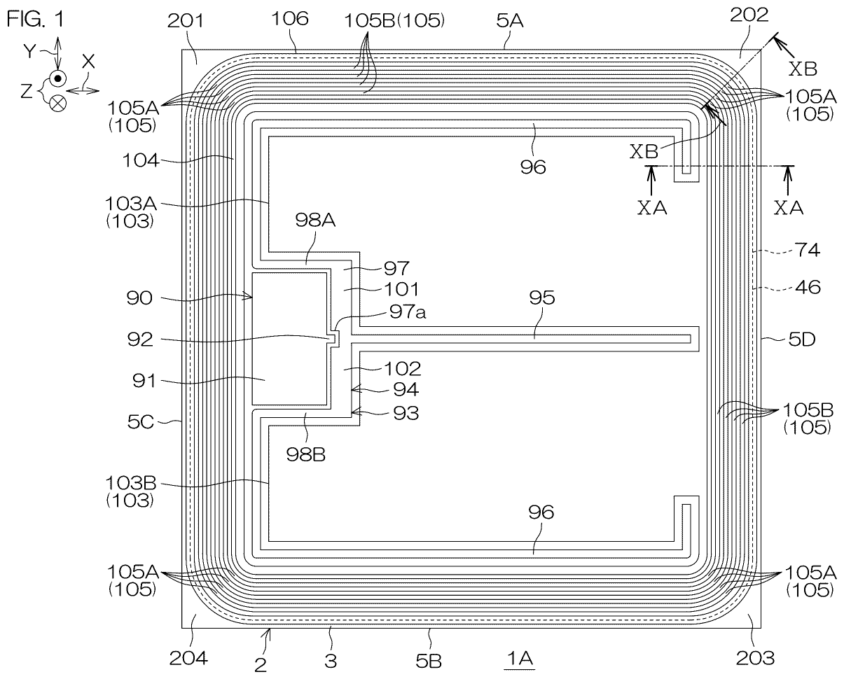

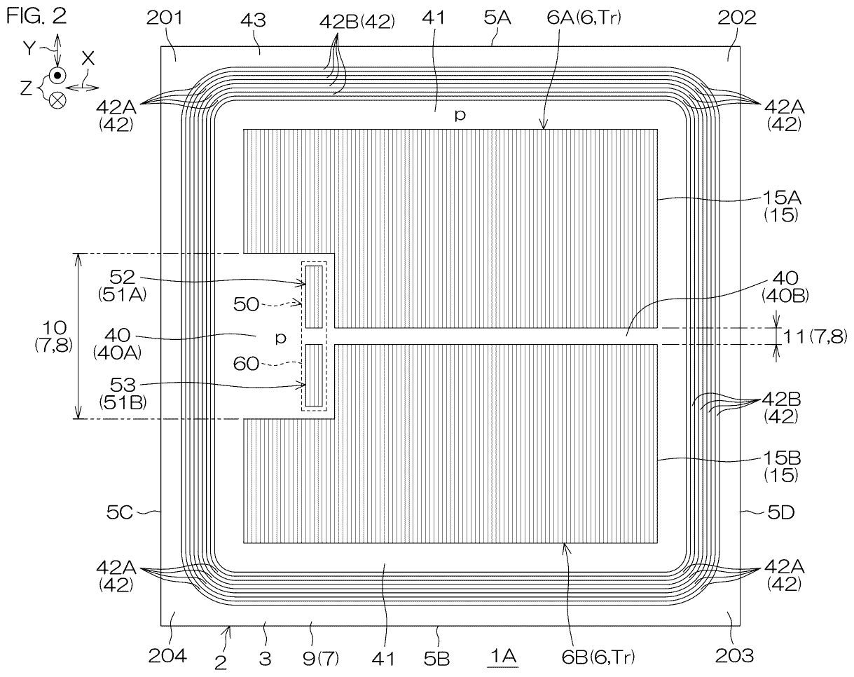

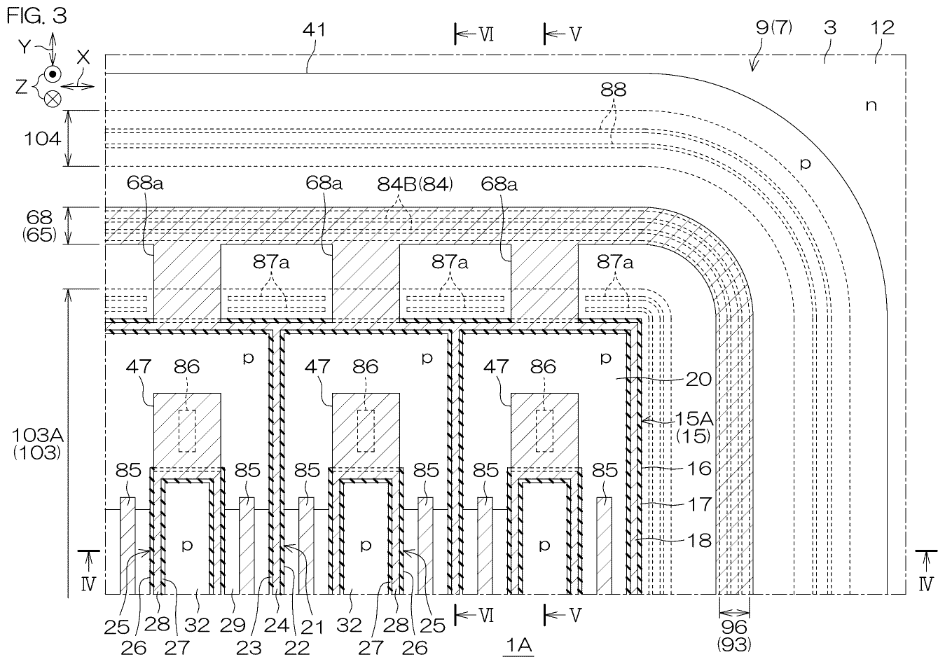

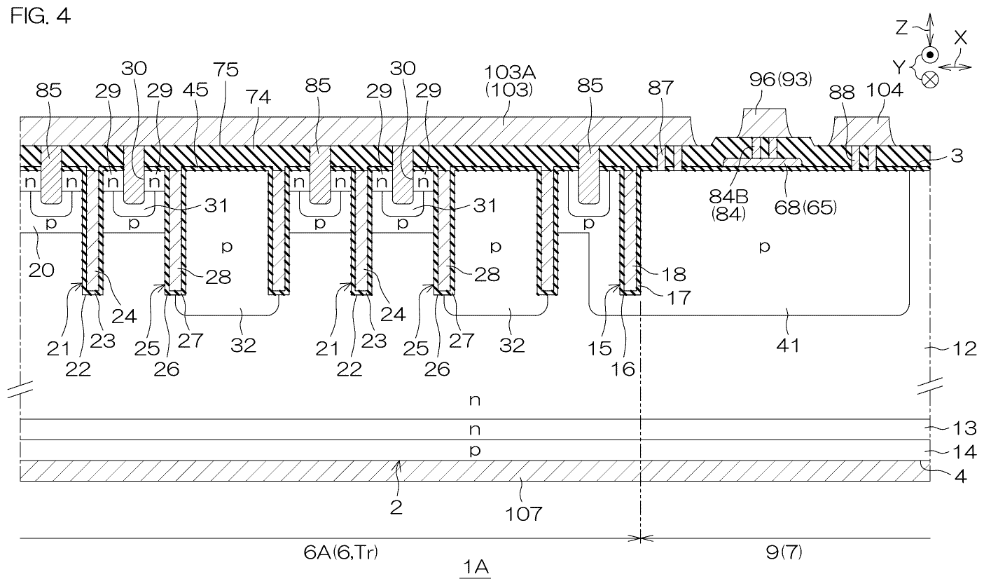

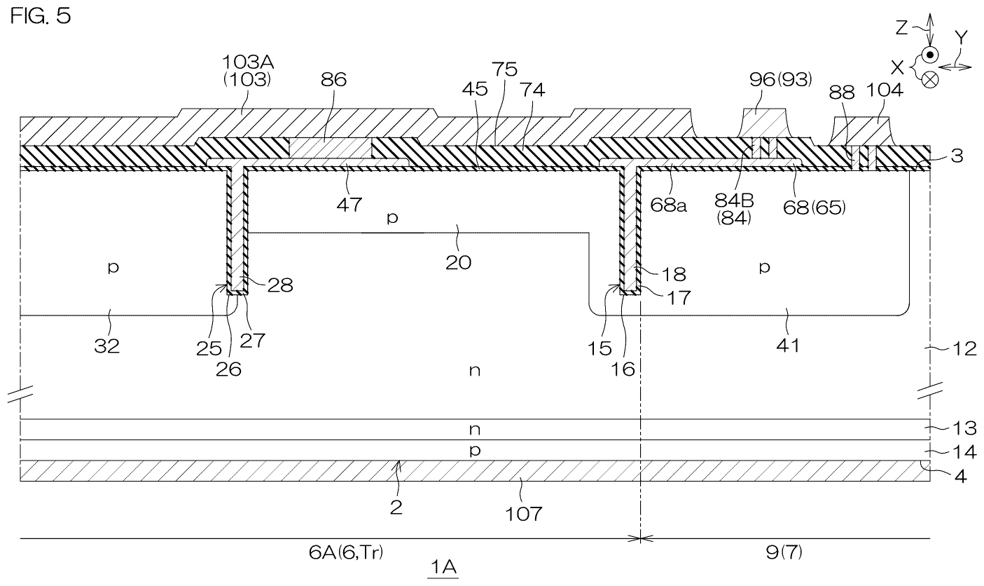

FIG. 1 is a plan view showing a semiconductor device 1A according to a preferred embodiment. FIG. 2 is a plan view showing a layout of a first principal surface 3. FIG. 3 is an enlarged plan view showing an active region 6 and an outer peripheral region 9. FIG. 4 is a cross-sectional view taken along line IV-IV shown in FIG. 3. FIG. 5 is a cross-sectional view taken along line V-V shown in FIG. 3.

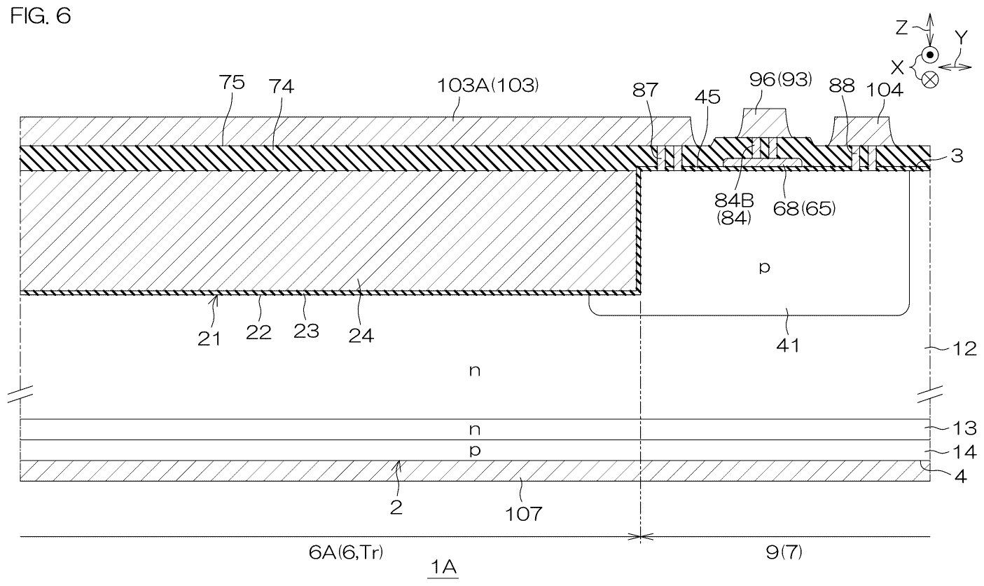

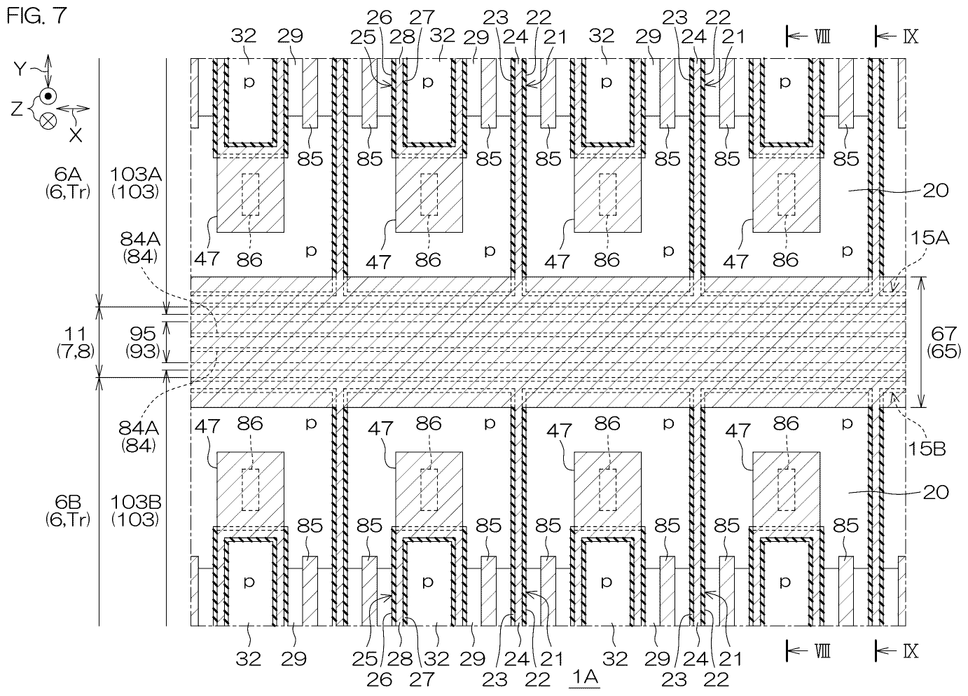

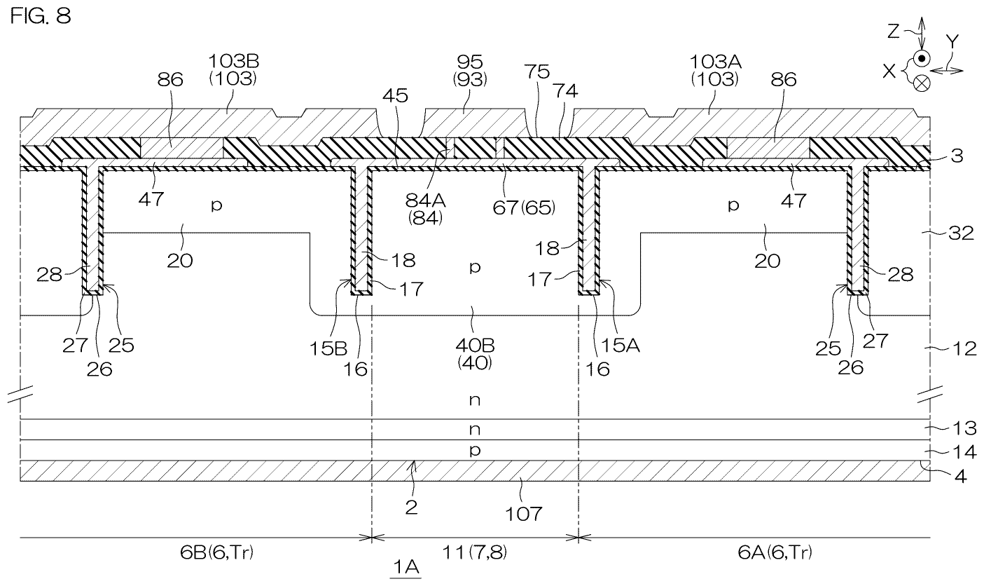

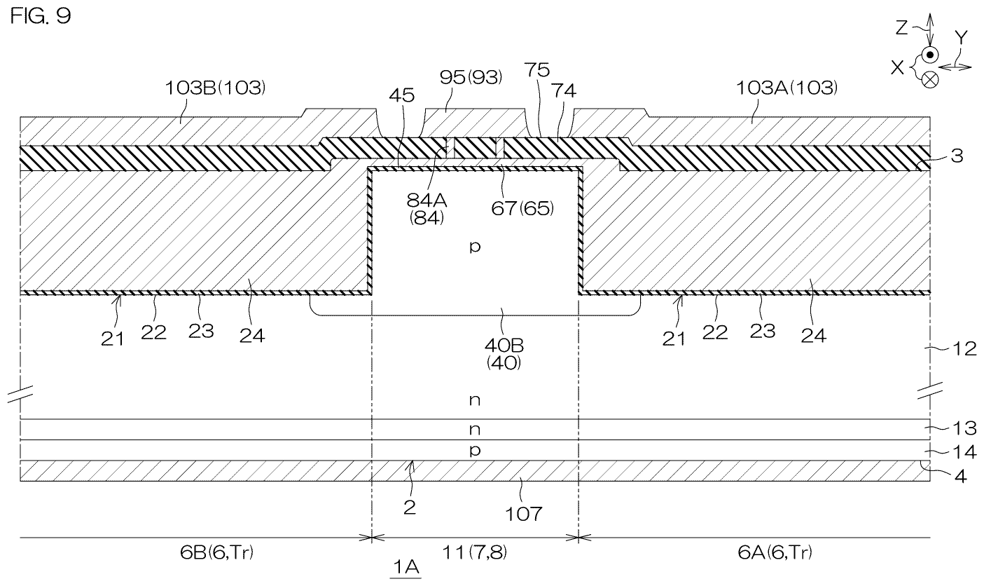

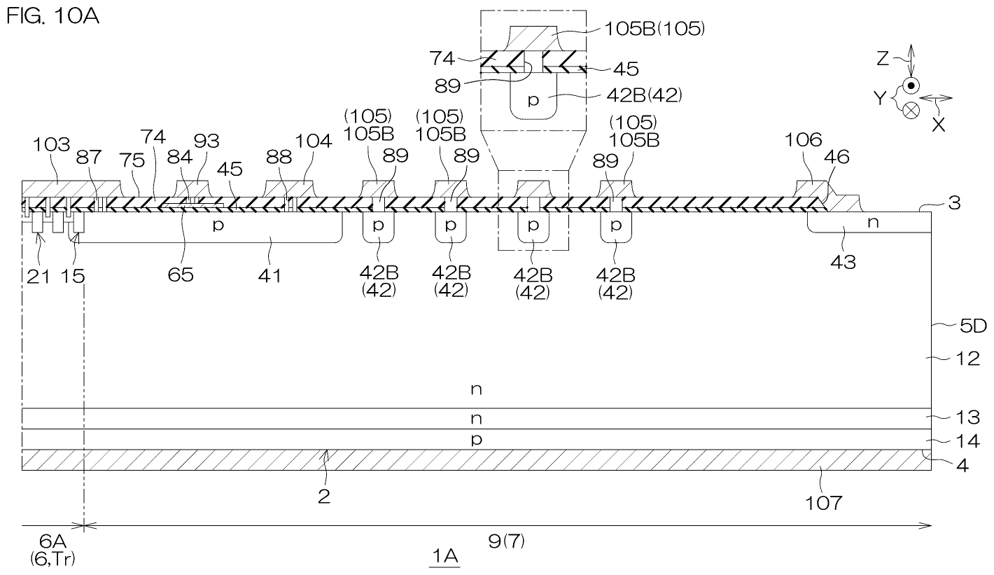

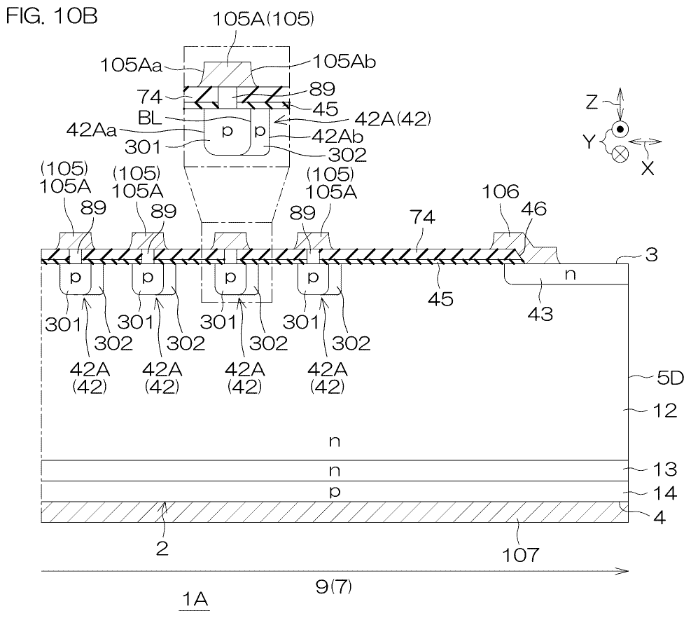

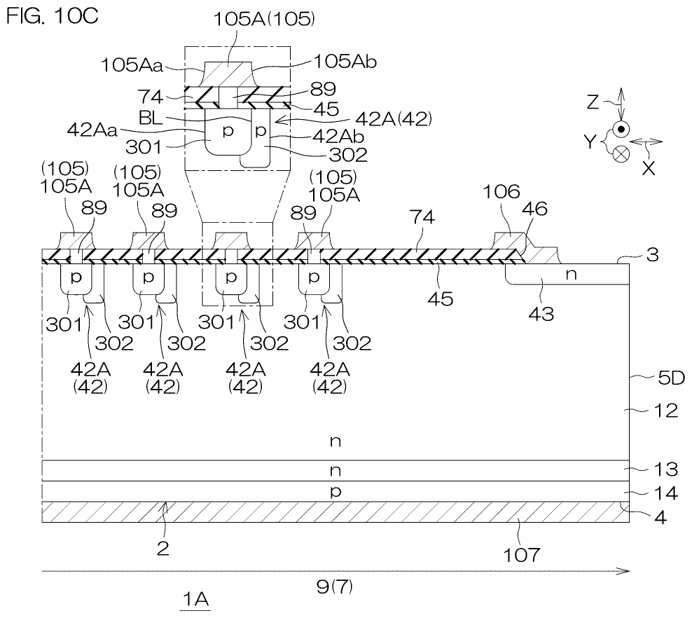

FIG. 6 is a cross-sectional view taken along line VI-VI shown in FIG. 3. FIG. 7 is an enlarged plan view showing the active regions 6 and a boundary region 8. FIG. 8 is a cross-sectional view taken along line VIII-VIII shown in FIG. 7. FIG. 9 is a cross-sectional view taken along line IX-IX shown in FIG. 7. FIG. 10A is a sectional view taken along line XA-XA shown in FIG. 1. FIG. 10B is a sectional view taken along line XB-XB shown in FIG. 1.

The semiconductor device 1A is an IGBT semiconductor device including an IGBT (insulated gate bipolar transistor). With reference to FIG. 1 to FIG. 10B, the semiconductor device 1A includes a chip 2 having a hexahedral shape (specifically, a rectangular parallelepiped shape). The chip 2 may be referred to as a “semiconductor chip.” In this embodiment, the chip 2 has a single layer structure constituted of a silicon monocrystal substrate (semiconductor substrate).

The chip 2 has the first principal surface 3 on one side, a second principal surface 4 on another side, and first to fourth side surfaces 5A to 5D connecting the first principal surface 3 and the second principal surface 4. The first principal surface 3 and the second principal surface 4 are each formed in a quadrangle shape in plan view as viewed in a normal direction Z thereto (hereinafter, simply referred to as “plan view”). The normal direction Z is also a thickness direction of the chip 2. The first principal surface 3 has a quadrangle shape in plan view.

The first side surface 5A and the second side surface 5B extend in a first direction X along the first principal surface 3 and face each other in a second direction Y intersecting the first direction X along the first principal surface 3. Specifically, the second direction Y is orthogonal to the first direction X. The third side surface 5C and the fourth side surface 5D extend in the second direction Y and face each other in the first direction X.

The semiconductor device 1A includes a plurality of the active regions 6 provided at an interval in the first principal surface 3. The plurality of active regions 6 include a first active region 6A and a second active region 6B. The first active region 6A is provided in a region at the first side surface 5A side with respect to a straight line crossing a center of the first principal surface 3 in the first direction X. The second active region 6B is provided in a region at the second side surface 5B side with respect to the straight line crossing the center of the first principal surface 3 in the first direction X. In this embodiment, each of the active regions 6 is formed in a polygonal shape having four sides parallel to a peripheral edge of the chip 2 in plan view. A planar shape of each of the active regions 6 is arbitrary.

An element structure is formed in each active region 6. In this embodiment, the element structure includes an IGBT structure Tr (a transistor structure). The element structure may include a transistor other than an IGBT. The element structure may include the IGBT structure and a free wheel diode (FWD) structure that is connected in antiparallel to the IGBT structure as illustrated in Japanese Patent Application Publication No. 2022-882.

The semiconductor device 1A includes a non-active region 7 provided in a region outside the plurality of active regions 6 in the first principal surface 3. The non-active region 7 includes the boundary region 8 and the outer peripheral region 9. The boundary region 8 is provided in a band shape extending in the first direction X in a region between the first active region 6A and the second active region 6B. In this embodiment, the boundary region 8 is positioned on the straight line crossing the center of the first principal surface 3 in the first direction X.

The boundary region 8 includes a pad region 10 having a comparatively large width in the second direction Y and a street region 11 having a width smaller than the width of the pad region 10 in the second direction Y. The pad region 10 may be referred to as a “first boundary region” or a “wide region.” The street region 11 may be referred to as a “second boundary region,” a “line region,” or a “narrow region.”

The pad region 10 is provided in a region at one side (the third side surface 5C side) in the first direction X. In this embodiment, the pad region 10 is positioned on the straight line crossing the center of the first principal surface 3 in the first direction X in plan view and is provided in a quadrangle shape in a vicinity of a central portion of the third side surface 5C. The street region 11 is provided in a region at another side (the fourth side surface 5D side) in the first direction X with respect to the pad region 10. In this embodiment, the street region 11 is led out in a band shape from the pad region 10 toward the fourth side surface 5D side and is positioned on the straight line crossing the center of the first principal surface 3 in the first direction X.

The outer peripheral region 9 is provided in a peripheral edge portion of the chip 2 such as to surround the plurality of active regions 6 entirely. The outer peripheral region 9 is provided in an annular shape (in this embodiment, a quadrangle annular shape) extending along the peripheral edge (the first to fourth side surfaces 5A to 5D) of the chip 2. The outer peripheral region 9 is connected to the pad region 10 at one side (the third side surface 5C side) of the first principal surface 3 and is connected to the street region 11 at the other side (the fourth side surface 5D side) of the first principal surface 3.

The outer peripheral region 9 has four corner portions 201, 202, 203, and 204. The corner portion 201 (hereinafter referred to as the “first corner portion 201”) is a corner portion that is sandwiched by the first side surface 5A and the third side surface 5C in plan view. The corner portion 202 (hereinafter referred to as the “second corner portion 202”) is a corner portion that is sandwiched by the first side surface 5A and the fourth side surface 5D in plan view.

The corner portion 203 (hereinafter referred to as the “third corner portion 203”) is a corner portion that is sandwiched by the fourth side surface 5D and the second side surface 5B in plan view. The corner portion 204 (hereinafter referred to as the “fourth corner portion 204”) is a corner portion that is sandwiched by the second side surface 5B and the third side surface 5C in plan view.

The semiconductor device 1A includes a drift region 12 of an n-type (a first conductivity type) that is formed in an interior of the chip 2. The drift region 12 is formed in an entire region of the interior of the chip 2. In this embodiment, the chip 2 is constituted of a semiconductor substrate of the n-type (a semiconductor chip of the n-type), and the drift region 12 is formed using the n-type chip 2.

The semiconductor device 1A includes a buffer region 13 of the n-type formed in a surface layer portion of the second principal surface 4. In this embodiment, the buffer region 13 is formed in a layer shape extending along the second principal surface 4 in an entire region of the second principal surface 4. The buffer region 13 has a higher n-type impurity concentration than the drift region 12. The presence or absence of the buffer region 13 is arbitrary, and an embodiment without the buffer region 13 may be adopted instead.

The semiconductor device 1A includes a collector region 14 of a p-type (a second conductivity type) formed in a surface layer portion of the second principal surface 4. The collector region 14 is formed in a surface layer portion of the buffer region 13 at the second principal surface 4 side. In this embodiment, the collector region 14 is formed in a layer shape extending along the second principal surface 4 in the entire region of the second principal surface 4. The collector region 14 is exposed from the second principal surface 4 and portions of the first to fourth side surfaces 5A to 5D.

The semiconductor device 1A includes a plurality of trench separation structures 15 formed in the first principal surface 3 such as to demarcate the plurality of active regions 6. A gate potential is applied to the plurality of trench separation structures 15. The trench separation structures 15 may be referred to as “trench gate separating structures” or “trench gate connection structures.” The plurality of trench separation structures 15 include a first trench separation structure 15A at the first active region 6A side and a second trench separation structure 15B at the second active region 6B side.

The first trench separation structure 15A surrounds the first active region 6A and demarcates the first active region 6A from the boundary region 8 and the outer peripheral region 9. In this embodiment, the first trench separation structure 15A is formed in a polygonal annular shape having four sides parallel to the peripheral edge of the chip 2 in plan view. The first trench separation structure 15A has portions that are bent such as to demarcate the pad region 10 and the street region 11 of the boundary region 8 in plan view.

The second trench separation structure 15B surrounds the second active region 6B and demarcates the second active region 6B from the boundary region 8 and the outer peripheral region 9. In this embodiment, the second trench separation structure 15B is formed in a polygonal annular shape having four sides parallel to the peripheral edge of the chip 2 in plan view. The second trench separation structure 15B has portions that are bent such as to demarcate the pad region 10 and the street region 11 of the boundary region 8 in plan view.

Each trench separation structure 15 preferably has a width less than the width of the street region 11. The width of the trench separation structure 15 is a width in a direction orthogonal to a direction in which the trench separation structure 15 extends. The width of the trench separation structure 15 may be not less than 0.1 μm and not more than 2.5 μm. The width of the trench separation structure 15 is preferably not less than 0.3 μm and not more than 1 μm. The width of the trench separation structure 15 is particularly preferably not less than 0.4 μm and not more than 0.7 μm. The trench separation structure 15 may have a depth of not less than 1 μm and not more than 20 μm. The depth of the trench separation structure 15 is preferably not less than 4 μm and not more than 10 μm.

Hereinafter, the arrangement of a single trench separation structure 15 shall be described. The trench separation structure 15 includes a separation trench 16, a separation insulation film 17, and a separation embedded electrode 18. The separation trench 16 is formed in the first principal surface 3 and demarcates a wall surface of the trench separation structure 15. The separation insulation film 17 covers a wall surface of the separation trench 16 in a film shape. The separation insulation film 17 may include at least one among a silicon oxide film, a silicon nitride film, and an aluminum oxide film.

The separation insulation film 17 preferably has a single layer structure constituted of a single insulating film. The separation insulation film 17 particularly preferably includes a silicon oxide film that is constituted of an oxide of the chip 2. The separation embedded electrode 18 is embedded in the separation trench 16 with the separation insulation film 17 interposed therebetween. The separation embedded electrode 18 may contain a conductive polysilicon. The gate potential is applied to the separation embedded electrode 18.

The semiconductor device 1A includes the IGBT structure Tr (transistor structure) formed in each active region 6. The IGBT structure Tr is not formed in the non-active region 7. Since the arrangement (the arrangement of the IGBT structure Tr) at the second active region 6B side is substantially the same as the arrangement (the arrangement of the IGBT structure Tr) at the first active region 6A side, the arrangement at the first active region 6A side is described below. In this embodiment, the arrangement at the second active region 6B side is line-symmetric to the arrangement at the first active region 6A side across the boundary region 8. The description of the structure at the first active region 6A side is applied to the description of the structure at the second active region 6B side, which shall be omitted.

In this embodiment, the n-type impurity concentration of the drift region 12 varies such as to decrease gradually from a surface of the drift region 12 at the first principal surface 3 side toward a surface at the second principal surface 4 side. The n-type impurity concentration of the drift region 12 is preferably, for example, not less than 1.0×10¹³ cm⁻³ and not more than 1.0×10¹⁵ cm⁻³.

The semiconductor device 1A includes a channel region 20 of the p-type formed in the surface layer portion of the first principal surface 3 in the first active region 6A. The channel region 20 may be referred to as a “body region” or a “base region.” The channel region 20 is formed in a surface layer portion of the drift region 12 at the first principal surface 3 side. The channel region 20 extends in a layer shape along the first principal surface 3 and is connected to an inner peripheral wall of the trench separation structure 15. The channel region 20 is formed shallower than the trench separation structure 15 and has a bottom portion positioned further to the first principal surface 3 side than the bottom wall of the trench separation structure 15. The bottom portion of the channel region 20 is preferably positioned closer to the first principal surface 3 than the depth range intermediate portion of the trench separation structure 15. A thickness of the channel region 20 may be approximately 1 μm.

The semiconductor device 1A includes a plurality of first trench structures 21 formed in the first principal surface 3 in the first active region 6A. The gate potential is applied to the plurality of first trench structures 21. The first trench structures 21 may be referred to as “trench gate structures.” The plurality of first trench structures 21 penetrate through the channel region 20 such as to reach the drift region 12. The plurality of first trench structures 21 are aligned at intervals in the first direction X in plan view and are each formed in a band shape extending in the second direction Y. That is, the plurality of first trench structures 21 are aligned in a stripe shape extending in the second direction Y.

In regard to a length direction (the second direction Y), each of the first trench structures 21 has one end portion at the boundary region 8 side and another end portion at the outer peripheral region 9 side. The one end portions and the other end portions of the plurality of first trench structures 21 are mechanically and electrically connected to the trench separation structure 15. That is, the plurality of first trench structures 21, together with the trench separation structure 15, constitute a single trench structure of ladder shape. A connection portion of a first trench structure 21 and the trench separation structure 15 may be considered to be a part of the trench separation structure 15 and/or a part of the first trench structure 21.

Each of the intervals between the plurality of first trench structures 21 is preferably less than the width of the street region 11. A width of each first trench structure 21 is preferably less than the width of the street region 11. The width of the first trench structure 21 is a width in a direction orthogonal to the direction in which the first trench structure 21 extends. The width of the first trench structure 21 may be not less than 0.1 μm and not more than 2.5 μm. The width of the first trench structure 21 is preferably not less than 0.3 μm and not more than 1 μm.

The width of the first trench structure 21 is particularly preferably not less than 0.4 μm and not more than 0.7 μm. The width of the first trench structure 21 is preferably substantially equal to the width of the trench separation structure 15. The first trench structure 21 may have a depth of not less than 1 μm and not more than 20 μm. The depth of the first trench structure 21 is preferably not less than 4 μm and not more than 10 μm. The depth of the first trench structure 21 is preferably substantially equal to the depth of the trench separation structure 15.

Hereinafter, the arrangement of a single first trench structure 21 shall be described. The first trench structure 21 includes a first trench 22, a first insulating film 23, and a first embedded electrode 24. The first trench 22 is formed in the first principal surface 3 and demarcates a wall surface of the first trench structure 21. In this embodiment, the first trench 22 is in communication with the separation trench 16 at both end portions in the second direction Y. Specifically, a side wall of the first trench 22 is in communication with a side wall of the separation trench 16, and a bottom wall of the first trench 22 is in communication with a bottom wall of the separation trench 16.

The first insulating film 23 covers a wall surface of the first trench 22 in a film shape. The first insulating film 23 may include at least one among a silicon oxide film, a silicon nitride film, and an aluminum oxide film. The first insulating film 23 preferably has a single layer structure constituted of a single insulating film.

The first insulating film 23 particularly preferably includes a silicon oxide film that is constituted of the oxide of the chip 2. In this embodiment, the first insulating film 23 is constituted of the same insulating film as the separation insulation film 17. The first insulating film 23 is connected to the separation insulation film 17 at communicating portions of the separation trench 16 and the first trench 22.

The first embedded electrode 24 is embedded in the first trench 22 with the first insulating film 23 interposed therebetween. The first embedded electrode 24 may contain a conductive polysilicon. The gate potential is applied to the first embedded electrode 24. The first embedded electrode 24 is mechanically and electrically connected to the separation embedded electrode 18 at the communicating portions of the separation trench 16 and the first trench 22.

The semiconductor device 1A includes a plurality of second trench structures 25 each formed in a region between mutually adjacent ones of the plurality of first trench structures 21 in the first principal surface 3 of the first active region 6A. The second trench structures 25 may be referred to as “emitter trench structures.” In plan view, each second trench structure 25 is formed at intervals in the first direction X from the plurality of first trench structures 21 and is formed in a quadrangle annular shape extending in the second direction Y.

A width of the second trench structure 25 is preferably less than the width of the street region 11. The width of the second trench structure 25 is a width in a direction orthogonal to the direction in which the second trench structure 25 extends. The width of the second trench structure 25 may be not less than 0.1 μm and not more than 2.5 μm. The width of the second trench structure 25 is preferably not less than 0.3 μm and not more than 1 μm.

The width of the second trench structure 25 is particularly preferably not less than 0.4 μm and not more than 0.7 μm. The width of the second trench structure 25 is preferably substantially equal to the width of the first trench structure 21. The second trench structure 25 may have a depth of not less than 1 μm and not more than 20 μm. The depth of the second trench structure 25 is preferably not less than 4 μm and not more than 10 μm. The depth of the second trench structure 25 is preferably substantially equal to the depth of the first trench structure 21.

Hereinafter, the arrangement of a single second trench structure 25 shall be described. The second trench structure 25 includes a second trench 26, a second insulating film 27, and a second embedded electrode 28. The second trench 26 is formed in the first principal surface 3 and demarcates a wall surface of the second trench structure 25.

The second insulating film 27 covers a wall surface of the second trench 26 in a film shape. The second insulating film 27 may include at least one among a silicon oxide film, a silicon nitride film, and an aluminum oxide film. The second insulating film 27 preferably has a single layer structure constituted of a single insulating film. The second insulating film 27 particularly preferably includes a silicon oxide film that is constituted of the oxide of the chip 2. In this embodiment, the second insulating film 27 is constituted of the same insulating film as the first insulating film 23.

The second embedded electrode 28 is embedded in the second trench 26 with the second insulating film 27 interposed therebetween. The second embedded electrode 28 may contain a conductive polysilicon. An emitter potential is applied to the second embedded electrode 28.

The semiconductor device 1A includes a plurality of emitter regions 29 of the n-type formed in a surface layer portion of the channel region 20 in the first active region 6A. Each of the plurality of emitter regions 29 has a higher n-type impurity concentration than the drift region 12. The plurality of emitter regions 29 are respectively formed on both sides of the plurality of first trench structures 21. The n-type impurity concentration of the emitter regions 29 is preferably, for example, not less than 1.0×10¹⁹ cm⁻³ and not more than 1.0×10²¹ cm⁻³.

The plurality of emitter regions 29 are each formed in a band shape extending along the plurality of first trench structures 21 in plan view. As a matter of course, the plurality of emitter regions 29 may be formed at intervals along the plurality of first trench structures 21 in plan view. In this embodiment, the plurality of emitter regions 29 are each formed in a region between a first trench structure 21 and a second trench structure 25 such as to be connected to the first trench structure 21 and the second trench structure 25. The emitter regions 29 are preferably not formed in a region between the trench separation structure 15 and the outermost second trench structure 25.

The semiconductor device 1A includes a plurality of contact holes 30 formed in the first principal surface 3 such as to expose the emitter regions 29 in the first active region 6A. The plurality of contact holes 30 are respectively formed on both sides of the plurality of first trench structures 21 at intervals from the plurality of first trench structures 21. Each of the plurality of contact holes 30 may be formed in a tapered shape in which an opening width narrows from an opening toward a bottom wall.

The plurality of contact holes 30 penetrate through the emitter regions 29 such as to reach the channel region 20. The plurality of contact holes 30 may be separated to the first principal surface 3 side from bottom portions of the emitter regions 29 such as not to reach the channel region 20. The plurality of contact holes 30 are each formed in a band shape extending along the plurality of first trench structures 21 in plan view. The plurality of contact holes 30 are preferably shorter than the plurality of first trench structures 21 in a length direction (the second direction Y). The plurality of contact holes 30 are particularly preferably shorter than the plurality of second trench structures 25.

The semiconductor device 1A includes a plurality of channel contact regions 31 of the p-type formed in regions different from the plurality of emitter regions 29 in the surface layer portion of the channel region 20 of the first active region 6A. The plurality of channel contact regions 31 have a higher p-type impurity concentration than the channel region 20. Each of the plurality of channel contact regions 31 is formed in a band shape extending along the corresponding contact hole 30 in plan view. Bottom portions of the plurality of channel contact regions 31 are each formed in a region between the bottom wall of the corresponding contact hole 30 and the bottom portion of the channel region 20.

The p-type impurity concentration of the channel region 20 is preferably, for example, not less than 1.0×10¹⁶ cm⁻³ and not more than 1.0×10¹⁸ cm⁻³. The p-type impurity concentration of the channel contact regions 31 is preferably, for example, not less than 1.0×10¹⁸ cm⁻³ and not more than 1.0×10²⁰ cm⁻³.

The semiconductor device 1A includes a plurality of floating regions 32 of the p-type respectively formed in regions surrounded by the plurality of second trench structures 25 in the surface layer portion of the first principal surface 3 in the first active region 6A. The plurality of floating regions 32 are formed in an electrically floating state. As a matter of course, the emitter potential may be applied to the plurality of floating regions 32. The plurality of floating regions 32 preferably have a higher p-type impurity concentration than the channel region 20.

Each floating region 32 extends in a layer shape along the first principal surface 3 and is connected to an inner peripheral wall of each second trench structure 25. Each floating region 32 is preferably formed deeper than a depth range intermediate portion of the second trench structure 25. In this embodiment, each floating region 32 is formed deeper than the second trench structure 25 and has a portion that covers a bottom wall of the second trench structure 25.

As described above, the first active region 6A includes, as the IGBT structure Tr, the channel region 20, the plurality of first trench structures 21, the plurality of second trench structures 25, the plurality of emitter regions 29, the plurality of contact holes 30, the plurality of channel contact regions 31, and the plurality of floating regions 32. Also, as with the first active region 6A, the second active region 6B includes, as the IGBT structure Tr, the channel region 20, the plurality of first trench structures 21, the plurality of second trench structures 25, the plurality of emitter regions 29, the plurality of contact holes 30, the plurality of channel contact regions 31, and the plurality of floating regions 32.

The semiconductor device 1A includes a boundary well region 40 of the p-type formed in a surface layer portion of the first principal surface 3 in the boundary region 8. In this embodiment, the boundary well region 40 has a higher p-type impurity concentration than the channel region 20. As a matter of course, the boundary well region 40 may have a lower p-type impurity concentration than the channel region 20.

The boundary well region 40 is formed in a band shape extending along the boundary region 8 in the first direction X in plan view. That is, the boundary well region 40 is formed in a layer shape extending along the first principal surface 3 in a region sandwiched by the first trench separation structure 15A and the second trench separation structure 15B and is exposed from the first principal surface 3. The boundary well region 40 is formed in a region sandwiched by the plurality of first trench structures 21 at the first active region 6A side and the plurality of first trench structures 21 at the second active region 6B side.

The boundary well region 40 includes a first boundary well region 40A formed in the pad region 10 and a second boundary well region 40B formed in the street region 11. The first boundary well region 40A has a comparatively large region width in the second direction Y. The first boundary well region 40A is formed in a polygonal shape (in this embodiment, a quadrangle shape) in plan view. The first boundary well region 40A is preferably formed in an entire region of the pad region 10.

The second boundary well region 40B has a region width smaller than the region width of the first boundary well region 40A in the second direction Y and is led out in a band shape from the first boundary well region 40A toward the street region 11. In this embodiment, the second boundary well region 40B is positioned on the straight line crossing the center of the first principal surface 3 in the first direction X. The second boundary well region 40B extends in a band shape such as to be positioned in a region at one side (the third side surface 5C side) and a region at the other side (the fourth side surface 5D side) in the first direction X with respect to a straight line crossing the center of the first principal surface 3 in the second direction Y.

The boundary well region 40 is preferably formed deeper than the channel region 20. The boundary well region 40 is particularly preferably formed deeper than the plurality of trench separation structures 15 (the plurality of first trench structures 21). In this embodiment, the boundary well region 40 has a width larger than the width of the boundary region 8 in the second direction Y and is led out from the boundary region 8 into the plurality of active regions 6.

The boundary well region 40 is connected to the plurality of trench separation structures 15 that are mutually adjacent in the second direction Y. The boundary well region 40 has a portion that covers the bottom walls of the plurality of trench separation structures 15. The boundary well region 40 has a portion that covers the bottom walls of the plurality of first trench structures 21 across the plurality of trench separation structures 15.

The boundary well region 40 covers the side walls of the trench separation structures 15 and the side walls of the plurality of trench structures in the plurality of active regions 6 and is connected to each channel region 20 in the surface layer portion of the first principal surface 3. The depth of the boundary well region 40 may be not less than 1 μm and not more than 20 μm. The depth of the boundary well region 40 is preferably not less than 5 μm and not more than 10 μm.

The semiconductor device 1A includes an outer peripheral well region 41 of the p-type formed in a surface layer portion of the first principal surface 3 in the outer peripheral region 9. In this embodiment, the outer peripheral well region 41 has a higher p-type impurity concentration than the channel region 20. As a matter of course, the outer peripheral well region 41 may have a lower p-type impurity concentration than the channel region 20 instead. The p-type impurity concentration of the outer peripheral well region 41 is preferably substantially equal to the p-type impurity concentration of the boundary well region 40.

The outer peripheral well region 41 is formed in a layer shape extending along the first principal surface 3 and is exposed from the first principal surface 3. The outer peripheral well region 41 is formed at an interval inward from the peripheral edge (the first to fourth side surfaces 5A to 5D) of the first principal surface 3. The outer peripheral well region 41 is formed in a band shape extending along the plurality of active regions 6 in plan view. In this embodiment, the outer peripheral well region 41 is formed in an annular shape (in this embodiment, a quadrangle annular shape) surrounding the plurality of active regions 6 entirely in plan view.

The outer peripheral well region 41 is preferably formed deeper than the channel region 20. The outer peripheral well region 41 is particularly preferably formed deeper than the plurality of trench separation structures 15 (the plurality of first trench structures 21). The outer peripheral well region 41 preferably has a depth substantially equal to the boundary well region 40.

The outer peripheral well region 41 is connected to the plurality of trench separation structures 15. The outer peripheral well region 41 has a portion that covers the bottom walls of the plurality of trench separation structures 15. The outer peripheral well region 41 is led out from the outer peripheral region 9 into the plurality of active regions 6. The outer peripheral well region 41 has a portion that covers the bottom walls of the plurality of first trench structures 21 across the plurality of trench separation structures 15.

In each active region 6, the outer peripheral well region 41 covers the side wall of the trench separation structure 15 and the side walls of the plurality of first trench structures 21 and is connected to the channel region 20 in the surface layer portion of the first principal surface 3. The outer peripheral well region 41 is connected to the boundary well region 40 at a connection portion of the boundary region 8 and the outer peripheral region 9. That is, the outer peripheral well region 41, together with the boundary well region 40, demarcates the plurality of active regions 6.

With reference to FIG. 2, FIG. 10A, and FIG. 10B, the semiconductor device 1A includes a plurality of field limiting rings (FLRs) 42 of the p-type formed in the surface layer portion of the first principal surface 3 in the outer peripheral region 9. In the following, the field limiting rings shall be called FLRs 42. The FLRs 42 are provided to relax concentration of electric field at outer ends of pn junctions of the semiconductor device 1A. The FLRs 42 may be referred to as “guard rings.”

The number of FLRs 42 is arbitrary and may be not less than 2 and not more than 20 (typically not less than 3 and not more than 10). In this embodiment, four FLRs 42 are provided. The plurality of FLRs 42 are formed in an electrically floating state.

The plurality of FLRs 42 are formed in a region between the peripheral edge of the chip 2 and the outer peripheral well region 41 at intervals from the peripheral edge of chip 2 and the outer peripheral well region 41. The plurality of FLRs 42 are formed in band shapes extending along the outer peripheral well region 41 in plan view. In this embodiment, the plurality of FLRs 42 are formed in annular shapes (quadrangle annular shapes) surrounding the outer peripheral well region 41 in plan view. The plurality of FLRs 42 each have width smaller than the width of the outer peripheral well region 41.

The plurality of FLRs 42 are preferably formed to be deeper than the channel region 20. The plurality of FLRs 42 may be formed to be of a depth substantially equal to that of the outer peripheral well region 41. The plurality of FLRs 42 may be formed to be shallower than the outer peripheral well region 41. The plurality of FLRs 42 may be formed to be of a constant depth.

Each FLR 42 has FLR curve portions 42A that are circular arcs in plan view shape in the four corner portions 201 to 204. Inner edges 42Aa and outer edges 42Ab of all of the FLR curve portions 42A may have the same center of curvature in each of the corner portions 201 to 204. Between the four corner portions 201 to 204, each FLR 42 has FLR rectilinear portions 42B that are rectilinear in plan view shape.

Each FLR curve portion 42A has a double-diffused structure including a first diffusion region 301 at an inner side and a second diffusion region 302 at an outer side that is lower in p-type impurity concentration than the first diffusion region 301.

The inner edge 42Aa of each FLR curve portion 42A is an inner edge of the first diffusion region 301 of the FLR curve portion 42A. The outer edge 42Ab of each FLR curve portion 42A is an outer edge of the second diffusion region 302 of the FLR curve portion 42A. A boundary line (referred to hereinafter as the “diffusion region boundary line BL”) between the first diffusion region 301 and the second diffusion region 302 is formed in a width intermediate portion between the inner edge 42Aa and the outer edge 42Ab of the FLR curve portion 42A. The diffusion region boundary line BL constitutes an outer edge of the first diffusion region 301 and an inner edge of the second diffusion region 302.

Each FLR rectilinear portion 42B has a single-diffused structure constituted of just a diffusion region having the same second conductivity type impurity concentration as the first diffusion region 301.

In this embodiment, between the four corner portions 201 to 204, the intervals between the plurality of FLR rectilinear portions 42B are fixed and the plurality of FLR rectilinear portions 42B have the same width. Also, in the four corner portions 201 to 204, the intervals between the plurality of FLR curve portions 42A are fixed and the plurality of FLR curve portions 42A have the same width. Also, in the four corner portions 201 to 204, respective widths of the first diffusion regions 301 of the plurality of FLR curve portions 42A are the same and respective widths of the second diffusion regions 302 of the plurality of FLR curve portions 42A are the same. Also, the width of the first diffusion region 301 of each FLR curve portion 42A is the same as the width of each FLR rectilinear portion 42B.

In this embodiment, in each of the corner portions 201 to 204, the inner edges 42Aa and the outer edges 42Ab of all of the FLR curve portions 42A have the same center of curvature. Also, in each of the corner portions 201 to 204, the centers of curvature of the inner edge 42Aa and the outer edge BL of the first diffusion region 301 and the inner edge BL and the outer edge 42Ab of the second diffusion region 302 in each FLR curve portion 42A are present at positions on a dividing line that is a straight line dividing an apex angle of the corresponding corner portion in ½.

Here, between the four corner portions 201 to 204, the intervals between the plurality of FLR rectilinear portions 42B do not have to be fixed. Also, between the four corner portions 201 to 204, the widths of the plurality of FLR rectilinear portions 42B may differ. Also, in the four corner portions 201 to 204, the intervals between the plurality of FLR curve portions 42A do not have to be fixed. Also, in the four corner portions 201 to 204, the widths of the plurality of FLR curve portions 42A may differ. Also, the respective widths of the first diffusion regions 301 of the plurality of FLR curve portions 42A may differ. Also, the respective widths of the second diffusion regions 302 of the plurality of FLR curve portions 42A may differ.

Here, in each of the corner portions 201 to 204, the inner edges 42Aa and the outer edges 42Ab of all of the FLR curve portions 42A do not have to have the same center of curvature. Also, in each of the corner portions 201 to 204, the centers of curvature of the inner edge 42Aa and the outer edge BL of the first diffusion region 301 and the inner edge BL and the outer edge 42Ab of the second diffusion region 302 in each FLR curve portion 42A do not have to be present at positions on the dividing line that is the straight line dividing the apex angle of the corresponding corner portion in ½.

In this embodiment, in each of the corner portions 201 to 204, the width of the second diffusion region 302 in each FLR curve portion 42A is narrower than the width of the first diffusion region 301. Here, the width of the second diffusion region 302 in each FLR curve portion 42A may instead be wider than the width of the first diffusion region 301. Also, the width of the second diffusion region 302 in each FLR curve portion 42A may be the same as the width of the first diffusion region 301.

In this embodiment, in each of the corner portions 201 to 204, a depth of the second diffusion region 302 in each FLR curve portion 42A is the same as a depth of the first diffusion region 301. The depth of the second diffusion region 302 in each FLR curve portion 42A may instead differ from the depth of the first diffusion region 301. For example, as shown in FIG. 10C, the depth of the second diffusion region 302 in each FLR curve portion 42A may be deeper than the depth of the first diffusion region 301.

In this embodiment, whereas the FLRs 42 are formed rectilinearly in plan view in regions between the corner portions 201 to 204, the FLRs 42 are formed curvedly in plan view in the corner portions 201 to 204. Thus, in the outer peripheral region 9, electric field concentration occurs more readily in the corner portions 201 to 204 in which the FLR curve portions 42A are present than in the regions between corner portions at which the FLR rectilinear portions 42B are present. Thereby, breakdown voltages (BVs) of the corner portions 201 to 204 in the outer peripheral region 9 are made lower than those of the regions between corner portions in the outer peripheral region 9.

In this embodiment, the plurality of FLR curve portions 42A in each of the corner portions 201 to 204 each have the double-diffused structure including the first diffusion region 301 at the inner side and the second diffusion region 302 at the outer side that is of lower p-type impurity concentration than the first diffusion region 301. Equipotential surfaces can thereby be made smooth in each of the corner portions 201 to 204 and therefore, electric field concentration can be relaxed in each of the corner portions 201 to 204. The breakdown voltages of the corner portions 201 to 204 can thereby be increased.

The semiconductor device 1A includes a channel stop region 43 formed in a surface layer portion of the first principal surface 3 in the outer peripheral region 9 at intervals to the peripheral edge side of the chip 2 from the plurality of FLRs 42. The channel stop region 43 has a higher n-type impurity concentration than the drift region 12. Such a channel stop region 43 can be formed, for example, at the same time as the emitter regions 29 in a step of forming the emitter regions 29.

The channel stop region 43 is formed in a band shape extending along the peripheral edge of the chip 2 in plan view. In this embodiment, the channel stop region 43 is formed an annular shape (quadrangle annular shape) surrounding the plurality of FLRs 42 in plan view. The channel stop region 43 may be exposed from the first to fourth side surfaces 5A to 5D. The channel stop region 43 is formed in an electrically floating state.

The semiconductor device 1A includes a principal surface insulating film 45 selectively covering the first principal surface 3. The principal surface insulating film 45 selectively covers the first principal surface 3 in the active regions 6, the boundary region 8, and the outer peripheral region 9. The principal surface insulating film 45 may include at least one among a silicon oxide film, a silicon nitride film, and an aluminum oxide film.

The principal surface insulating film 45 preferably has a single layer structure constituted of a single insulating film. The principal surface insulating film 45 particularly preferably includes a silicon oxide film that is constituted of the oxide of the chip 2. In this embodiment, the principal surface insulating film 45 is constituted of the same insulating film as the first insulating films 23 (the separation insulation films 17). The principal surface insulating film 45 covers the first principal surface 3 such as to expose the trench separation structures 15, the first trench structures 21, and the second trench structures 25.

Specifically, the principal surface insulating film 45 is connected to the separation insulation films 17, the first insulating films 23, and the second insulating films 27 and exposes the separation embedded electrodes 18, the first embedded electrodes 24, and the second embedded electrodes 28. The principal surface insulating film 45 selectively covers the boundary well region 40, the outer peripheral well region 41, the FLRs 42, and the channel stop region 43 in the boundary region 8 and the outer peripheral region 9.

With reference to FIG. 3 and FIG. 5, the semiconductor device 1A includes a plurality of emitter electrode films 47 disposed on the first principal surface 3 such as to cover the plurality of second trench structures 25 in the active regions 6. Specifically, the plurality of emitter electrode films 47 are disposed on the principal surface insulating film 45. The plurality of emitter electrode films 47 may contain a conductive polysilicon.

The plurality of emitter electrode films 47 cover both end portions of the plurality of second trench structures 25 in the second direction Y, respectively. In this embodiment, the plurality of emitter electrode films 47 are each formed in a band shape extending in the second direction Y in a region between the corresponding second trench structure 25 and the trench separation structure 15. The plurality of emitter electrode films 47 are formed at intervals toward the second trench structure 25 side from the trench separation structure 15. The plurality of emitter electrode films 47 face the channel region 20 with the principal surface insulating film 45 interposed therebetween.

The plurality of emitter electrode films 47 are respectively formed integrally with the second embedded electrodes 28 of the plurality of second trench structures 25. That is, each of the plurality of emitter electrode films 47 is constituted of a portion where a part of the second embedded electrode 28 is led out in a film shape onto the first principal surface 3 (the principal surface insulating film 45). As a matter of course, the plurality of emitter electrode films 47 may be formed separately from the second embedded electrodes 28 instead.

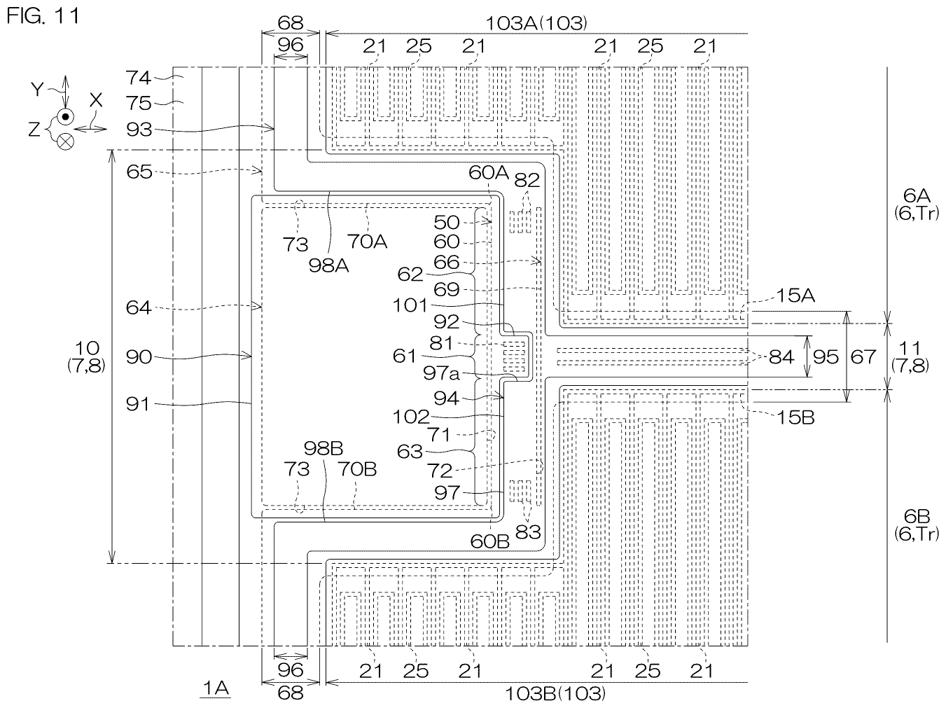

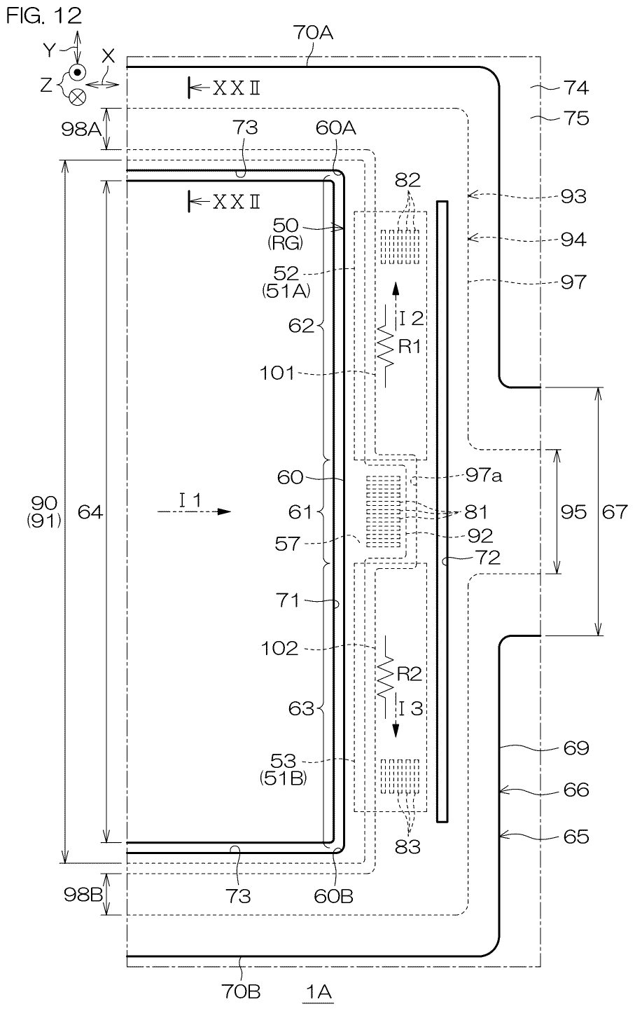

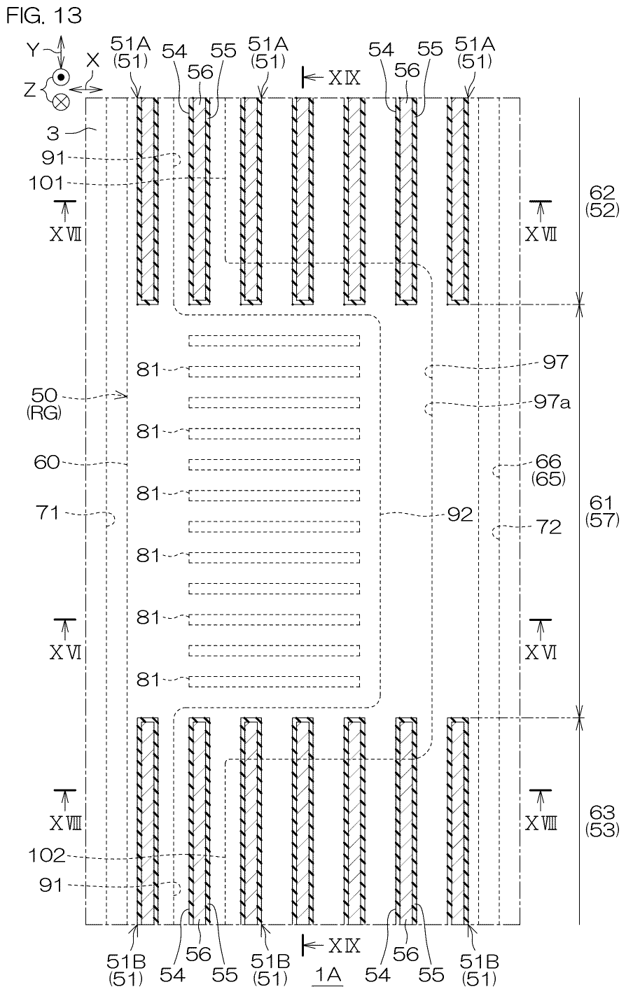

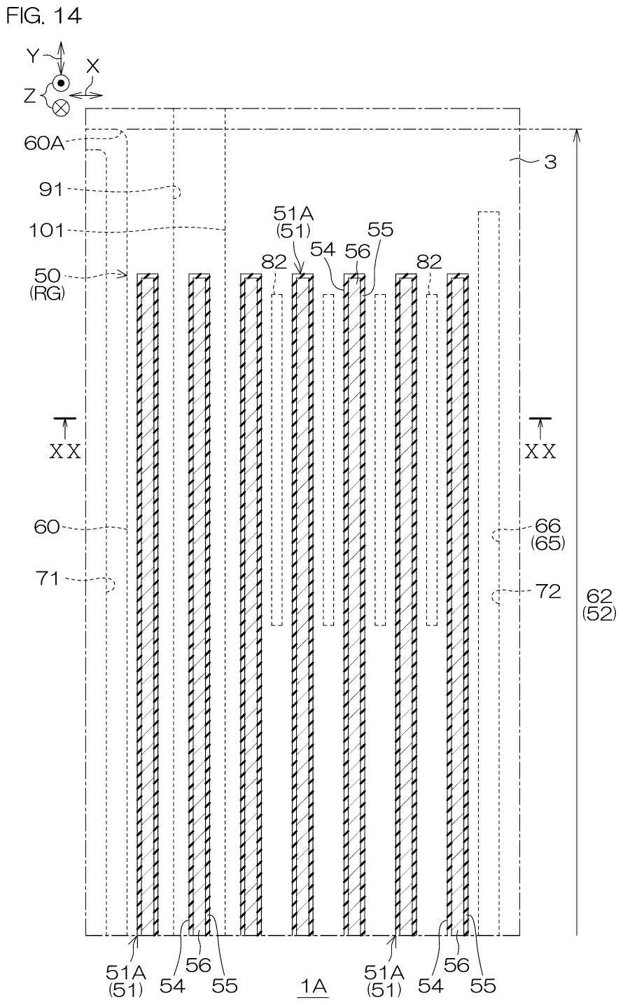

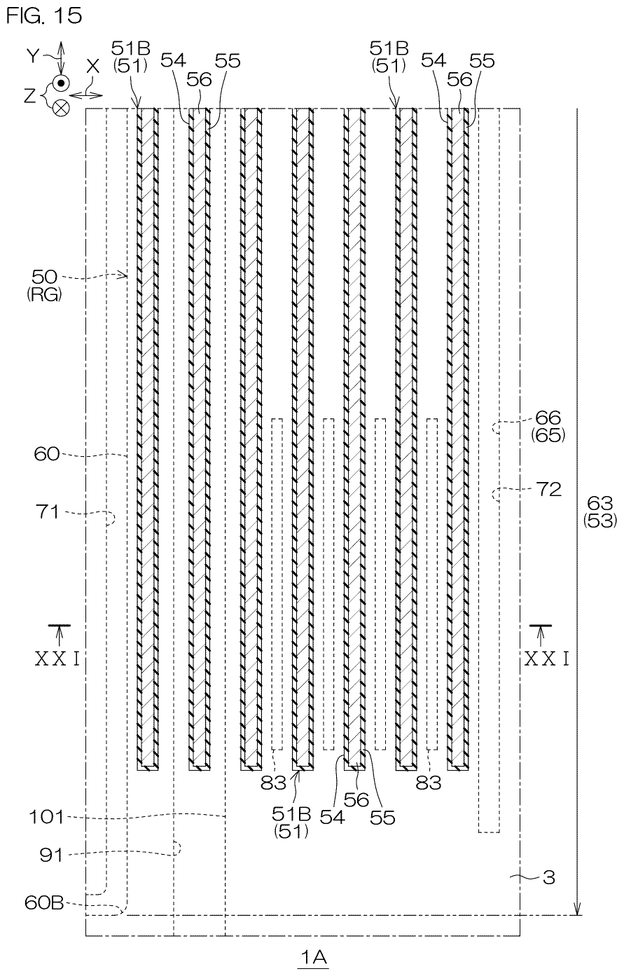

FIG. 11 is an enlarged plan view showing the pad region 10. FIG. 12 is an enlarged plan view showing a gate resistive structure 50 shown in FIG. 11. FIG. 13 is an enlarged plan view showing an inner portion of the gate resistive structure 50 shown in FIG. 12. FIG. 14 is an enlarged plan view showing one end portion of the gate resistive structure 50 shown in FIG. 12. FIG. 15 is an enlarged plan view showing another end portion of the gate resistive structure 50 shown in FIG. 12.

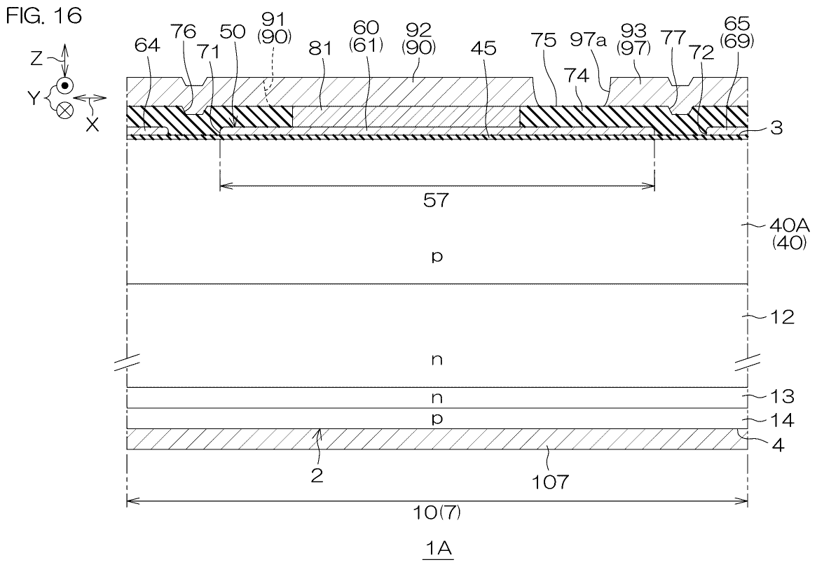

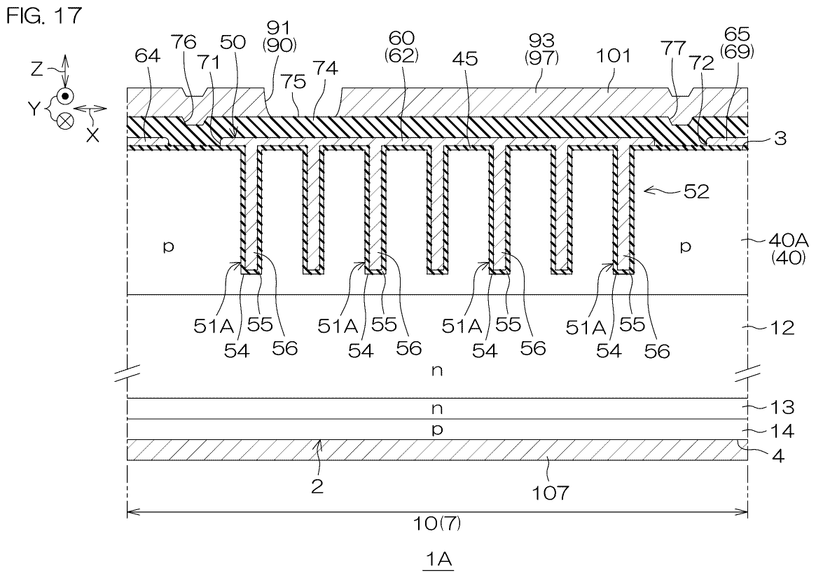

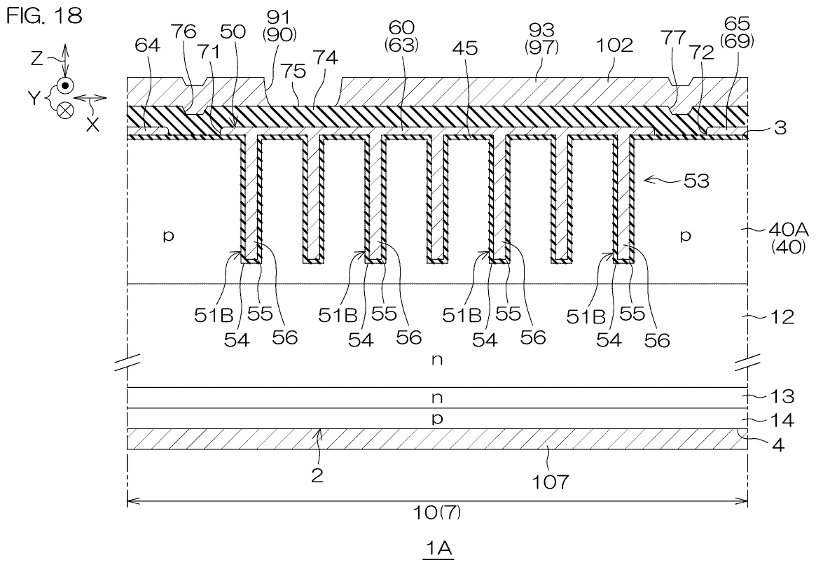

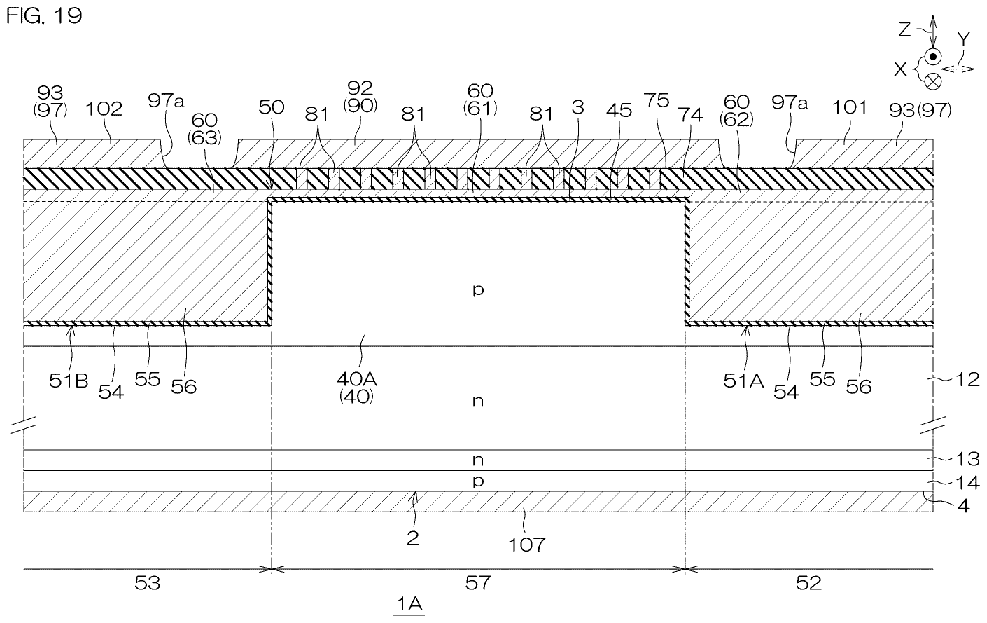

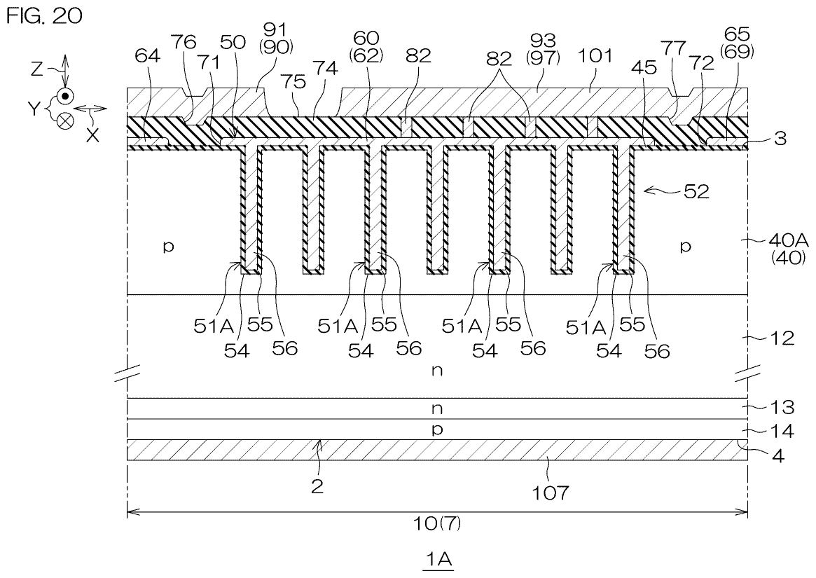

FIG. 16 is a cross-sectional view taken along line XVI-XVI shown in FIG. 13. FIG. 17 is a cross-sectional view taken along line XVII-XVII shown in FIG. 13. FIG. 18 is a cross-sectional view taken along line XVIII-XVIII shown in FIG. 13. FIG. 19 is a cross-sectional view taken along line XIX-XIX shown in FIG. 13. FIG. 20 is a cross-sectional view taken along line XX-XX shown in FIG. 14.

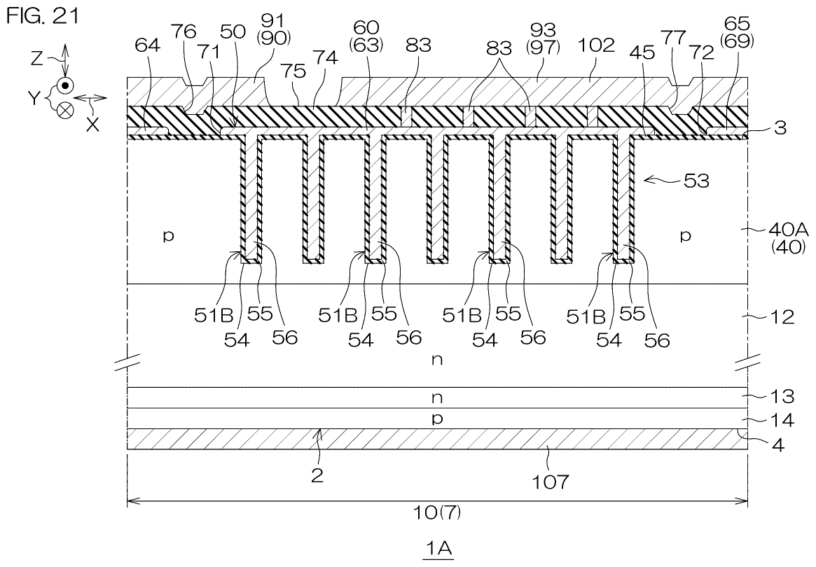

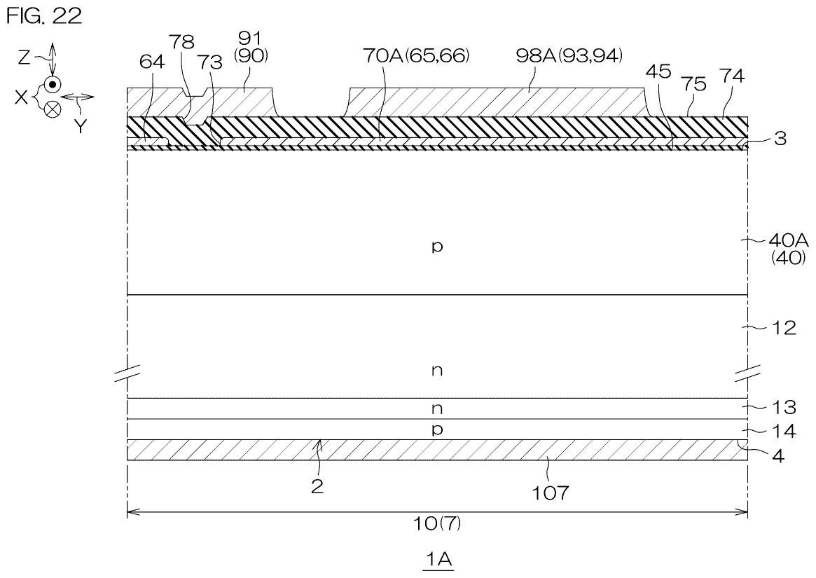

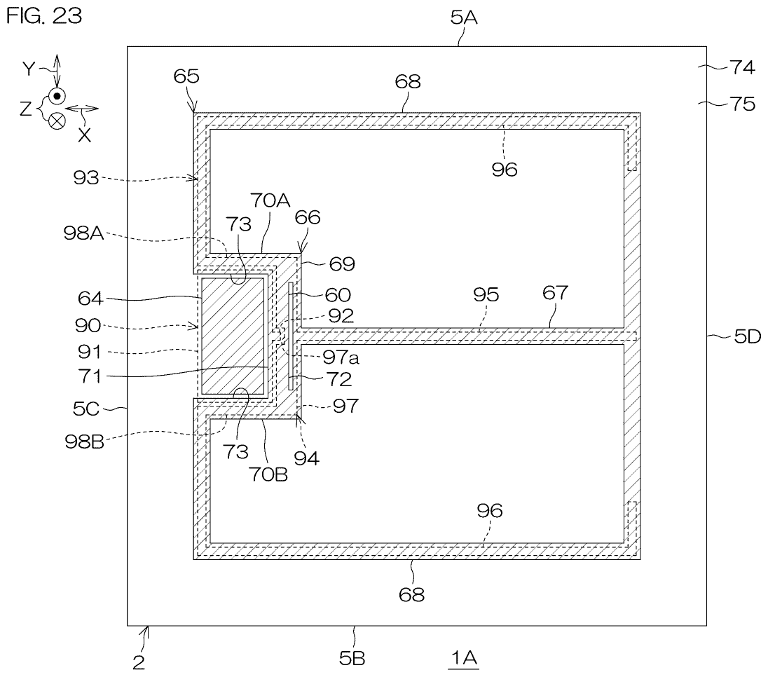

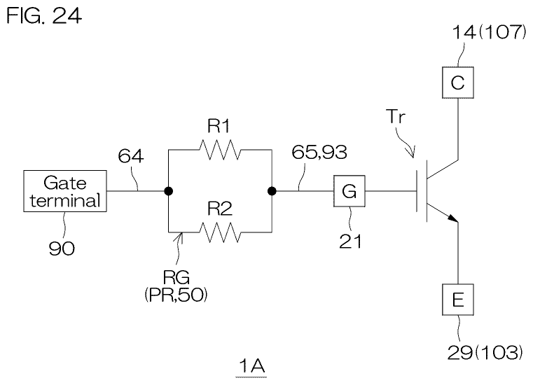

FIG. 21 is a cross-sectional view taken along line XXI-XXI shown in FIG. 15. FIG. 22 is a cross-sectional view taken along line XXII-XXII shown in FIG. 12. FIG. 23 is a plan view showing a layout of a resistive film 60, a gate electrode film 64, and a gate wiring film 65. FIG. 24 is an electric circuit diagram showing the gate resistive structure 50, a gate terminal electrode 90, and a gate wiring electrode 93.

With reference to FIG. 11 to FIG. 24, the semiconductor device 1A includes the gate resistive structure 50 formed in the pad region 10. The gate resistive structure 50 constitutes a gate resistance RG for a gate of the IGBT (the first trench structures 21 of the IGBT structure Tr). The gate resistive structure 50 includes a plurality of trench resistive structures 51 formed in the first principal surface 3 in the pad region 10. Although the gate potential is applied to the plurality of trench resistive structures 51, the plurality of trench resistive structures 51 do not contribute to control of channels.

In this embodiment, the plurality of trench resistive structures 51 constitute a first trench group 52 and a second trench group 53. The first trench group 52 includes a plurality of first trench resistive structures 51A that constitute a part of the plurality of trench resistive structures 51 and is provided at one side (the first side surface 5A side) in the second direction Y. The number of first trench resistive structures 51A is arbitrary and is adjusted based on a resistance value to be achieved.

For example, the first trench group 52 may include not less than 2 and not more than 100 first trench resistive structures 51A. The number of first trench resistive structures 51A is preferably not more than 50. The number of first trench resistive structures 51A may be not more than 25. The number of first trench resistive structures 51A is preferably not less than 5. As a matter of course, the gate resistive structure 50 may include a single first trench resistive structure 51A instead of the first trench group 52.

In this embodiment, the first trench group 52 is provided in a region at one side (the first side surface 5A side) in the second direction Y with respect to the straight line crossing the center of the first principal surface 3 in the first direction X. The first trench group 52 is preferably disposed such as to be shifted further to the active region 6 side (the street region 11 side) than the outer peripheral region 9 in the pad region 10. In this embodiment, the first trench group 52 is disposed at an interval to the active region 6 side (the street region 11 side) from a central portion of the pad region 10. These arrangements are effective in suppressing electric field concentration on the plurality of first trench resistive structures 51A.

The plurality of first trench resistive structures 51A are formed in the first principal surface 3 at intervals from the plurality of trench separation structures 15 (the plurality of first trench structures 21). The plurality of first trench resistive structures 51A are aligned at intervals in the first direction X in plan view and are each formed in a band shape extending in the second direction Y. That is, the plurality of first trench resistive structures 51A are aligned in a stripe shape extending in the second direction Y. The plurality of first trench resistive structures 51A have one end portions at one side (the first side surface 5A side) in the second direction Y and other end portions at another side (the second side surface 5B side) in the second direction Y.

The plurality of first trench resistive structures 51A are formed at intervals to the first principal surface 3 side from a bottom portion of the boundary well region 40 (the first boundary well region 40A) such as to be positioned inside the boundary well region 40 (the first boundary well region 40A) and face the drift region 12 with a part of the boundary well region 40 interposed therebetween. That is, the plurality of first trench resistive structures 51A do not penetrate through the boundary well region 40 (the first boundary well region 40A).

The intervals between the plurality of first trench resistive structures 51A are preferably less than the width of the street region 11. The intervals between the plurality of first trench resistive structures 51A are preferably substantially equal to the interval between a first trench structure 21 and a second trench structure 25. The intervals between the plurality of first trench resistive structures 51A may be smaller than the interval between the first trench structure 21 and the second trench structure 25. The intervals between the plurality of first trench resistive structures 51A may be larger than the interval between the first trench structure 21 and the second trench structure 25.

The width of each first trench resistive structure 51A is preferably less than the width of the street region 11. The width of the first trench resistive structure 51A is a width in a direction orthogonal to the direction in which the first trench resistive structure 51A extends. The width of the first trench resistive structure 51A may be not less than 0.1 μm and not more than 2.5 μm. The width of the first trench resistive structure 51A is preferably not less than 0.3 μm and not more than 1 μm.

The width of the first trench resistive structure 51A is particularly preferably not less than 0.4 μm and not more than 0.7 μm. The width of the first trench resistive structure 51A is preferably substantially equal to the width of each first trench structure 21. The first trench resistive structure 51A may have a depth of not less than 1 μm and not more than 20 μm. The depth of the first trench resistive structure 51A is preferably not less than 4 μm and not more than 10 μm. The depth of the first trench resistive structure 51A is preferably substantially equal to the depth of the first trench structure 21.

The second trench group 53 includes a plurality of second trench resistive structures 51B that constitute a part of the plurality of trench resistive structures 51 and is provided at an interval to the other side (the second side surface 5B side) in the second direction Y from the first trench group 52. The number of second trench resistive structures 51B is arbitrary and is adjusted based on a resistance value to be achieved. For example, when a resistance value substantially equal to the resistance value at the first trench group 52 side is to be realized, the second trench group 53 may include the same number of second trench resistive structures 51B as the number of first trench resistive structures 51A.

For example, when a resistance value different from the resistance value at the first trench group 52 side is to be realized, the second trench group 53 may include a different number of second trench resistive structures 51B from the number of first trench resistive structures 51A. For example, when the resistance value at the second trench group 53 side is larger than the resistance value at the first trench group 52 side, the number of second trench resistive structures 51B may be fewer than the number of first trench resistive structures 51A. For example, when the resistance value at the second trench group 53 side is less than the resistance value at the first trench group 52 side, the number of second trench resistive structures 51B may be larger than the number of first trench resistive structures 51A.

For example, the second trench group 53 may include not less than 2 and not more than 100 second trench resistive structures 51B. The number of second trench resistive structures 51B is preferably not more than 50. The number of second trench resistive structures 51B may be not more than 25. The number of second trench resistive structures 51B is preferably not less than 5. As a matter of course, the semiconductor device 1A may include a single second trench resistive structure 51B instead of the second trench group 53.

In this embodiment, the second trench group 53 is provided in a region at the other side (the second side surface 5B side) in the second direction Y with respect to the straight line crossing the center of the first principal surface 3 in the first direction X. The second trench group 53 faces the first trench group 52 in the second direction Y. The second trench group 53 is preferably disposed such as to be shifted further to the active region 6 side (the street region 11 side) than the outer peripheral region 9 in the pad region 10. In this embodiment, the second trench group 53 is disposed at an interval to the active region 6 side (the street region 11 side) from the central portion of the pad region 10. These arrangements are effective in suppressing electric field concentration on the plurality of second trench resistive structures 51B.

The plurality of second trench resistive structures 51B are formed in the first principal surface 3 at intervals from the plurality of trench separation structures 15 (the plurality of first trench structures 21). The plurality of second trench resistive structures 51B are aligned at intervals in the first direction X in plan view and are each formed in a band shape extending in the second direction Y.

That is, the plurality of second trench resistive structures 51B are aligned in a stripe shape extending in the second direction Y. The plurality of second trench resistive structures 51B respectively face the plurality of first trench resistive structures 51A in a one-to-one correspondence in the second direction Y. That is, the plurality of second trench resistive structures 51B are respectively disposed in the same straight lines as the plurality of first trench resistive structures 51A. The plurality of second trench resistive structures 51B have one end portions at one side (the first side surface 5A side) in the second direction Y and other end portions at the other side (the second side surface 5B side) in the second direction Y.

The plurality of second trench resistive structures 51B are formed at intervals to the first principal surface 3 side from the bottom portion of the boundary well region 40 (the first boundary well region 40A) such as to be positioned inside the boundary well region 40 (the first boundary well region 40A) and face the drift region 12 with a part of the boundary well region 40 interposed therebetween. That is, the plurality of second trench resistive structures 51B do not penetrate through the boundary well region 40 (the first boundary well region 40A).

The intervals between the plurality of second trench resistive structures 51B are preferably less than the width of the street region 11. The intervals between the plurality of second trench resistive structures 51B are preferably substantially equal to the interval between a first trench structure 21 and a second trench structure 25 that are mutually adjacent. The intervals between the plurality of second trench resistive structures 51B may be smaller than the interval between the first trench structure 21 and the second trench structure 25. The intervals between the plurality of second trench resistive structures 51B may be larger than the interval between the first trench structure 21 and the second trench structure 25.

The intervals between the plurality of second trench resistive structures 51B may be smaller than the intervals between the plurality of first trench resistive structures 51A. The intervals between the plurality of second trench resistive structures 51B may be larger than the intervals between the plurality of first trench resistive structures 51A. The intervals between the plurality of second trench resistive structures 51B are preferably substantially equal to the intervals between the plurality of first trench resistive structures 51A.

The width of each second trench resistive structure 51B is preferably less than the width of the street region 11. The width of the second trench resistive structure 51B is a width in a direction orthogonal to the direction in which the second trench resistive structure 51B extends. The width of the second trench resistive structure 51B may be not less than 0.1 μm and not more than 2.5 μm. The width of the second trench resistive structure 51B is preferably not less than 0.3 μm and not more than 1 μm. The width of the second trench resistive structure 51B is particularly preferably not less than 0.4 μm and not more than 0.7 μm. The width of the second trench resistive structure 51B is preferably substantially equal to the width of each first trench resistive structure 51A.

In this embodiment, each second trench resistive structure 51B has a length substantially equal to a length of each first trench resistive structure 51A in the second direction Y. As a matter of course, the second trench resistive structure 51B may be longer than the first trench resistive structure 51A in the second direction Y. Also, the second trench resistive structure 51B may be shorter than the first trench resistive structure 51A in the second direction Y. The length of the first trench resistive structure 51A and the length of the second trench resistive structure 51B are adjusted according to the resistance values to be achieved.

Each second trench resistive structure 51B may have a depth of not less than 1 μm and not more than 20 μm. The depth of the second trench resistive structure 51B is preferably not less than 4 μm and not more than 10 μm. The depth of the second trench resistive structure 51B is preferably substantially equal to the depth of each first trench resistive structure 51A (the first trench structure 21).

Hereinafter, the arrangement of a single trench resistive structure 51 (a first trench resistive structure 51A or a second trench resistive structure 51B) is described. The trench resistive structure 51 includes a resistance trench 54, a resistance insulation film 55, and a resistance embedded electrode 56. The resistance trench 54 is formed in the first principal surface 3 and demarcates a wall surface of the trench resistive structure 51.

The resistance insulation film 55 covers a wall surface of the resistance trench 54 in a film shape. The resistance insulation film 55 is connected to the principal surface insulating film 45 on the first principal surface 3. The resistance insulation film 55 may include at least one among a silicon oxide film, a silicon nitride film, and an aluminum oxide film. The resistance insulation film 55 preferably has a single layer structure constituted of a single insulating film. The resistance insulation film 55 particularly preferably includes a silicon oxide film that is constituted of the oxide of the chip 2.

The resistance embedded electrode 56 is embedded in the resistance trench 54 with the resistance insulation film 55 interposed therebetween. The resistance embedded electrode 56 may contain a conductive polysilicon. The gate potential is applied to the resistance embedded electrode 56.

In this embodiment, the gate resistive structure 50 includes a space region 57 demarcated in a region of the pad region 10 between the first trench group 52 and the second trench group 53. The space region 57 is formed by a flat portion of the first principal surface 3 in a region between the other end portions of the plurality of first trench resistive structures 51A and the one end portions of the plurality of second trench resistive structures 51B.

In this embodiment, the space region 57 is demarcated in a quadrangle shape in plan view. The space region 57 exposes the boundary well region 40 from the first principal surface 3. In this embodiment, the space region 57 is formed on the straight line crossing the center of the first principal surface 3 in the first direction X in plan view and faces the street region 11 in the first direction X.

The space region 57 has a space width along the second direction Y. The space width is larger than the width of the first trench resistive structure 51A (the second trench resistive structure 51B) in the first direction X. The space width is larger than the interval between two first trench resistive structures 51A (the second trench resistive structures 51B) that are mutually adjacent in the first direction X. The space width is preferably larger than the width of the first trench group 52 (the second trench group 53) in the first direction X. The space width may be smaller than the width of the first trench group 52 (the second trench group 53) in the first direction X.

The space width is preferably smaller than the length of the first trench group 52 (the second trench group 53) in the second direction Y. The space width may be substantially equal to the width of the street region 11 in the second direction Y. The space width may be larger than the width of the street region 11 in the second direction Y. The space width may be smaller than the width of the street region 11 in the second direction Y.

The gate resistive structure 50 includes the resistive film 60 disposed on the first principal surface 3 such as to cover the plurality of trench resistive structures 51 in the pad region 10. Specifically, the resistive film 60 is disposed on the principal surface insulating film 45. The resistive film 60 includes at least one among a conductive polysilicon film and an alloy film. The alloy film may contain an alloy crystal constituted of a metal element and a non-metal element. The alloy film may include at least one among a CrSi film, a CrSiN film, a CrSiO film, a TaN film, and a TiN film. In this embodiment, the resistive film 60 contains a conductive polysilicon.

A thickness of the resistive film 60 is adjusted as appropriate in accordance with the resistance value to be attained. The thickness of the resistive film 60 is preferably not more than the depth of the first trench resistive structures 51A (the second trench resistive structures 51B). The thickness of the resistive film 60 is particularly preferably less than the depth of the first trench resistive structures 51A (the second trench resistive structures 51B).

The thickness of the resistive film 60 is preferably not less than 0.5 times the width of the first trench resistive structures 51A (the second trench resistive structures 51B). The thickness of the resistive film 60 may be not less than 0.05 μm and not more than 2.5 μm. The thickness of the resistive film 60 is preferably not less than 0.5 μm and not more than 1.5 μm. When the resistive film 60 is constituted of the alloy film, the thickness of the resistive film 60 may be not less than 0.1 nm and not more than 100 nm.

The resistive film 60 is formed in a band shape extending in the second direction Y and has a first end portion 60A at one side (the first side surface 5A side) in the second direction Y and a second end portion 60B at the other side (the second side surface 5B side) in the second direction Y. In regard to the first direction X, the resistive film 60 has a width larger than the width of the first trench group 52 (the second trench group 53) in the first direction X. The width of the resistive film 60 may be less than the space width. As a matter of course, the width of the resistive film 60 may be not less than the space width. The resistive film 60 preferably has a uniform width in regard to the first direction X.

The resistive film 60 has a portion positioned at one side (the first side surface 5A side) and a portion positioned at the other side (the second side surface 5B side) in the second direction Y with respect to the straight line crossing the center of the first principal surface 3 in the first direction X. The resistive film 60 faces the first active region 6A, the second active region 6B, and the street region 11 in the first direction X. That is, the resistive film 60 faces the plurality of trench separation structures 15, the plurality of first trench structures 21, and the plurality of second trench structures 25 in the first direction X.

The resistive film 60 includes a first covering portion 61 that covers the space region 57, a second covering portion 62 that covers the first trench group 52, and a third covering portion 63 that covers the second trench group 53. The first covering portion 61 is a portion that covers the first principal surface 3 in a region outside the first trench group 52 (the plurality of first trench resistive structures 51A) and the second trench group 53 (the plurality of second trench resistive structures 51B). The first covering portion 61 is positioned at an intermediate portion between the first end portion 60A and the second end portion 60B and faces the boundary well region 40 with the principal surface insulating film 45 interposed therebetween in the thickness direction.

The second covering portion 62 forms the first end portion 60A of the resistive film 60 and covers all of the first trench resistive structures 51A. The second covering portion 62 forms the first end portion 60A further to an outer side (a peripheral edge side of the pad region 10) than the one end portions of the plurality of first trench resistive structures 51A. That is, the first end portion 60A faces the first covering portion 61 with the first trench group 52 interposed therebetween in plan view. The second covering portion 62 is connected to the resistance embedded electrodes 56 of the plurality of first trench resistive structures 51A and faces the boundary well region 40 with the principal surface insulating film 45 interposed therebetween in the thickness direction.

The third covering portion 63 forms the second end portion 60B of the resistive film 60 and covers all of the second trench resistive structures 51B. The third covering portion 63 forms the second end portion 60B further to an outer side (a peripheral edge side of the pad region 10) than the other end portions of the plurality of second trench resistive structures 51B. That is, the second end portion 60B faces the first covering portion 61 with the second trench group 53 interposed therebetween in plan view. The third covering portion 63 is connected to the resistance embedded electrodes 56 of the plurality of second trench resistive structures 51B and faces the boundary well region 40 with the principal surface insulating film 45 interposed therebetween in the thickness direction.

The resistive film 60 is integrally formed with the resistance embedded electrodes 56 of the plurality of first trench resistive structures 51A in the second covering portion 62 and is integrally formed with the resistance embedded electrodes 56 of the plurality of second trench resistive structures 51B in the third covering portion 63. That is, the resistive film 60 is constituted of a portion where a part of each resistance embedded electrode 56 is led out in a film shape onto the first principal surface 3 (the principal surface insulating film 45). As a matter of course, the resistive film 60 may be formed separately from the resistance embedded electrodes 56 instead.

The semiconductor device 1A includes the gate electrode film 64 disposed on the first principal surface 3 such as to be mutually adjacent to the resistive film 60. Specifically, the gate electrode film 64 is disposed on the principal surface insulating film 45. The gate electrode film 64 includes at least one among a conductive polysilicon film and an alloy film. The alloy film may contain an alloy crystal constituted of a metal element and a non-metal element.

The alloy film may include at least one among a CrSi film, a CrSiN film, a CrSiO film, a TaN film, and a TiN film. The gate electrode film 64 is preferably formed of the same resistance material as the resistive film 60. In this embodiment, the gate electrode film 64 contains a conductive polysilicon. The gate electrode film 64 preferably has a thickness substantially equal to the thickness of the resistive film 60.

The gate electrode film 64 is disposed on the principal surface insulating film 45 at an interval to an inner portion side (the third side surface 5C side) of the pad region 10 from the resistive film 60 and is physically separated from the resistive film 60. The gate electrode film 64 is formed at an interval to the inner portion side of the pad region 10 from the plurality of trench separation structures 15 in plan view.

The gate electrode film 64 faces the boundary well region 40 (the first boundary well region 40A) with the principal surface insulating film 45 interposed therebetween. The gate electrode film 64 is formed in a polygonal shape (in this embodiment, a quadrangle shape) in plan view. In this embodiment, the gate electrode film 64 is formed in a rectangular shape extending in the second direction Y along the resistive film 60.

With reference to FIG. 11, FIG. 12, and FIG. 24, the semiconductor device 1A includes the gate wiring film 65 disposed on the first principal surface 3 to be mutually adjacent to the resistive film 60 such as to face the gate electrode film 64 with the resistive film 60 interposed therebetween. Specifically, the gate wiring film 65 is disposed on the principal surface insulating film 45. The gate wiring film 65 includes at least one among a conductive polysilicon film and an alloy film. The alloy film may contain an alloy crystal constituted of a metal element and a non-metal element.

The alloy film may include at least one among a CrSi film, a CrSiN film, a CrSiO film, a TaN film, and a TiN film. The gate wiring film 65 is preferably formed of the same resistance material as the resistive film 60. In this embodiment, the gate wiring film 65 contains a conductive polysilicon. The gate wiring film 65 preferably has a thickness substantially equal to the thickness of the resistive film 60.

The gate wiring film 65 is disposed on the principal surface insulating film 45 at an interval from the gate electrode film 64 and is physically separated from the gate electrode film 64. The gate wiring film 65 has a first connection portion connected to the first end portion 60A of the resistive film 60 and a second connection portion connected to the second end portion 60B of the resistive film 60.

That is, the gate wiring film 65 is electrically connected to the plurality of trench resistive structures 51 via the resistive film 60. Specifically, the gate wiring film 65 is electrically connected, at a portion between the first covering portion 61 and the second covering portion 62 of the resistive film 60, to the plurality of first trench resistive structures 51A and is electrically connected, at a portion between the first covering portion 61 and the third covering portion 63 of the resistive film 60, to the plurality of second trench resistive structures 51B.

In this embodiment, the gate wiring film 65 includes a first lower wiring portion 66, a second lower wiring portion 67, and a third lower wiring portion 68. The first lower wiring portion 66 is routed to the pad region 10. Specifically, the first lower wiring portion 66 surrounds the resistive film 60 and the gate electrode film 64 in a plurality of directions (in this embodiment, three directions) in the pad region 10.

The first lower wiring portion 66 includes a first lower line portion 69 and a plurality of second lower line portions 70A and 70B. The first lower line portion 69 is disposed at the street region 11 side with respect to the resistive film 60 in the pad region 10. The first lower line portion 69 is disposed on the first principal surface 3 to be mutually adjacent to the resistive film 60 such as to face the gate electrode film 64 with the resistive film 60 interposed therebetween in plan view. The first lower line portion 69 faces the boundary well region 40 (the first boundary well region 40A) with the principal surface insulating film 45 interposed therebetween in the thickness direction.

The first lower line portion 69 is formed in a band shape extending in the second direction Y along the resistive film 60. The first lower line portion 69 has a length larger than a length of the resistive film 60 and a length of the gate electrode film 64 in the second direction Y. The first lower line portion 69 has one end portion at one side (the first side surface 5A side) in the second direction Y and another end portion at the other side (the second side surface 5B side) in the second direction Y.

The plurality of second lower line portions 70A and 70B include the second lower line portion 70A at one side and the second lower line portion 70B at another side. The second lower line portion 70A is disposed in a region at one side (the first side surface 5A side) in the second direction Y with respect to the resistive film 60 and the gate electrode film 64 in the pad region 10. The second lower line portion 70B is disposed in a region at the other side (the second side surface 5B side) in the second direction Y with respect to the resistive film 60 and the gate electrode film 64 in the pad region 10.

The second lower line portion 70A is formed in a band shape extending in the first direction X and has one end portion connected to the one end portion of the first lower line portion 69 and another end portion positioned at the peripheral edge side (the third side surface 5C side) of the chip 2. The second lower line portion 70A is further connected to the first end portion 60A of the resistive film 60 and formed at an interval from the gate electrode film 64. That is, the second lower line portion 70A constitutes the first connection portion with respect to the first end portion 60A. The second lower line portion 70A faces the boundary well region 40 (the first boundary well region 40A) with the principal surface insulating film 45 interposed therebetween in the thickness direction.

The second lower line portion 70B is formed in a band shape extending in the first direction X and has one end portion connected to the other end portion of the first lower line portion 69 and another end portion positioned at the peripheral edge side (the third side surface 5C side) of the chip 2. The second lower line portion 70B at the other side is further connected to the second end portion 60B of the resistive film 60 and formed at an interval from the gate electrode film 64.

That is, the second lower line portion 70B constitutes the second connection portion with respect to the second end portion 60B. The second lower line portion 70B at the other side faces the second lower line portion 70A at the one side with the gate electrode film 64 interposed therebetween. The second lower line portion 70B at the other side faces the boundary well region 40 (the first boundary well region 40A) with the principal surface insulating film 45 interposed therebetween in the thickness direction.

The second lower wiring portion 67 is routed to the street region 11. Specifically, the second lower wiring portion 67 is led out from the first lower wiring portion 66 to the street region 11. More specifically, the second lower wiring portion 67 is led out from an inner portion (in this embodiment, a central portion) of the first lower line portion 69 to the street region 11 and is formed in a band shape extending in the first direction X.

In this embodiment, the second lower wiring portion 67 crosses a center of the chip 2. The second lower wiring portion 67 extends in a band shape such as to be positioned in a region at one side (the third side surface 5C side) and a region at the other side (the fourth side surface 5D side) in the first direction X with respect to the straight line crossing the center of the first principal surface 3 in the second direction Y. The second lower wiring portion 67 has one end portion connected to the first lower line portion 69 (the first lower wiring portion 66) at one side in the first direction X and another end portion at the other side in the first direction X.

The second lower wiring portion 67 faces the boundary well region 40 (the second boundary well region 40B) with the principal surface insulating film 45 interposed therebetween in the thickness direction. The second lower wiring portion 67 has a width larger than the width of the street region 11 in the second direction Y and is led out from the street region 11 to the plurality of active regions 6. The second lower wiring portion 67 covers the plurality of trench separation structures 15 in the plurality of active regions 6.

Also, the second lower wiring portion 67 covers the end portions of the plurality of first trench structures 21 in the plurality of active regions 6. Consequently, the second lower wiring portion 67 is electrically connected to the plurality of separation embedded electrodes 18 and the plurality of first embedded electrodes 24 and transmits the gate potential to the plurality of separation embedded electrodes 18 and the plurality of first embedded electrodes 24.

In this embodiment, the second lower wiring portion 67 is integrally formed with the plurality of separation embedded electrodes 18 and the plurality of first embedded electrodes 24. That is, the second lower wiring portion 67 is constituted of a portion where a part of the plurality of separation embedded electrodes 18 and a part of the plurality of first embedded electrodes 24 are led out in film shapes onto the first principal surface 3 (the principal surface insulating film 45). As a matter of course, the second lower wiring portion 67 may be formed separately from the plurality of separation embedded electrodes 18 and the plurality of first embedded electrodes 24 instead.

The third lower wiring portion 68 is routed to the outer peripheral region 9. Specifically, the third lower wiring portion 68 is led out from the first lower wiring portion 66 to the outer peripheral region 9. More specifically, the third lower wiring portion 68 is led out from the other end portions of the plurality of second lower line portions 70A and 70B to one side (the first side surface 5A side) and the other side (the second side surface 5B side) of the outer peripheral region 9 and is formed in a band shape extending along the outer peripheral region 9.

The third lower wiring portion 68, together with the second lower wiring portion 67, sandwiches the plurality of active regions 6. Specifically, the third lower wiring portion 68 extends along the peripheral edge (the first side surface 5A to the fourth side surface 5D) of the chip 2 such as to surround the plurality of active regions 6 in plan view and is connected to the other end portion of the second lower wiring portion 67. Thereby, the third lower wiring portion 68, together with the second lower wiring portion 67, surrounds the plurality of active regions 6.

The third lower wiring portion 68 faces an inner portion of the outer peripheral well region 41 with the principal surface insulating film 45 interposed therebetween. Specifically, the third lower wiring portion 68 faces the inner portion of the outer peripheral well region 41 at intervals inward from an inner edge and an outer edge of the outer peripheral well region 41 in plan view.

With reference to FIG. 3, the third lower wiring portion 68 has, in portions extending along the first side surface 5A, a plurality of lead-out portions 68a that are led out to the plurality of active regions 6 from the outer peripheral region 9. The plurality of lead-out portions 68a cover the first trench separation structure 15A at intervals in the first direction X at the first active region 6A side and covers the second trench separation structure 15B at intervals in the first direction X at the second active region 6B side.

That is, the plurality of lead-out portions 68a cover the end portions of the plurality of first trench structures 21. Consequently, in the first active region 6A, the third lower wiring portion 68 is electrically connected to the plurality of separation embedded electrodes 18 and the plurality of first embedded electrodes 24 and transmits the gate potential to the plurality of separation embedded electrodes 18 and the plurality of first embedded electrodes 24.

As a matter of course, a single lead-out portion 68a extending in a band shape along the first trench separation structure 15A may be formed at the first active region 6A side instead. Also, a single lead-out portion 68a extending in a band shape along the second trench separation structure 15B may be formed at the second active region 6B side.

In this embodiment, the third lower wiring portion 68 is integrally formed with the plurality of separation embedded electrodes 18 and the plurality of first embedded electrodes 24. That is, the third lower wiring portion 68 is constituted of a portion where a part of the plurality of separation embedded electrodes 18 and a part of the plurality of first embedded electrodes 24 are led out in film shapes onto the first principal surface 3 (the principal surface insulating film 45). As a matter of course, the third lower wiring portion 68 may be formed separately from the plurality of separation embedded electrodes 18 and the plurality of first embedded electrodes 24 instead.

With reference to FIG. 11 to FIG. 15, the semiconductor device 1A includes a first slit 71 demarcated in a region between the resistive film 60 and the gate electrode film 64. The first slit 71 is formed in a band shape extending in the second direction Y in plan view and demarcates the first to third covering portions 61 to 63 of the resistive film 60.

The first slit 71 exposes the principal surface insulating film 45. The first slit 71 is formed outside the plurality of trench resistive structures 51 in plan view and faces the boundary well region 40 (the first boundary well region 40A) in the thickness direction. That is, the first slit 71 does not face the trench resistive structures 51 in the thickness direction.

The first slit 71 has a first length in the second direction Y. The first slit 71 is formed to be narrower than the gate electrode film 64 in the first direction X. The first slit 71 is preferably formed to be narrower than the resistive film 60 in the first direction X. The first slit 71 is preferably formed to be narrower than the first trench group 52 in the first direction X. The first slit 71 is preferably formed to be wider than each trench resistive structure 51 in the first direction X.

A width of the first slit 71 may be not less than 0.1 μm and not more than 10 μm. The width of the first slit 71 may be not less than 0.1 μm and not more than 0.5 μm, not less than 0.5 μm and not more than 1 μm, not less than 1 μm and not more than 2.5 μm, not less than 2.5 μm and not more than 5 μm, not less than 5 μm and not more than 7.5 μm, or not less than 7.5 μm and not more than 10 μm. The width of the first slit 71 is preferably not less than 3 μm and not more than 7 μm.

With reference to FIG. 11 to FIG. 15, the semiconductor device 1A includes a second slit 72 demarcated in a region between the resistive film 60 and the gate wiring film 65. Specifically, the second slit 72 is demarcated in a region between the resistive film 60 and the first lower line portion 69. The second slit 72 faces the first slit 71 with the resistive film 60 interposed therebetween.

The second slit 72 is formed in a band shape extending in the second direction Y in plan view and demarcates the first to third covering portions 61 to 63 of the resistive film 60. That is, the second slit 72 extends in parallel to the first slit 71 and, together with the first slit 71, demarcates the resistive film 60. The second slit 72 exposes the principal surface insulating film 45.

The second slit 72 is formed outside the plurality of trench resistive structures 51 in plan view and faces the boundary well region 40 (the first boundary well region 40A) in the thickness direction. That is, the second slit 72 does not face the trench resistive structures 51 in the thickness direction. The second slit 72 faces the first slit 71 with the plurality of first trench resistive structures 51A and the plurality of second trench resistive structures 51B interposed therebetween in plan view.

The second slit 72 has a second length in the second direction Y. The second length may be different from the first length of the first slit 71. The second length is preferably not more than the first length from the viewpoint of appropriately connecting the resistive film 60 and the gate wiring film 65. In this embodiment, the second length is less than the first length. As a matter of course, the second length may be substantially equal to the first length instead. Also, the second length may be larger than the first length.

The second slit 72 is formed to be narrower than the gate electrode film 64 in the first direction X. The second slit 72 is preferably formed to be narrower than the first lower line portion 69 in the first direction X. The second slit 72 is particularly preferably formed to be narrower than the resistive film 60 in the first direction X. The second slit 72 is preferably formed to be narrower than the first trench group 52 in the first direction X. The second slit 72 is preferably formed to be wider than each trench resistive structure 51.

A width of the second slit 72 may be not less than 0.1 μm and not more than 10 μm. The width of the second slit 72 may be not less than 0.1 μm and not more than 0.5 μm, not less than 0.5 μm and not more than 1 μm, not less than 1 μm and not more than 2.5 μm, not less than 2.5 μm and not more than 5 μm, not less than 5 μm and not more than 7.5 μm, or not less than 7.5 μm and not more than 10 μm. The width of the second slit 72 is preferably not less than 3 μm and not more than 7 μm. The width of the second slit 72 may be not less than the width of the first slit 71. The width of the second slit 72 may be less than the width of the first slit 71. The width of the second slit 72 may be substantially equal to the width of the first slit 71.

With reference to FIG. 11 to FIG. 15, the semiconductor device 1A includes a plurality of third slits 73 demarcated in regions between the gate electrode film 64 and the gate wiring film 65. Specifically, the plurality of third slits 73 are demarcated in regions between the gate electrode film 64 and the plurality of second lower line portions 70A and 70B, respectively.

Each of the plurality of third slits 73 is formed in a band shape extending in the first direction X in plan view and exposes the principal surface insulating film 45. The plurality of third slits 73 are connected to the first slit 71 and face each other in the second direction Y with the gate electrode film 64 interposed therebetween. That is, the plurality of third slits 73, together with the first slit 71, demarcate the gate electrode film 64. Also, the plurality of third slits 73, together with the first slit 71, physically and electrically separate the gate electrode film 64 from the gate wiring film 65.

Each third slit 73 is formed to be narrower than the gate electrode film 64. The third slit 73 is preferably formed to be narrower than the second lower line portions 70A and 70B. The third slit 73 is particularly preferably formed to be narrower than the resistive film 60. The third slit 73 is preferably formed to be narrower than the first trench group 52 (the second trench group 53). The third slit 73 is preferably formed to be wider than each trench resistive structure 51.

A width of each third slit 73 may be not less than 0.1 μm and not more than 10 μm. The width of the third slit 73 may be not less than 0.1 μm and not more than 0.5 μm, not less than 0.5 μm and not more than 1 μm, not less than 1 μm and not more than 2.5 μm, not less than 2.5 μm and not more than 5 μm, not less than 5 μm and not more than 7.5 μm, or not less than 7.5 μm and not more than 10 μm. The width of the third slit 73 is preferably not less than 3 μm and not more than 7 μm. The width of the third slit 73 may be not less than the width of the first slit 71. The width of the third slit 73 may be less than the width of the first slit 71. The width of the third slit 73 may be substantially equal to the width of the first slit 71.

The semiconductor device 1A includes an interlayer insulating film 74 that covers the principal surface insulating film 45. The interlayer insulating film 74 is thicker than the principal surface insulating film 45. The interlayer insulating film 74 may have a single layer structure including a single insulating film or a laminated structure including a plurality of insulating films. The interlayer insulating film 74 may include at least one among a silicon oxide film, a silicon nitride film, and an aluminum oxide film.

The interlayer insulating film 74 may have a laminated structure including a plurality of silicon oxide films. In this case, the interlayer insulating film 74 may include at least one among an NSG (non-doped silicate glass) film, a PSG (phosphor silicate glass) film, and a BPSG (boron phosphor silicate glass) film as an example of a silicon oxide film. The order of lamination of the NSG film, the PSG film, and the BPSG film is arbitrary.

The interlayer insulating film 74 covers the principal surface insulating film 45 in the active regions 6, the boundary region 8, and the outer peripheral region 9. In the active regions 6, the interlayer insulating film 74 covers the plurality of trench separation structures 15, the plurality of first trench structures 21, and the plurality of second trench structures 25.

In the pad region 10, the interlayer insulating film 74 covers the plurality of trench resistive structures 51 (resistance embedded electrodes 56), the resistive film 60, the gate electrode film 64, and the gate wiring film 65. In the pad region 10, the interlayer insulating film 74 covers the boundary well region 40 (the first boundary well region 40A) with the principal surface insulating film 45 interposed therebetween. In the outer peripheral region 9, the interlayer insulating film 74 selectively covers the outer peripheral well region 41, the FLRs 42, and the channel stop region 43 with the principal surface insulating film 45 interposed therebetween. A laminated film of the principal surface insulating film 45 and the interlayer insulating film 74 is an example of an “insulating film” in the present disclosure.

The interlayer insulating film 74 enters into the first slit 71 from above the resistive film 60 and the gate electrode film 64 and has a portion that covers the principal surface insulating film 45 inside the first slit 71. That is, inside the first slit 71, the interlayer insulating film 74 faces the boundary well region 40 (the first boundary well region 40A) with the principal surface insulating film 45 interposed therebetween in the thickness direction. Inside the first slit 71, the interlayer insulating film 74 electrically insulates the resistive film 60 and the gate electrode film 64.

The interlayer insulating film 74 enters into the second slit 72 from above the resistive film 60 and the gate wiring film 65 (the first lower line portion 69) and has a portion that covers the principal surface insulating film 45 inside the second slit 72. That is, inside the second slit 72, the interlayer insulating film 74 faces the boundary well region 40 (the first boundary well region 40A) with the principal surface insulating film 45 interposed therebetween in the thickness direction. Inside the second slit 72, the interlayer insulating film 74 electrically insulates the resistive film 60 and the gate wiring film 65 (the first lower line portion 69).

The interlayer insulating film 74 enters into the plurality of third slits 73 from above the gate electrode film 64 and the gate wiring film 65 (the second lower line portions 70A and 70B) and has portions that cover the principal surface insulating film 45 inside the plurality of third slits 73. That is, inside the plurality of third slits 73, the interlayer insulating film 74 faces the boundary well region 40 (the first boundary well region 40A) with the principal surface insulating film 45 interposed therebetween in the thickness direction.

Inside the plurality of third slits 73, the interlayer insulating film 74 electrically insulates the gate electrode film 64 and the gate wiring film 65. The interlayer insulating film 74 has an insulating principal surface 75 extending along the first principal surface 3 (the principal surface insulating film 45). The insulating principal surface 75 has, in the pad region 10, a first recess portion 76, a second recess portion 77, and a plurality of third recess portions 78 (see FIG. 16 to FIG. 22). The first recess portion 76 is formed in a portion that covers the first slit 71. The first recess portion 76 is recessed toward the first slit 71 and is formed in a band shape extending in the second direction Y along the first slit 71 in plan view.

The second recess portion 77 is formed in a portion that covers the second slit 72. The second recess portion 77 is recessed toward the second slit 72 and is formed in a band shape extending in the second direction Y along the second slit 72 in plan view. The plurality of third recess portions 78 are formed in portions covering the plurality of third slits 73, respectively. Each of the plurality of third recess portions 78 is recessed toward the corresponding third slit 73 and is formed in a band shape extending in the first direction X along the corresponding third slit 73 in plan view.

With reference to FIG. 11 to FIG. 22, the semiconductor device 1A includes at least one (in this embodiment, a plurality) of first resistance connection electrodes 81 embedded in the interlayer insulating film 74 such as to be electrically connected to the resistive film 60. The first resistance connection electrodes 81 may be referred to as “first resistance via electrodes.” Each first resistance connection electrode 81 may include at least one type among a Ti film, a TiN film, a W film, an Al film, a Cu film, an Al alloy film, a Cu alloy film, and a conductive polysilicon film. In this embodiment, the first resistance connection electrodes 81 has a laminated structure including a Ti film and a W film.

In this embodiment, the plurality of first resistance connection electrodes 81 are connected to the first covering portion 61 of the resistive film 60. That is, the plurality of first resistance connection electrodes 81 are connected to a portion of the resistive film 60 covering a region outside the plurality of trench resistive structures 51. Specifically, the plurality of first resistance connection electrodes 81 are connected to a portion of the resistive film 60 covering the space region 57 between the first trench group 52 (the plurality of first trench resistive structures 51A) and the second trench group 53 (the plurality of second trench resistive structures 51B).

The plurality of first resistance connection electrodes 81 are formed in regions at intervals in the second direction Y from the plurality of trench resistive structures 51 in plan view and do not face the plurality of trench resistive structures 51 in the first direction X. In this embodiment, the plurality of first resistance connection electrodes 81 are each formed in a band shape extending in the first direction X in plan view and are disposed at intervals in the second direction Y. That is, the plurality of first resistance connection electrodes 81 are aligned in a stripe shape extending in the first direction X in plan view.

The plurality of first resistance connection electrodes 81 extend in a direction intersecting (in this embodiment, orthogonal to) the extending direction of the resistive film 60 (the plurality of trench resistive structures 51). That is, the plurality of first resistance connection electrodes 81 intersect (are orthogonal to) a current direction of the resistive film 60. As a result, a current can be spread appropriately with respect to the resistive film 60 from the plurality of first resistance connection electrodes 81. That is, current constriction caused by the layout of the plurality of first resistance connection electrodes 81 is suppressed, and an undesirable variation (increase) in the resistance value caused by the current constriction is suppressed.

The plurality of first resistance connection electrodes 81 face just the flat portion of the first principal surface 3 with the resistive film 60 interposed therebetween and do not face the trench resistive structures 51 with the resistive film 60 interposed therebetween. The plurality of first resistance connection electrodes 81 face the boundary well region 40 (the first boundary well region 40A) with the resistive film 60 and the principal surface insulating film 45 interposed therebetween. The plurality of first resistance connection electrodes 81 are formed in a region sandwiched by the first slit 71 and the second slit 72 at intervals from the first slit 71 and the second slit 72 in plan view.

That is, the plurality of first resistance connection electrodes 81 are each formed to be narrower than the resistive film 60 in the first direction X. In plan view, the plurality of first resistance connection electrodes 81 face one or a plurality of first trench resistive structures 51A at one side (the first side surface 5A side) in the second direction Y and face one or a plurality of second trench resistive structures 51B at the other side (the second side surface 5B side) in the second direction Y.

The plurality of first resistance connection electrodes 81 suffice to face at least two of the plurality of first trench resistive structures 51A in the second direction Y and do not have to face all of the first trench resistive structures 51A. In this embodiment, the plurality of first resistance connection electrodes 81 face a part of the plurality of first trench resistive structures 51A in the second direction Y. As a matter of course, the plurality of first resistance connection electrodes 81 may face all of the first trench resistive structures 51A in the second direction Y instead.

Similarly, the plurality of first resistance connection electrodes 81 suffice to face at least two of the plurality of second trench resistive structures 51B in the second direction Y and do not have to face all of the second trench resistive structures 51B. In this embodiment, the plurality of first resistance connection electrodes 81 face a part of the plurality of second trench resistive structures 51B in the second direction Y. As a matter of course, the plurality of first resistance connection electrodes 81 may face all of the second trench resistive structures 51B in the second direction Y instead.

The plurality of first resistance connection electrodes 81 have a first connection area S1 with respect to the resistive film 60. The first connection area S1 is defined by a total plane area of the plurality of first resistance connection electrodes 81. When a single first resistance connection electrode 81 is formed, the first connection area S1 is defined by a plane area of the single first resistance connection electrode 81. The first connection area S1 is adjusted according to a first current I1 flowing through the first resistance connection electrodes 81 (see FIG. 12).

With reference to FIG. 11 to FIG. 22, the semiconductor device 1A includes at least one (in this embodiment, a plurality) of second resistance connection electrodes 82 embedded in the interlayer insulating film 74 such as to be electrically connected to the resistive film 60 at a location different from the first resistance connection electrodes 81. The second resistance connection electrodes 82 may be referred to as “second resistance via electrodes.”

Each second resistance connection electrode 82 may include at least one type among a Ti film, a TiN film, a W film, an Al film, a Cu film, an Al alloy film, a Cu alloy film, and a conductive polysilicon film. In this embodiment, the second resistance connection electrode 82 has a laminated structure including a Ti film and a W film.

In this embodiment, the plurality of second resistance connection electrodes 82 are connected to the second covering portion 62 of the resistive film 60. That is, the plurality of second resistance connection electrodes 82 are embedded in a portion of the resistive film 60 covering the first trench group 52 (the plurality of first trench resistive structures 51A).

The plurality of second resistance connection electrodes 82, with the plurality of first resistance connection electrodes 81, form a first gate resistance R1. The first gate resistance R1 is constituted of a portion of the resistive film 60 and the plurality of first trench resistive structures 51A that is positioned in a region between the plurality of first resistance connection electrodes 81 and the plurality of second resistance connection electrodes 82. A resistance value of the first gate resistance R1 is adjusted by a distance between the plurality of first resistance connection electrodes 81 and the plurality of second resistance connection electrodes 82.

The plurality of second resistance connection electrodes 82 are formed in regions facing the plurality of first trench resistive structures 51A in the first direction X in plan view. In this embodiment, the plurality of second resistance connection electrodes 82 extend in a different direction from the first resistance connection electrodes 81 in plan view. Specifically, the plurality of second resistance connection electrodes 82 are each formed in a band shape extending in the second direction Y in plan view and are aligned at intervals in the first direction X. That is, the plurality of second resistance connection electrodes 82 are aligned in a stripe shape extending in the second direction Y in plan view.

In plan view, the plurality of second resistance connection electrodes 82 are respectively disposed, at intervals from the plurality of first trench resistive structures 51A, in regions between the plurality of first trench resistive structures 51A that are mutually adjacent. That is, the plurality of second resistance connection electrodes 82 are aligned alternately with the plurality of first trench resistive structures 51A in the first direction X.

Also, in this embodiment, the plurality of second resistance connection electrodes 82 face just the flat portion of the first principal surface 3 with the resistive film 60 interposed therebetween and do not face the trench resistive structures 51 with the resistive film 60 interposed therebetween. The plurality of second resistance connection electrodes 82 face the boundary well region 40 (the first boundary well region 40A) with the resistive film 60 and the principal surface insulating film 45 interposed therebetween.

The plurality of second resistance connection electrodes 82 suffice to be disposed in a part of the regions between the plurality of first trench resistive structures 51A and do not necessarily have to be disposed in all of the regions between the plurality of first trench resistive structures 51A. The plurality of second resistance connection electrodes 82 suffice to be disposed in at least one region positioned at the active region 6 side among the regions between the plurality of first trench resistive structures 51A and do not have to be disposed in at least one region positioned at the gate electrode film 64 side.

It is preferable that at least one of the plurality of second resistance connection electrodes 82 faces the plurality of first resistance connection electrodes 81 in the second direction Y in plan view. In this case, at least one of the plurality of second resistance connection electrodes 82 that is positioned at the gate electrode film 64 side preferably faces the plurality of first resistance connection electrodes 81 in the second direction Y.

At least one of the plurality of second resistance connection electrodes 82 that is positioned at the active region 6 side does not have to face the plurality of first resistance connection electrodes 81 in the second direction Y. As a matter of course, all of the second resistance connection electrodes 82 may be disposed such as to face the plurality of first resistance connection electrodes 81 in the second direction Y.

The plurality of second resistance connection electrodes 82 have a length less than the length of the plurality of first trench resistive structures 51A in the second direction Y. The plurality of second resistance connection electrodes 82 are preferably disposed in regions at the other end portion side of the plurality of first trench resistive structures 51A with respect to length direction intermediate portions of the plurality of first trench resistive structures 51A.

The length of the plurality of second resistance connection electrodes 82 is preferably not less than 1/100 and not more than ½ of the length of the plurality of first trench resistive structures 51A. The length of the plurality of second resistance connection electrodes 82 may be not less than 1/20 and not more than ¼ of the length of the plurality of first trench resistive structures 51A.

The plurality of second resistance connection electrodes 82 have a second connection area S2 with respect to the resistive film 60. The second connection area S2 is defined by a total plane area of the plurality of second resistance connection electrodes 82. When a single second resistance connection electrode 82 is formed, the second connection area S2 is defined by a plane area of the single second resistance connection electrode 82.

The second connection area S2 may be substantially equal to the first connection area S1. The second connection area S2 may be larger than the first connection area S1. The second connection area S2 may be less than the first connection area S1. The second connection area S2 is adjusted according to a current ratio I2/I1 (shunt ratio) of a second current I2 flowing through the second resistance connection electrodes 82 to the first current I1 flowing through the first resistance connection electrodes 81 (see FIG. 12).

In this case, a value of an area ratio S2/S1 of the second connection area S2 to the first connection area S1 is preferably set to be not less than the value of the current ratio I2/I1. For example, when the current ratio I2/I1 is 1, the area ratio S2/S1 is preferably set to not less than 1. For example, when the current ratio I2/I1 is ½, the area ratio S2/S1 is preferably set to not less than ½.

When the current ratio I2/I1 is ¼, the area ratio S2/S1 is preferably set to not less than ¼. In this embodiment, the current ratio I2/I1 is substantially ½, and the second connection area S2 is not less than ½ times the first connection area S1. The second connection area S2 is preferably not more than twice the first connection area S1.

With reference to FIG. 11 to FIG. 22, the semiconductor device 1A includes at least one (in this embodiment, a plurality) of third resistance connection electrodes 83 embedded in the interlayer insulating film 74 such as to be electrically connected to the resistive film 60 at a location different from the first resistance connection electrodes 81 and the second resistance connection electrodes 82. The third resistance connection electrodes 83 may be referred to as “third resistance via electrodes.”

Each third resistance connection electrode 83 may include at least one type among a Ti film, a TiN film, a W film, an Al film, a Cu film, an Al alloy film, a Cu alloy film, and a conductive polysilicon film. In this embodiment, the third resistance connection electrode 83 has a laminated structure including a Ti film and a W film.

In this embodiment, the plurality of third resistance connection electrodes 83 are connected to the third covering portion 63 of the resistive film 60. That is, the plurality of third resistance connection electrodes 83 are embedded in a portion of the resistive film 60 covering the second trench group 53 (the plurality of second trench resistive structures 51B).

The plurality of third resistance connection electrodes 83, with the plurality of first resistance connection electrodes 81, form a second gate resistance R2. The second gate resistance R2 is constituted of a portion of the resistive film 60 and the plurality of second trench resistive structures 51B that is positioned in a region between the plurality of first resistance connection electrodes 81 and the plurality of third resistance connection electrodes 83.

A resistance value of the second gate resistance R2 is adjusted by a distance between the plurality of first resistance connection electrodes 81 and the plurality of third resistance connection electrodes 83. In this embodiment, the resistance value of the second gate resistance R2 is substantially equal to the resistance value of the first gate resistance R1. Also, the distance between the plurality of first resistance connection electrodes 81 and the plurality of third resistance connection electrodes 83 is substantially equal to the distance between the plurality of first resistance connection electrodes 81 and the plurality of second resistance connection electrodes 82.

As a matter of course, the resistance value of the second gate resistance R2 may be different from the resistance value of the first gate resistance R1. In this case, the distance between the plurality of first resistance connection electrodes 81 and the plurality of third resistance connection electrodes 83 may be different from the distance between the plurality of first resistance connection electrodes 81 and the plurality of second resistance connection electrodes 82.

For example, the resistance value of the second gate resistance R2 may be less than the resistance value of the first gate resistance R1. In this case, the distance between the plurality of first resistance connection electrodes 81 and the plurality of third resistance connection electrodes 83 may be set to be less than the distance between the plurality of first resistance connection electrodes 81 and the plurality of second resistance connection electrodes 82.

For example, the resistance value of the second gate resistance R2 may be larger than the resistance value of the first gate resistance R1. In this case, the distance between the plurality of first resistance connection electrodes 81 and the plurality of third resistance connection electrodes 83 may be set to be larger than the distance between the plurality of first resistance connection electrodes 81 and the plurality of second resistance connection electrodes 82.

The plurality of third resistance connection electrodes 83 are formed in regions facing the plurality of second trench resistive structures 51B in the first direction X in plan view. In this embodiment, the plurality of third resistance connection electrodes 83 extend in a different direction from the first resistance connection electrodes 81 in plan view. Specifically, the plurality of third resistance connection electrodes 83 are each formed in a band shape extending in the second direction Y in plan view and are aligned at intervals in the first direction X. That is, the plurality of third resistance connection electrodes 83 are aligned in a stripe shape extending in the second direction Y in plan view.

In plan view, the plurality of third resistance connection electrodes 83 are respectively disposed, at intervals from the plurality of second trench resistive structures 51B, in regions between the plurality of second trench resistive structures 51B that are mutually adjacent. That is, the plurality of third resistance connection electrodes 83 are aligned alternately with the plurality of second trench resistive structures 51B in the first direction X.

Also, in this embodiment, the plurality of third resistance connection electrodes 83 face just the flat portion of the first principal surface 3 with the resistive film 60 interposed therebetween and do not face the trench resistive structures 51 with the resistive film 60 interposed therebetween. The plurality of third resistance connection electrodes 83 face the boundary well region 40 (the first boundary well region 40A) with the resistive film 60 and the principal surface insulating film 45 interposed therebetween.

The plurality of third resistance connection electrodes 83 suffice to be disposed in a part of the regions between the plurality of second trench resistive structures 51B and do not necessarily have to be disposed in all of the regions between the plurality of second trench resistive structures 51B. The plurality of third resistance connection electrodes 83 suffice to be disposed in at least one region positioned at the active region 6 side among the regions between the plurality of second trench resistive structures 51B and do not have to be disposed in at least one region positioned at the gate electrode film 64 side.

It is preferable that at least one of the plurality of third resistance connection electrodes 83 faces the plurality of first resistance connection electrodes 81 in the second direction Y in plan view. In this case, at least one of the plurality of third resistance connection electrodes 83 that is positioned at the gate electrode film 64 side preferably faces the plurality of first resistance connection electrodes 81 in the second direction Y.

At least one of the plurality of third resistance connection electrodes 83 that is positioned at the active region 6 side does not have to face the plurality of first resistance connection electrodes 81 in the second direction Y. As a matter of course, all of the third resistance connection electrodes 83 may be disposed such as to face the plurality of first resistance connection electrodes 81 in the second direction Y.

It is preferable that at least one of the plurality of third resistance connection electrodes 83 faces the plurality of second resistance connection electrodes 82 in the second direction Y in plan view. In this embodiment, the number of the plurality of third resistance connection electrodes 83 is set to be equal to the number of the plurality of second resistance connection electrodes 82, and all of the third resistance connection electrodes 83 face all of the second resistance connection electrodes 82 in the second direction Y in a one-to-one correspondence. As a matter of course, the number of third resistance connection electrodes 83 may be larger than the number of second resistance connection electrodes 82 or may be fewer than the number of second resistance connection electrodes 82.

The plurality of third resistance connection electrodes 83 have a length less than the length of the plurality of second trench resistive structures 51B in the second direction Y. The plurality of third resistance connection electrodes 83 are preferably disposed in regions at the other end portion side of the plurality of second trench resistive structures 51B with respect to length direction intermediate portions of the plurality of second trench resistive structures 51B.

The length of the plurality of third resistance connection electrodes 83 is preferably not less than 1/100 and not more than ½ of the length of the plurality of second trench resistive structures 51B. The length of the plurality of third resistance connection electrodes 83 may be not less than 1/20 and not more than ¼ of the length of the plurality of second trench resistive structures 51B. The length of the third resistance connection electrodes 83 may be substantially equal to the length of the second trench resistive structures 51B. The length of the third resistance connection electrodes 83 may be larger than the length of the second trench resistive structures 51B. The length of the third resistance connection electrodes 83 may be smaller than the length of the second trench resistive structures 51B.

The plurality of third resistance connection electrodes 83 have a third connection area S3 with respect to the resistive film 60. The third connection area S3 is defined by a total plane area of the plurality of third resistance connection electrodes 83. When a single third resistance connection electrode 83 is formed, the third connection area S3 is defined by a plane area of the single third resistance connection electrode 83. The third connection area S3 is adjusted according to a current ratio I3/I1 (shunt ratio) of a third current I3 flowing through the third resistance connection electrodes 83 to the first current I1 flowing through the first resistance connection electrodes 81 (see FIG. 12).

In this case, a value of an area ratio S3/S1 of the third connection area S3 to the first connection area S1 is preferably set to be not less than the value of the current ratio I3/I1. For example, when the current ratio I3/I1 is 1, the area ratio S3/S1 is preferably set to not less than 1. For example, when the current ratio I3/I1 is ½, the area ratio S3/S1 is preferably set to not less than ½.

When the current ratio I3/I1 is ¼, the area ratio S3/S1 is preferably set to not less than ¼. In this embodiment, since the third current I3 is substantially equal to the second current I2 and the current ratio I3/I1 is substantially ½, the third connection area S3 is set to not less than ½ times the first connection area S1. The third connection area S3 is preferably not more than twice the first connection area S1. As a matter of course, the third current I3 may be larger than the second current I2 or may be smaller than the second current I2.

With reference to FIG. 3 to FIG. 10A, the semiconductor device 1A includes a plurality of gate connection electrodes 84 embedded in the interlayer insulating film 74 such as to be electrically connected to the gate wiring film 65 in the non-active region 7. The gate connection electrodes 84 may be referred to as “gate via electrodes.” The plurality of gate connection electrodes 84 may each include at least one type among a Ti film, a TiN film, a W film, an Al film, a Cu film, an Al alloy film, a Cu alloy film, and a conductive polysilicon film. In this embodiment, each of the plurality of gate connection electrodes 84 has a laminated structure including a Ti film and a W film.

The plurality of gate connection electrodes 84 include at least one (in this embodiment, a plurality) of first gate connection electrodes 84A and at least one (in this embodiment, a plurality) of second gate connection electrodes 84B. The plurality of first gate connection electrodes 84A are embedded in a portion of the interlayer insulating film 74 covering the second lower wiring portion 67 in the street region 11 and are electrically connected to the second lower wiring portion 67 (see FIG. 7 to FIG. 9). In this embodiment, the plurality of first gate connection electrodes 84A are formed at intervals in the second direction Y and are each formed in a band shape extending in the first direction X.

The plurality of second gate connection electrodes 84B are embedded in a portion of the interlayer insulating film 74 covering the third lower wiring portion 68 in the outer peripheral region 9 and are electrically connected to the third lower wiring portion 68 (see FIG. 3 to FIG. 6). In this embodiment, the plurality of second gate connection electrodes 84B are formed at intervals to an outer edge side from an inner edge side of the third lower wiring portion 68 and are each formed in a band shape extending along the third lower wiring portion 68.

With reference to FIG. 3 and FIG. 4, the semiconductor device 1A includes a plurality of first emitter connection electrodes 85 that penetrate through the principal surface insulating film 45 and are embedded in the interlayer insulating film 74 such as to be electrically connected to the plurality of emitter regions 29 in each active region 6. The first emitter connection electrodes 85 may be referred to as “first emitter via electrodes.”

The plurality of first emitter connection electrodes 85 may each include at least one type among a Ti film, a TiN film, a W film, an Al film, a Cu film, an Al alloy film, a Cu alloy film, and a conductive polysilicon film. In this embodiment, each of the plurality of first emitter connection electrodes 85 has a laminated structure including a Ti film and a W film.

The plurality of first emitter connection electrodes 85 penetrate through the interlayer insulating film 74 and the principal surface insulating film 45 and are respectively embedded in the plurality of contact holes 30. The plurality of first emitter connection electrodes 85 are respectively formed in band shapes extending in the second direction Y along the plurality of first trench structures 21 in plan view. That is, in this embodiment, the plurality of first emitter connection electrodes 85 extend in the same direction as the extending direction of the plurality of second resistance connection electrodes 82 and the extending direction of the plurality of third resistance connection electrodes 83. The plurality of first emitter connection electrodes 85 are each electrically connected to the emitter region 29 and the channel contact region 31 inside the corresponding contact hole 30.

With reference to FIG. 3 and FIG. 5, the semiconductor device 1A includes a plurality of second emitter connection electrodes 86 that penetrate through the principal surface insulating film 45 and are embedded in the interlayer insulating film 74 such as to be electrically connected to the plurality of emitter electrode films 47 in each active region 6. The second emitter connection electrodes 86 may be referred to as “second emitter via electrodes.”

The plurality of second emitter connection electrodes 86 may each include at least one type among a Ti film, a TiN film, a W film, an Al film, a Cu film, an Al alloy film, a Cu alloy film, and a conductive polysilicon film. In this embodiment, the plurality of second emitter connection electrodes 86 each have a laminated structure including a Ti film and a W film. The plurality of second emitter connection electrodes 86 are electrically connected to the second embedded electrodes 28 via the plurality of emitter electrode films 47.

With reference to FIG. 3 to FIG. 6, the semiconductor device 1A includes at least one (in this embodiment, a plurality) of first well connection electrodes 87 that penetrate through the principal surface insulating film 45 and are embedded in the interlayer insulating film 74 such as to be electrically connected to the inner edge of the outer peripheral well region 41. The first well connection electrodes 87 may be referred to as “first well via electrodes.”

The plurality of first well connection electrodes 87 may each include at least one type among a Ti film, a TiN film, a W film, an Al film, a Cu film, an Al alloy film, a Cu alloy film, and a conductive polysilicon film. In this embodiment, the plurality of first well connection electrodes 87 each have a laminated structure including a Ti film and a W film.

In this embodiment, the plurality of first well connection electrodes 87 are disposed at intervals to the outer edge side from the inner edge side of the outer peripheral well region 41. The plurality of first well connection electrodes 87 are disposed at the inner edge side of the outer peripheral well region 41 with respect to a width direction intermediate portion of the outer peripheral well region 41 and are electrically connected to regions at the inner edge side of the outer peripheral well region 41. Specifically, the plurality of first well connection electrodes 87 are disposed in regions between the inner edge of the outer peripheral well region 41 and the third lower wiring portion 68 of the gate wiring film 65. Each of the plurality of first well connection electrodes 87 extends in a band shape along the inner edge of the outer peripheral well region 41.

Each of the plurality of first well connection electrodes 87 has a plurality of segment portions 87a at portions extending in the first direction X (see FIG. 3). The plurality of segment portions 87a are respectively disposed, at intervals from the plurality of lead-out portions 68a of the gate wiring film 65 (the third lower wiring portion 68), in regions between the plurality of lead-out portions 68a. When the single lead-out portion 68a extending in the band shape is formed along each trench separation structure 15, the plurality of segment portions 87a are omitted.

With reference to FIG. 3 to FIG. 6, the semiconductor device 1A includes at least one (in this embodiment, a plurality) of second well connection electrodes 88 that penetrate through the principal surface insulating film 45 and are embedded in the interlayer insulating film 74 such as to be electrically connected to the outer edge of the outer peripheral well region 41. The second well connection electrodes 88 may be referred to as “second well via electrodes.”

The plurality of second well connection electrodes 88 may each include at least one type among a Ti film, a TiN film, a W film, an Al film, a Cu film, an Al alloy film, a Cu alloy film, and a conductive polysilicon film. In this embodiment, the plurality of second well connection electrodes 88 each have a laminated structure including a Ti film and a W film.

The plurality of second well connection electrodes 88 are disposed at intervals to the outer edge side from the inner edge side of the outer peripheral well region 41. The plurality of second well connection electrodes 88 are disposed at the outer edge side of the outer peripheral well region 41 with respect to the width direction intermediate portion of the outer peripheral well region 41 and are electrically connected to regions at the outer edge side of the outer peripheral well region 41. Specifically, the plurality of second well connection electrodes 88 are disposed in regions between the outer edge of the outer peripheral well region 41 and the third lower wiring portion 68 of the gate wiring film 65. Each of the plurality of second well connection electrodes 88 extends in a band shape along the outer edge of the outer peripheral well region 41.

With reference to FIG. 10A and FIG. 10B, the semiconductor device 1A includes a plurality of FLR connection electrodes 89 that penetrate through the principal surface insulating film 45 and are embedded in the interlayer insulating film 74 such as to be electrically connected to the corresponding FLRs 42. In this embodiment, one FLR connection electrode 89 is connected to one FLR 42. As a matter of course, a plurality of FLR connection electrodes 89 may be connected to one FLR 42. The FLR connection electrodes 89 may be referred to as “FLR via electrodes.”

The plurality of FLR connection electrodes 89 may each include at least one type among a Ti film, a TiN film, a W film, an Al film, a Cu film, an Al alloy film, a Cu alloy film, and a conductive polysilicon film. In this embodiment, the plurality of FLR connection electrodes 89 each have a laminated structure including a Ti film and a W film.

The plurality of FLR connection electrodes 89 are each formed in a band shape extending along the corresponding FLR 42. In this embodiment, the plurality of FLR connection electrodes 89 are each formed in an annular shape (quadrangle annular shape) extending along the corresponding FLR 42. The plurality of FLR connection electrodes 89 are formed in an electrically floating state.

With reference to FIG. 1 and FIG. 11 to FIG. 22, the semiconductor device 1A includes the gate terminal electrode 90 disposed on the first principal surface 3 such as to be electrically connected to the gate resistive structure 50 in the pad region 10 (non-active region 7). Specifically, the gate terminal electrode 90 is disposed on the interlayer insulating film 74. The gate terminal electrode 90 may be referred to as a “gate pad” or a “gate pad electrode.”

The gate terminal electrode 90 is preferably constituted of a conductive material different from the resistive film 60. The gate terminal electrode 90 is preferably constituted of a conductive material different from the gate electrode film 64. The gate terminal electrode 90 has a lower resistance value than the trench resistive structures 51 and the resistive film 60 and is electrically connected to the trench resistive structures 51 via the resistive film 60. The gate terminal electrode 90 has a lower resistance value than the gate electrode film 64.

In this embodiment, the gate terminal electrode 90 is constituted of a metal film. The gate terminal electrode 90 may also be referred to as a “gate metal terminal.” The gate terminal electrode 90 may include at least one type among a Ti film, a TiN film, a W film, an Al film, a Cu film, an Al alloy film, a Cu alloy film, and a conductive polysilicon film.

The gate terminal electrode 90 may include at least one among a pure Cu film (Cu film having a purity of 99% or more), a pure Al film (Al film having a purity of 99% or more), an AlCu alloy film, an AlSi alloy film, and an AlSiCu alloy film. In this embodiment, the gate terminal electrode 90 has a laminated structure that includes a Ti film and an Al alloy film (in this embodiment, an AlCu alloy film) laminated in that order from the chip 2 side.

The gate terminal electrode 90 preferably has a thickness larger than the thickness of the resistive film 60 (the thickness of the gate electrode film 64). The thickness of the gate terminal electrode 90 may be not less than 1 μm and not more than 10 μm. The gate terminal electrode 90 preferably has a plane area of not less than 1% and not more than 30% of the plane area of the first principal surface 3. The plane area of the gate terminal electrode 90 is particularly preferably not more than 25% of the plane area of the first principal surface 3. The plane area of the gate terminal electrode 90 may be not more than 10% of the plane area of the first principal surface 3.

The gate terminal electrode 90 is disposed on the interlayer insulating film 74 such as to cover the resistive film 60 and the gate electrode film 64 in the pad region 10. The gate terminal electrode 90 covers the plurality of first resistance connection electrodes 81 in a portion that covers the resistive film 60 and is electrically connected to the plurality of first resistance connection electrodes 81. That is, the gate terminal electrode 90 is electrically connected to the resistive film 60 (the first covering portion 61) via the plurality of first resistance connection electrodes 81.

With reference to FIG. 11 to FIG. 22 (particularly FIG. 11 to FIG. 13), the gate terminal electrode 90 includes a first electrode portion 91 and a second electrode portion 92. The first electrode portion 91 has a comparatively wide electrode width in the second direction Y. The first electrode portion 91 is a portion that forms a terminal main body of the gate terminal electrode 90 and is positioned in a region outside the first resistance connection electrodes 81 in plan view. The first electrode portion 91 may be referred to as a “terminal main body portion.”

For example, a bonding wire is connected to the first electrode portion 91. Therefore, the first electrode portion 91 is formed to be wider than a joint portion of the bonding wire. The first electrode portion 91 is formed in a polygonal shape (in this embodiment, a quadrangle shape) having four sides parallel to the peripheral edge of the chip 2 (a peripheral edge of the pad region 10) in plan view. The first electrode portion 91 is disposed in a region facing the gate electrode film 64 with the interlayer insulating film 74 interposed therebetween.

The first electrode portion 91 preferably covers not less than 50% of the region of the gate electrode film 64 in plan view. The first electrode portion 91 particularly preferably covers not less than 90% of the region of the gate electrode film 64 in plan view. In this embodiment, the first electrode portion 91 has a wider electrode width than the gate electrode film 64 and covers the entire region of the gate electrode film 64.

Flatness of the first electrode portion 91 is enhanced by the gate electrode film 64. The first electrode portion 91 may be electrically insulated from the gate electrode film 64 by the interlayer insulating film 74. The first electrode portion 91 may be electrically connected to the gate electrode film 64 via one or a plurality of the gate connection electrodes 84 embedded in the interlayer insulating film 74.

The first electrode portion 91 covers the first slit 71 with the interlayer insulating film 74 interposed therebetween and backfills the first recess portion 76 of the interlayer insulating film 74 (the insulating principal surface 75). When the gate terminal electrode 90 (the first electrode portion 91) that partially exposes the first recess portion 76 is formed, an electrode residue generated during a step of forming the gate terminal electrode 90 is liable to remain in the first recess portion 76.

When the electrode residue is present, the gate terminal electrode 90 (the first electrode portion 91) is liable to become electrically connected to another electrode via the electrode residue. Therefore, the gate terminal electrode 90 (the first electrode portion 91) preferably covers an entire region of the first slit 71 with the interlayer insulating film 74 interposed therebetween.

That is, the gate terminal electrode 90 (the first electrode portion 91) preferably fills an entire region of the first recess portion 76 of the interlayer insulating film 74 (the insulating principal surface 75). According to this arrangement, a layout that avoids the problem of electrode residue in the first recess portion 76 is provided. The present disclosure does not exclude an embodiment including the gate terminal electrode 90 (the first electrode portion 91) that partially exposes the first recess portion 76.

The first electrode portion 91 is led out from above the gate electrode film 64 to above the resistive film 60 across the first slit 71 in plan view. In this embodiment, the first electrode portion 91 covers an edge portion of the resistive film 60 with the interlayer insulating film 74 interposed therebetween. Specifically, the first electrode portion 91 covers the edge portion of the resistive film 60 at an interval toward the gate electrode film 64 side with respect to the straight line crossing a center portion of the resistive film 60 in the second direction Y.

In a portion covering the resistive film 60, the first electrode portion 91 may cover one or a plurality of the trench resistive structures 51 with the resistive film 60 interposed therebetween. The first electrode portion 91 may cover one or a plurality of the first trench resistive structures 51A with the resistive film 60 interposed therebetween. The first electrode portion 91 may cover one or a plurality of the second trench resistive structures 51B with the resistive film 60 interposed therebetween. In this embodiment, the first electrode portion 91 covers one first trench resistive structure 51A and one second trench resistive structure 51B with the resistive film 60 interposed therebetween.

The first electrode portion 91 covers the plurality of third slits 73 with the interlayer insulating film 74 interposed therebetween and backfills the plurality of third recess portions 78 of the interlayer insulating film 74 (the insulating principal surface 75). When the gate terminal electrode 90 (the first electrode portion 91) that partially exposes the plurality of third recess portions 78 is formed, electrode residues generated during the step of forming the gate terminal electrode 90 are liable to remain in the plurality of third recess portions 78.

When the electrode residues are present, the gate terminal electrode 90 (the first electrode portion 91) is liable to become electrically connected to another electrode via the electrode residues. Therefore, the gate terminal electrode 90 (the first electrode portion 91) preferably covers entire regions of the plurality of third recess portions 78 with the interlayer insulating film 74 interposed therebetween.

That is, the gate terminal electrode 90 (the first electrode portion 91) preferably fills the entire regions of the third recess portions 78 of the interlayer insulating film 74 (the insulating principal surface 75). According to this arrangement, a layout that avoids the problem of electrode residues in the plurality of third recess portions 78 is provided. The present disclosure does not exclude an embodiment including the gate terminal electrode 90 (the first electrode portion 91) that partially exposes the plurality of third recess portions 78.

The first electrode portion 91 is led out from above the gate electrode film 64 to above the plurality of second lower line portions 70A and 70B across the plurality of third slits 73 in plan view. In this embodiment, the first electrode portion 91 covers edge portions of the plurality of second lower line portions 70A and 70B with the interlayer insulating film 74 interposed therebetween.

The second electrode portion 92 has a smaller electrode width than the first electrode portion 91 in the second direction Y and is constituted of a lead-out portion led out in the first direction X such as to protrude from the first electrode portion 91 toward the plurality of first resistance connection electrodes 81. The second electrode portion 92 may be referred to as a “terminal lead-out portion.” For example, a bonding wire is not connected to the second electrode portion 92. Therefore, the second electrode portion 92 is formed to be narrower than a joint portion of the bonding wire.

A protruding direction of the second electrode portion 92 is the same as the extending direction of the plurality of first resistance connection electrodes 81. In this embodiment, the second electrode portion 92 is led out from a central portion of the first electrode portion 91 and covers all of the first resistance connection electrodes 81.

In plan view, the second electrode portion 92 is formed at an interval to the second slit 72 side from the first slit 71 and does not intersect the first slit 71. Further, in plan view, the second electrode portion 92 is formed at an interval to the first slit 71 side from the second slit 72 and does not intersect the second slit 72. That is, the second electrode portion 92 has a width smaller than the width of the resistive film 60 in the first direction X and is disposed just in a region directly above the resistive film 60.

The second electrode portion 92 faces the space region 57 with the principal surface insulating film 45, the resistive film 60, and the interlayer insulating film 74 interposed therebetween. That is, the second electrode portion 92 faces the flat portion of the first principal surface 3 in the thickness direction. Also, the second electrode portion 92 faces the boundary well region 40 (the first boundary well region 40A) in the thickness direction.

In regard to the first direction X, the second electrode portion 92 has a width larger than the width of each trench resistive structure 51 in the first direction X. In regard to the second direction Y, the second electrode portion 92 has a width smaller than the length of each trench resistive structure 51 in the second direction Y. In regard to the second direction Y, the second electrode portion 92 preferably has a width smaller than the space width of the space region 57.

In this embodiment, the second electrode portion 92 is formed at intervals to the space region 57 side from the other end portions (the first trench group 52) of the plurality of first trench resistive structures 51A. Also, in this embodiment, the second electrode portion 92 is formed at intervals to the space region 57 side from the one end portions (the second trench group 53) of the plurality of second trench resistive structures 51B. That is, the second electrode portion 92 faces just the space region 57 in the thickness direction and does not face the plurality of trench resistive structures 51 in the thickness direction.

As a matter of course, the second electrode portion 92 may face the other end portions (the first trench group 52) of the plurality of first trench resistive structures 51A in the thickness direction. Also, the second electrode portion 92 may face the one end portions (the second trench group 53) of the plurality of second trench resistive structures 51B in the thickness direction. In view of the flatness of the second electrode portion 92, the second electrode portion 92 is preferably formed in a region outside the plurality of trench resistive structures 51 at intervals from the plurality of trench resistive structures 51 in plan view.

With reference to FIG. 11 to FIG. 23, the semiconductor device 1A includes the gate wiring electrode 93 disposed on the first principal surface 3 such as to be electrically connected to the gate resistive structure 50 in the pad region 10 (non-active region 7). Specifically, the gate wiring electrode 93 is disposed on the interlayer insulating film 74. The gate wiring electrode 93 may be referred to as a “gate finger” or a “gate finger electrode.”

The gate wiring electrode 93 is preferably constituted of a conductive material different from the resistive film 60. The gate wiring electrode 93 is preferably constituted of a conductive material different from the gate wiring film 65. The gate wiring electrode 93 has a lower resistance value than the trench resistive structure 51 and the resistive film 60 and is electrically connected to the gate terminal electrode 90 via the trench resistive structure 51 and the resistive film 60. The gate wiring electrode 93 has a lower resistance value than the gate wiring film 65.

In this embodiment, the gate wiring electrode 93 is constituted of a metal film. The gate wiring electrode 93 may be referred to as a “gate metal wiring.” The gate wiring electrode 93 may include at least one type among a Ti film, a TiN film, a W film, an Al film, a Cu film, an Al alloy film, a Cu alloy film, and a conductive polysilicon film.

The gate wiring electrode 93 may include at least one among a pure Cu film, a pure Al film, an AlCu alloy film, an AlSi alloy film, and an AlSiCu alloy film. In this embodiment, the gate wiring film 65 has a laminated structure that includes a Ti film and an Al alloy film (in this embodiment, an AlCu alloy film) laminated in that order from the chip 2 side. That is, the gate wiring film 65 has the same electrode constitution as the gate terminal electrode 90.

The gate wiring electrode 93 preferably has a thickness larger than the thickness of the resistive film 60 (the thickness of the gate wiring film 65). The thickness of the gate wiring electrode 93 may be not less than 1 μm and not more than 10 μm. The thickness of the gate wiring electrode 93 is preferably substantially equal to the thickness of the gate terminal electrode 90.

The gate wiring electrode 93 is routed in a region between the active regions 6 and the non-active region 7, is electrically connected to the first trench structures 21 (trench separation structures 15) in the active regions 6, and is electrically connected to the resistive film 60 in the non-active region 7. Specifically, the gate wiring electrode 93 is electrically connected to the first end portion 60A and the second end portion 60B of the resistive film 60 via the gate wiring film 65.

That is, the gate wiring electrode 93 forms, between itself and the gate terminal electrode 90, a parallel resistance circuit PR that includes the first gate resistance R1 and the second gate resistance R2 (see also FIG. 24). The parallel resistance circuit PR constitutes the gate resistance RG interposed between the gate terminal electrode 90 and the gate wiring electrode 93. The parallel resistance circuit PR is also established between the gate electrode film 64 and the gate wiring film 65. A resistance value of the gate resistance RG (the parallel resistance circuit PR) is calculated by a combined resistance (=(R1+R2)/R1·R2) of the first gate resistance R1 and the second gate resistance R2.

In this embodiment, the gate wiring electrode 93 includes a first upper wiring portion 94, a second upper wiring portion 95, and a third upper wiring portion 96. The first upper wiring portion 94 is disposed in the pad region 10 such as to surround the gate terminal electrode 90 from a plurality of directions (in this embodiment, three directions), and is disposed on the first lower wiring portion 66 of the gate wiring film 65 with the interlayer insulating film 74 interposed therebetween.

The first upper wiring portion 94 includes a first upper line portion 97 and a plurality of second upper line portions 98A and 98B. In the pad region 10, the first upper line portion 97 is disposed in a region covering the first lower line portion 69 of the gate wiring film 65 with the interlayer insulating film 74 interposed therebetween and is formed in a band shape extending in the second direction Y.

The first upper line portion 97 has one end portion at one side (the first side surface 5A side) in the second direction Y and another end portion at the other side (the second side surface 5B side) in the second direction Y. The first upper line portion 97 covers the second slit 72 with the interlayer insulating film 74 interposed therebetween and backfills the second recess portion 77 of the interlayer insulating film 74 (the insulating principal surface 75).

When the gate terminal electrode 90 (the first electrode portion 91 and/or the second electrode portion 92) that intersects the second recess portion 77 and the gate wiring electrode 93 (the first upper line portion 97) that partially exposes the second recess portion 77 are formed, electrode residues generated during the step of forming the gate terminal electrode 90 is liable to remain in the plurality of second recess portion 77.

When the electrode residues are present, the gate wiring electrode 93 (the first upper line portion 97) is liable to become electrically connected to the gate terminal electrode 90 via the electrode residues. In this case, the gate wiring electrode 93 (the first upper line portion 97), together with the gate terminal electrode 90 (the first electrode portion 91), forms a short circuit without interposition of the gate resistive structure 50. Therefore, the gate wiring electrode 93 (the first upper line portion 97) preferably covers an entire region of the second slit 72 with the interlayer insulating film 74 interposed therebetween.

That is, the gate wiring electrode 93 (the first upper line portion 97) preferably fills an entire region of the second recess portion 77 of the interlayer insulating film 74 (the insulating principal surface 75). According to this arrangement, a layout that avoids the problem of electrode residue in the second recess portion 77 is provided. The present disclosure does not exclude an embodiment including the gate terminal electrode 90 (the first electrode portion 91 and/or the second electrode portion 92) that intersects the second recess portion 77 and the gate wiring electrode 93 (the first upper line portion 97) that partially exposes the second recess portion 77.

The first upper line portion 97 is led out from above the gate wiring film 65 (the first lower line portion 69) to above the resistive film 60 across the second slit 72 in plan view. The first upper line portion 97 covers an edge portion of the resistive film 60 with the interlayer insulating film 74 interposed therebetween. The first upper line portion 97 may further cross the straight line crossing the center portion of the resistive film 60 in the second direction Y to cover a portion of the resistive film 60 positioned in a region at the gate electrode film 64 side with respect to the straight line.

The first upper line portion 97 is formed at intervals from the first electrode portion 91 and the second electrode portion 92 of the gate terminal electrode 90 in the first direction X. In this embodiment, the first upper line portion 97 has, in a portion along the second electrode portion 92 of the gate terminal electrode 90, a recess portion 97a recessed in the first direction X along the second electrode portion 92.

The first upper line portion 97 includes a first connection region 101 and a second connection region 102. The first connection region 101 is formed in a region at one side (the first side surface 5A side) in the second direction Y with respect to the recess portion 97a and faces the second electrode portion 92 in the second direction Y. The first connection region 101 covers the second covering portion 62 of the resistive film 60 with the interlayer insulating film 74 interposed therebetween. That is, the first connection region 101 covers the first trench group 52 (the plurality of first trench resistive structures 51A) with the interlayer insulating film 74 and the second covering portion 62 of the resistive film 60 interposed therebetween.

The first connection region 101 further covers the plurality of second resistance connection electrodes 82 and is electrically connected to the plurality of second resistance connection electrodes 82. The first connection region 101 is thereby electrically connected to the second covering portion 62 of the resistive film 60 and the first trench group 52 (the plurality of first trench resistive structures 51A) via the plurality of second resistance connection electrodes 82.

The first connection region 101 suffices to cover one or a plurality of the first trench resistive structures 51A mutually adjacent to one or a plurality of the second resistance connection electrodes 82 and does not have to cover all of the first trench resistive structures 51A. As a matter of course, the first connection region 101 may cover all of the first trench resistive structures 51A. The second connection region 102 is formed in a region at the other side (the second side surface 5B side) in the second direction Y with respect to the recess portion 97a and faces the second electrode portion 92 in the second direction Y. The second connection region 102 covers the third covering portion 63 of the resistive film 60 with the interlayer insulating film 74 interposed therebetween. That is, the second connection region 102 covers the second trench group 53 (the plurality of second trench resistive structures 51B) with the interlayer insulating film 74 and the third covering portion 63 of the resistive film 60 interposed therebetween.

The second connection region 102 further covers the plurality of third resistance connection electrodes 83 and is electrically connected to the plurality of third resistance connection electrodes 83. The second connection region 102 is thereby electrically connected to the third covering portion 63 of the resistive film 60 and the second trench group 53 (the plurality of second trench resistive structures 51B) via the plurality of third resistance connection electrodes 83.

The second connection region 102 suffices to cover one or a plurality of the second trench resistive structures 51B mutually adjacent to one or a plurality of the third resistance connection electrodes 83 and does not have to cover all of the second trench resistive structures 51B. As a matter of course, the second connection region 102 may cover all of the second trench resistive structures 51B.

A facing area of the gate wiring electrode 93 (the first upper line portion 97) with respect to the resistive film 60 is preferably larger than a facing area of the gate terminal electrode 90 (the first electrode portion 91 and the second electrode portion 92) with respect to the resistive film 60. As a matter of course, the facing area of the gate wiring electrode 93 may be smaller than the facing area of the gate terminal electrode 90.

When the gate terminal electrode 90 (the first electrode portion 91) that partially exposes the first recess portion 76 and the first upper line portion 97 that intersects the first recess portion 76 are formed, electrode residues generated during the step of forming the gate terminal electrode 90 is liable to remain in the plurality of first recess portion 76.

When the electrode residues are present, the gate wiring electrode 93 (the first upper line portion 97) is liable to become electrically connected to the gate terminal electrode 90 (the first electrode portion 91) via the electrode residues. In this case, the gate wiring electrode 93 (the first upper line portion 97), together with the gate terminal electrode 90 (the first electrode portion 91), forms a short circuit without interposition of the gate resistive structure 50.

Therefore, it is preferable that, in plan view, the first upper line portion 97 is formed at an interval to the second recess portion 77 (the second slit 72) side from the first recess portion 76 (the first slit 71) and does not intersect the first recess portion 76 (the first slit 71). In this embodiment, the gate terminal electrode 90 (the first electrode portion 91) covers the entire region of the first recess portion 76.

That is, in a region above the resistive film 60, the first upper line portion 97 faces the first electrode portion 91 and the second electrode portion 92 of the gate terminal electrode 90 in the first direction X. According to this arrangement, a layout that avoids the problem of electrode residue in the first recess portion 76 is provided. The present disclosure does not exclude an embodiment including the gate terminal electrode 90 (the first electrode portion 91) that partially exposes the first recess portion 76 and the first upper line portion 97 that intersects the first recess portion 76.

The first current I1 applied to the gate terminal electrode 90 (the second electrode portion 92) is transmitted to the first covering portion 61 of the resistive film 60 via the plurality of first resistance connection electrodes 81. The first current I1 transmitted to the first covering portion 61 is divided into the second current I2 at the second covering portion 62 (the first trench group 52) side of the resistive film 60 and the third current I3 at the third covering portion 63 (the second trench group 53) side of the resistive film 60.

The second current I2 is transmitted to the first connection region 101 of the first upper line portion 97 via the plurality of second resistance connection electrodes 82, and the third current I3 is transmitted to the second connection region 102 of the first upper line portion 97 via the plurality of third resistance connection electrodes 83. Thus, the gate wiring electrode 93 (the first upper line portion 97) forms, between itself and the gate terminal electrode 90 (the second electrode portion 92), the parallel resistance circuit PR that includes the first gate resistance R1 and the second gate resistance R2 (see also FIG. 24).

The plurality of second upper line portions 98A and 98B include the second upper line portion 98A at one side and the second upper line portion 98B at the other side. In the pad region 10, the second upper line portion 98A is disposed in a region at one side (the first side surface 5A side) in the second direction Y with respect to the gate terminal electrode 90. In the pad region 10, the second upper line portion 98B is disposed in a region at the other side (the second side surface 5B side) in the second direction Y with respect to the gate terminal electrode 90.

The second upper line portion 98A is formed in a band shape extending in the first direction X and has one end portion connected to the one end portion of the first upper line portion 97 and another end portion positioned at the peripheral edge side (the third side surface 5C side) of the chip 2. The second upper line portion 98A covers the second lower line portion 70A of the gate wiring film 65 with the interlayer insulating film 74 interposed therebetween. The second upper line portion 98A is formed at an interval to one side in the second direction Y from the first electrode portion 91 of the gate terminal electrode 90.

The second upper line portion 98B is formed in a band shape extending in the first direction X and has one end portion connected to the other end portion of the first upper line portion 97 and another end portion positioned at the peripheral edge side (the third side surface 5C side) of the chip 2. The second upper line portion 98B covers the second lower line portion 70B of the gate wiring film 65 with the interlayer insulating film 74 interposed therebetween. The second upper line portion 98B is formed at an interval to the other side in the second direction Y from the first electrode portion 91 of the gate terminal electrode 90 and faces the second upper line portion 98A with the first electrode portion 91 interposed therebetween.

When the gate terminal electrode 90 (the first electrode portion 91) that partially exposes the first recess portion 76 and the second upper line portions 98A and 98B that intersect the first recess portion 76 are formed, an electrode residue generated during the step of forming the gate terminal electrode 90 is liable to remain in the first recess portion 76. When the electrode residue is present, the gate wiring electrode 93 (the second upper line portions 98A and 98B) is liable to become electrically connected to the gate terminal electrode 90 (the first electrode portion 91) via the electrode residue.

In this case, the gate wiring electrode 93 (the second upper line portions 98A and 98B), together with the gate terminal electrode 90 (the first electrode portion 91), forms a short circuit without interposition of the gate resistive structure 50. Therefore, it is preferable that the second upper line portions 98A and 98B are disposed at intervals from the first recess portion 76 and do not have a portion that covers the first recess portion 76 (a portion intersecting the first recess portion 76).

According to this arrangement, a layout that avoids the problem of electrode residue in the first recess portion 76 is provided. The present disclosure does not exclude an embodiment including the gate terminal electrode 90 (the first electrode portion 91) that partially exposes the first recess portion 76 and the second upper line portions 98A and 98B that intersect the first recess portion 76. Also, when the gate terminal electrode 90 (the first electrode portion 91) that partially exposes the plurality of third recess portions 78 and the second upper line portions 98A and 98B that intersect the plurality of third recess portions 78 are formed, electrode residues generated during the step of forming the gate terminal electrode 90 are liable to remain in the plurality of third recess portions 78. In this case, the gate wiring electrode 93 (the second upper line portions 98A and 98B), together with the gate terminal electrode 90 (the first electrode portion 91), forms a short circuit without interposition of the gate resistive structure 50.

Therefore, it is preferable that the second upper line portions 98A and 98B are disposed at intervals from the plurality of third recess portions 78 and do not have a portion that covers the plurality of third recess portions 78 (a portion that intersects the plurality of third recess portions 78). According to this arrangement, a layout that avoids the problem of electrode residues in the plurality of third recess portions 78 is provided. In this embodiment, the gate terminal electrode 90 (the first electrode portion 91) covers the entire regions of the plurality of third recess portions 78.

That is, in regions above the second lower line portions 70A and 70B, the second upper line portions 98A and 98B face the first electrode portion 91 of the gate terminal electrode 90 in the second direction Y. The present disclosure does not exclude an embodiment including the gate terminal electrode 90 (the first electrode portion 91) that partially exposes the plurality of third recess portions 78 and the second upper line portions 98A and 98B that intersect the plurality of third recess portions 78.

The second upper line portions 98A and 98B preferably cover inner portions of the second lower line portions 70A and 70B at intervals from peripheral edges of the second lower line portions 70A and 70B in plan view. That is, it is preferable that the second upper line portions 98A and 98B face just the second lower line portions 70A and 70B with the interlayer insulating film 74 interposed therebetween and do not face the principal surface insulating film 45 with the interlayer insulating film 74 interposed therebetween.

The second upper wiring portion 95 is led out from the first upper wiring portion 94 to the street region 11 and covers the second lower wiring portion 67 of the gate wiring film 65 with the interlayer insulating film 74 interposed therebetween. Specifically, the second upper wiring portion 95 is led out from an inner portion (in this embodiment, a central portion) of the first upper line portion 97 and is formed in a band shape extending in the first direction X.

In this embodiment, the second upper wiring portion 95 crosses the center of the chip 2. The second upper wiring portion 95 extends in a band shape such as to be positioned in a region at one side (the third side surface 5C side) and a region at the other side (the fourth side surface 5D side) in the first direction X with respect to the straight line crossing the center of the first principal surface 3 in the second direction Y. The second upper wiring portion 95 has one end portion connected to the first upper wiring portion 94 at one side in the first direction X and another end portion at the other side in the first direction X. In this embodiment, the other end portion of the second upper wiring portion 95 is constituted of an open end.

The second upper wiring portion 95 covers the plurality of first gate connection electrodes 84A and is electrically connected to the second lower wiring portion 67 via the plurality of first gate connection electrodes 84A. The second upper wiring portion 95 has a width smaller than the width of the street region 11 in the second direction Y and is formed at intervals inward of the street region 11 from the plurality of active regions 6. That is, the second upper wiring portion 95 is formed at intervals from the plurality of trench separation structures 15 (the plurality of first trench structures 21) in plan view.

The third upper wiring portion 96 is led out from the first upper wiring portion 94 to the outer peripheral region 9 and covers the third lower wiring portion 68 of the gate wiring film 65 with the interlayer insulating film 74 interposed therebetween. Specifically, the third upper wiring portion 96 is led out from the other end portions of the plurality of second upper line portions 98A and 98B to one side (the first side surface 5A side) and the other side (the second side surface 5B side) of the outer peripheral region 9 and is formed in a band shape extending along the outer peripheral region 9.

The third upper wiring portion 96, together with the second upper wiring portion 95, sandwiches the plurality of active regions 6. Specifically, the third upper wiring portion 96 extends along the peripheral edge (the first side surface 5A to the fourth side surface 5D) of the chip 2 such as to surround the plurality of active regions 6 in plan view. Thereby, the third upper wiring portion 96, together with the second upper wiring portion 95, surrounds the plurality of active regions 6. In this embodiment, the third upper wiring portion 96 is formed at an interval from the second upper wiring portion 95. The third upper wiring portion 96 may be connected to the second upper wiring portion 95.

The third upper wiring portion 96 covers the plurality of second gate connection electrodes 84B and is electrically connected to the third lower wiring portion 68 via the plurality of second gate connection electrodes 84B. The third upper wiring portion 96 preferably has a width smaller than the width of the third lower wiring portion 68 in plan view. The third upper wiring portion 96 preferably covers the inner portion of the third lower wiring portion 68 at an interval from the peripheral edge of the third lower wiring portion 68 in plan view.

With reference to FIG. 1 to FIG. 11, the semiconductor device 1A includes, in the active regions 6, an emitter terminal electrode 103 disposed on the first principal surface 3 at intervals from the gate terminal electrode 90 and the gate wiring electrode 93. Specifically, the emitter terminal electrode 103 is disposed on the interlayer insulating film 74. The emitter terminal electrode 103 may be referred to as an “emitter pad” or an “emitter pad electrode.” The emitter terminal electrode 103 is preferably constituted of a conductive material different from the resistive film 60. The emitter terminal electrode 103 is preferably constituted of a conductive material different from the emitter electrode film 47.

The emitter terminal electrode 103 has a lower resistance value than the trench resistive structures 51 and the resistive film 60. In this embodiment, the emitter terminal electrode 103 is constituted of a metal film. The emitter terminal electrode 103 may be referred to as an “emitter metal terminal.” The emitter terminal electrode 103 may include at least one type among a Ti film, a TiN film, a W film, an Al film, a Cu film, an Al alloy film, a Cu alloy film, and a conductive polysilicon film.

The emitter terminal electrode 103 may include at least one among a pure Cu film, a pure Al film, an AlCu alloy film, an AlSi alloy film, and an AlSiCu alloy film. In this embodiment, the emitter terminal electrode 103 has a laminated structure that includes a Ti film and an Al alloy film (in this embodiment, an AlCu alloy film) laminated in that order from the chip 2 side. That is, the emitter terminal electrode 103 has the same electrode constitution as the gate terminal electrode 90.

The emitter terminal electrode 103 preferably has a thickness larger than the thickness of the resistive film 60 (the thickness of the gate electrode film 64). The thickness of the emitter terminal electrode 103 may be not less than 1 μm and not more than 10 μm. The thickness of the emitter terminal electrode 103 is preferably substantially equal to the thickness of the gate terminal electrode 90.

The emitter terminal electrode 103 has a plane area larger than the plane area of the gate terminal electrode 90. The plane area of the emitter terminal electrode 103 is preferably not less than 50% and not more than 90% of the plane area of the first principal surface 3. The plane area of the emitter terminal electrode 103 is particularly preferably not less than 70% of the plane area of the first principal surface 3.

In this embodiment, the emitter terminal electrode 103 includes a first emitter terminal electrode 103A and a second emitter terminal electrode 103B. The first emitter terminal electrode 103A is disposed in a region, between the second upper wiring portion 95 and the third upper wiring portion 96, on a portion of the interlayer insulating film 74 covering the first active region 6A. The first emitter terminal electrode 103A is led out from the first active region 6A to the outer peripheral region 9 in plan view.

The first emitter terminal electrode 103A covers the plurality of first emitter connection electrodes 85 and the plurality of second emitter connection electrodes 86 in the first active region 6A and covers the plurality of first well connection electrodes 87 in the outer peripheral region 9. The first emitter terminal electrode 103A is electrically connected to the plurality of second trench structures 25, the plurality of emitter regions 29, and the plurality of channel contact regions 31 via the plurality of first emitter connection electrodes 85 and the plurality of second emitter connection electrodes 86. The first emitter terminal electrode 103A is electrically connected to an inner edge portion of the outer peripheral well region 41 via the plurality of first well connection electrodes 87.

The second emitter terminal electrode 103B is disposed in a region, between the second upper wiring portion 95 and the third upper wiring portion 96, on a portion of the interlayer insulating film 74 covering the second active region 6B. The second emitter terminal electrode 103B is led out from the second active region 6B to the outer peripheral region 9 in plan view.

The second emitter terminal electrode 103B covers the plurality of first emitter connection electrodes 85 and the plurality of second emitter connection electrodes 86 in the second active region 6B and covers the plurality of first well connection electrodes 87 in the outer peripheral region 9. The second emitter terminal electrode 103B is electrically connected to the plurality of second trench structures 25, the plurality of emitter regions 29, and the plurality of channel contact regions 31 via the plurality of first emitter connection electrodes 85 and the plurality of second emitter connection electrodes 86. The second emitter terminal electrode 103B is electrically connected to an inner edge portion of the outer peripheral well region 41 via the plurality of first well connection electrodes 87.

The semiconductor device 1A includes an emitter wiring electrode 104 that, on the interlayer insulating film 74, is led out from the emitter terminal electrode 103 to a region outside the gate wiring electrode 93. The emitter wiring electrode 104 may be referred to as an “emitter finger” or an “emitter finger electrode.” The emitter wiring electrode 104 is preferably constituted of a conductive material different from the resistive film 60. The emitter wiring electrode 104 is preferably constituted of a conductive material different from the emitter electrode film 47.

The emitter wiring electrode 104 has a lower resistance value than the trench resistive structures 51 and the resistive film 60. In this embodiment, the emitter wiring electrode 104 is constituted of a metal film. The emitter wiring electrode 104 may be referred to as an “emitter metal wiring.” The emitter wiring electrode 104 may include at least one type among a Ti film, a TiN film, a W film, an Al film, a Cu film, an Al alloy film, a Cu alloy film, and a conductive polysilicon film.

The emitter wiring electrode 104 may include at least one among a pure Cu film, a pure Al film, an AlCu alloy film, an AlSi alloy film, and an AlSiCu alloy film. In this embodiment, the emitter wiring electrode 104 has a laminated structure that includes a Ti film and an Al alloy film (in this embodiment, an AlCu alloy film) laminated in that order from the chip 2 side. That is, the emitter wiring electrode 104 has the same electrode constitution as the emitter terminal electrode 103.

The emitter wiring electrode 104 preferably has a thickness larger than the thickness of the resistive film 60 (the thickness of the gate electrode film 64). The thickness of the emitter wiring electrode 104 may be not less than 1 μm and not more than 10 μm. The thickness of the emitter wiring electrode 104 is preferably substantially equal to the thickness of the gate terminal electrode 90 (the emitter terminal electrode 103).

The emitter wiring electrode 104 is connected to both the first emitter terminal electrode 103A and the second emitter terminal electrode 103B and is led out to a region further outward than the gate wiring electrode 93 (the third upper wiring portion 96) from the first emitter terminal electrode 103A and the second emitter terminal electrode 103B.

The emitter wiring electrode 104 is formed in a band shape extending along the peripheral edge of the chip 2 such as to surround the gate terminal electrode 90, the gate wiring electrode 93, the first emitter terminal electrode 103A, and the second emitter terminal electrode 103B. In this embodiment, the emitter wiring electrode 104 is formed in an annular shape (specifically, a quadrangle annular shape) extending along the peripheral edge (the first to fourth side surfaces 5A to 5D) of the chip 2 and surrounds the gate terminal electrode 90, the gate wiring electrode 93, the first emitter terminal electrode 103A, and the second emitter terminal electrode 103B entirely.

The emitter wiring electrode 104 is routed on a portion of the interlayer insulating film 74 covering an outer edge portion of the outer peripheral well region 41. The emitter wiring electrode 104 covers the plurality of second well connection electrodes 88 and is electrically connected to the outer edge portion of the outer peripheral well region 41 via the plurality of second well connection electrodes 88.

With reference to FIG. 1, FIG. 2, FIG. 10A, and FIG. 10B, the semiconductor device 1A includes, in the outer peripheral region 9, a plurality of FLR electrodes 105 disposed on the interlayer insulating film 74. The plurality of FLR electrodes 105 may include at least one type among a Ti film, a TiN film, a W film, an Al film, a Cu film, an Al alloy film, a Cu alloy film, and a conductive polysilicon film.

The plurality of FLR electrodes 105 may include at least one among a pure Cu film, a pure Al film, an AlCu alloy film, an AlSi alloy film, and an AlSiCu alloy film. In this embodiment, the plurality of FLR electrodes 105 each have a laminated structure that includes a barrier metal film and a main metal film laminated in that order from the chip 2 side. The barrier metal film is constituted, for example, of a laminated film that includes a Ti film and a TiN film that are laminated in that order from the chip 2 side. The main metal film is constituted, for example, of an Al alloy film (in this embodiment, an AlCu alloy film).

The plurality of FLR electrodes 105 are each formed in a band shape extending along the corresponding FLR 42. In this embodiment, the plurality of FLR electrodes 105 are each formed in an annular shape (quadrangle annular shape) extending along the corresponding FLR 42. In this embodiment, the plurality of FLR electrodes 105 are formed in an electrically floating state.

Each FLR electrode 105 has electrode curve portions 105A that are circular arcs in plan view shape in the four corner portions 201 to 204. Inner edges 105Aa and outer edges 105Ab of all of the electrode curve portions 105A may have the same center of curvature in each of the corner portions 201 to 204. Between the four corner portions 201 to 204, each FLR electrode 105 has electrode rectilinear portions 105B that are rectilinear in plan view shape.

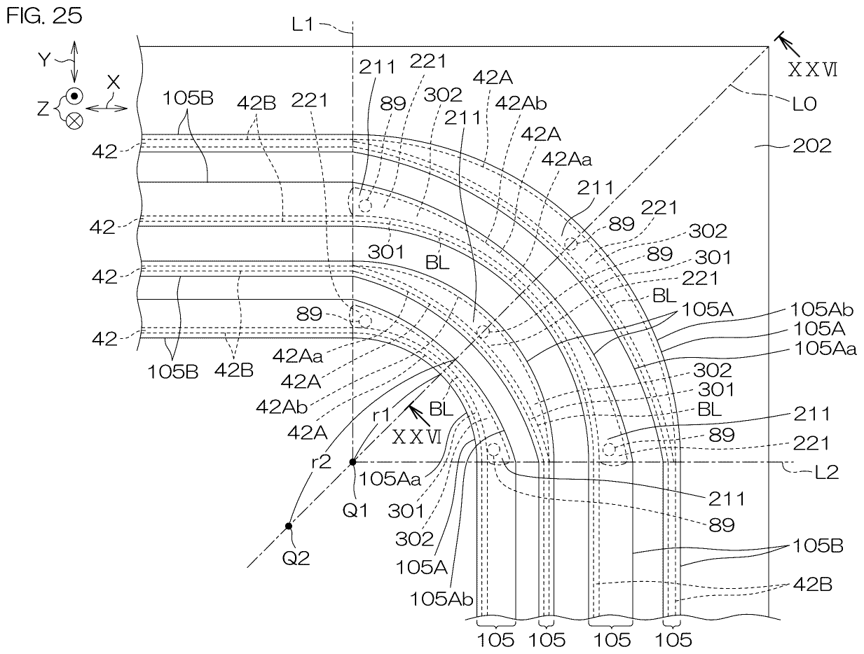

In this embodiment, in each of the corner portions 201 to 204, the inner edges 105Aa and the outer edges 105Ab of all of the electrode curve portions 105A have the same center of curvature. Also, in each of the corner portions 201 to 204, the center of curvature of the inner edge 105Aa and the outer edge 105Ab of each electrode curve portion 105A is present at a position on the dividing line that is the straight line dividing the apex angle of the corresponding corner portion in ½. The dividing line that is, for example, the straight line dividing the apex angle of the second corner portion 202 in ½ is, for example, indicated by L0 in FIG. 25 used for description of a modification example to be described below.

Here, in each of the corner portions 201 to 204, the inner edges 105Aa and the outer edges 105Ab of all of the electrode curve portions 105A do not have to have the same center of curvature. Also, in each of the corner portions 201 to 204, the centers of curvature of the inner edge 105Aa and the outer edge 105Ab of each electrode curve portion 105A do not have to be present at positions on the dividing line that is the straight line dividing the apex angle of the corresponding corner portion in ½.

The plurality of FLR electrodes 105 face the corresponding FLRs 42. Each FLR electrode 105 covers the corresponding plurality of FLR connection electrodes 89 entirely. Each FLR electrode 105 is electrically connected to the corresponding FLR 42 respectively via the corresponding plurality of FLR connection electrodes 89. The FLR connection electrodes 89 may be formed integrally with the corresponding FLR electrode 105. The plurality of FLR electrodes 105 are formed in an electrically floating state.

With reference to FIG. 1, FIG. 10A and FIG. 10B, the semiconductor device 1A includes, in the outer peripheral region 9, a channel stop electrode 106 disposed on the interlayer insulating film 74. The channel stop electrode 106 may be referred to as an “EQR (equipotential ring) electrode.” The channel stop electrode 106 may include at least one type among a Ti film, a TiN film, a W film, an Al film, a Cu film, an Al alloy film, a Cu alloy film, and a conductive polysilicon film.

The channel stop electrode 106 may include at least one among a pure Cu film, a pure Al film, an AlCu alloy film, an AlSi alloy film, and an AlSiCu alloy film. In this embodiment, the channel stop electrode 106 has a laminated structure that includes a barrier metal film and a main metal film laminated in that order from the chip 2 side. The barrier metal film is constituted, for example, of a laminated film that includes a Ti film and a TiN film that are laminated in that order from the chip 2 side. The main metal film is constituted, for example, of an Al alloy film (in this embodiment, an AlCu alloy film).

The channel stop electrode 106 is formed in a band shape extending along the peripheral edge of the chip 2. In this embodiment, the channel stop electrode 106 is formed in an annular shape (quadrangle annular shape) extending along the peripheral edge of the chip 2. The channel stop electrode 106 enters into a removed portion 46 of the interlayer insulating film 74 from above the interlayer insulating film 74 and is electrically connected to the channel stop region 43. The channel stop electrode 106 is formed in an electrically floating state. The channel stop region 43 may be formed at an inward from the peripheral edge of the chip 2 such as to expose a peripheral edge portion of the first principal surface 3 (the channel stop region 43).

The semiconductor device 1A includes a collector electrode 107 that covers the second principal surface 4. The collector electrode 107 is electrically connected to the collector region 14 exposed from the second principal surface 4. The collector electrode 107 forms an ohmic contact with the collector region 14. The collector electrode 107 may cover an entire region of the second principal surface 4 such as to be continuous with the peripheral edge of the chip 2 (the first to fourth side surfaces 5A to 5D).

The semiconductor device 1A includes the chip 2, the trench resistive structures 51, the resistive film 60, the gate terminal electrode 90, and the gate wiring electrode 93. The chip 2 has the first principal surface 3. The trench resistive structures 51 are formed in the first principal surface 3. On the first principal surface 3, the resistive film 60 is electrically connected to the trench resistive structures 51.

The gate terminal electrode 90 has a lower resistance value than the resistive film 60 and, on the first principal surface 3, is electrically connected to the trench resistive structures 51 via the resistive film 60. The gate wiring electrode 93 has a lower resistance value than the resistive film 60 and, on the first principal surface 3, is electrically connected to the gate terminal electrode 90 via the trench resistive structures 51 and the resistive film 60.

According to this arrangement, the gate resistance RG including the trench resistive structures 51 and the resistive film 60 can be interposed between the gate terminal electrode 90 and the gate wiring electrode 93. Particularly, according to this arrangement, since the trench resistive structures 51 are incorporated in the chip 2 in the region between the gate terminal electrode 90 and the gate wiring electrode 93, an increase in the occupied area of the gate resistance RG with respect to the first principal surface 3 can be suppressed. Therefore, it is possible to provide the semiconductor device 1A having a novel layout that contributes to miniaturization in the arrangement including the gate resistance RG.

The semiconductor device 1A preferably includes the gate electrode film 64 and the gate wiring film 65. The gate electrode film 64 is disposed on the first principal surface 3 adjacent to the resistive film 60. The gate wiring film 65 is disposed on the first principal surface 3 to be mutually adjacent to the resistive film 60 such as to face the gate electrode film 64 with the resistive film 60 interposed therebetween.

In such a structure, the gate terminal electrode 90 preferably covers the gate electrode film 64. Also, the gate wiring electrode 93 preferably covers the gate wiring film 65. According to this arrangement, in the arrangement including resistive film 60, the gate electrode film 64, and the gate wiring film 65 on the first principal surface 3, it is possible to provide the semiconductor device 1A having a novel layout that contributes to miniaturization.

The resistive film 60 preferably has the first end portion 60A at one side and the second end portion 60B at the other side. In this case, the gate wiring film 65 preferably includes the first connection portion connected to the first end portion 60A of the resistive film 60 and the second connection portion connected to the second end portion 60B of the resistive film 60. In this case, the gate wiring electrode 93 is preferably electrically connected to the resistive film 60 via the gate wiring film 65.

According to this arrangement, since the gate wiring electrode 93 can be electrically connected to the resistive film 60 via the gate wiring film 65, it is not necessary to directly connect the gate wiring electrode 93 to the resistive film 60. Consequently, the design rule of the gate wiring electrode 93 can be relaxed, and the degree of freedom of design the gate wiring electrode 93 can be improved.

The semiconductor device 1A preferably includes the first slit 71 demarcated between the resistive film 60 and the gate electrode film 64, and the second slit 72 demarcated between the resistive film 60 and the gate wiring film 65. According to this arrangement, the resistive film 60 can be appropriately separated (demarcated) from the gate electrode film 64 and the gate wiring film 65 by the first slit 71 and the second slit 72. As a result, the precision of the resistance value of the resistive film 60 can be improved.

The gate terminal electrode 90 preferably covers the resistive film 60 and the gate electrode film 64 across the first slit 71 in plan view. The gate wiring film 65 preferably covers the resistive film 60 and the gate electrode film 64 across the second slit 72 in plan view. The first slit 71 is preferably formed to be narrower than the resistive film 60. The second slit 72 is preferably formed to be narrower than the resistive film 60.

The trench resistive structures 51 preferably each extend in a band shape in the second direction Y (the one direction) in plan view. In this case, the resistive film 60 preferably extends in a band shape in the second direction Y (the one direction) in plan view. Also, the first slit 71 preferably extends in a band shape in the second direction Y (the one direction) in plan view. Also, the second slit 72 preferably extends in a band shape in the second direction Y (the one direction) in plan view. The first slit 71 may have the first length in the second direction Y (the one direction), and the second slit 72 may have the second length smaller than the first length in the second direction Y (the one direction).

The semiconductor device 1A preferably includes the third slits 73 demarcated between the gate electrode film 64 and the gate wiring film 65. According to this arrangement, the gate wiring film 65 can be appropriately separated (demarcated) from the gate electrode film 64 by the third slits 73. The gate wiring film 65 can thereby be suppressed from forming, together with the gate electrode film 64, a short circuit without interposition of the resistive film 60. The gate terminal electrode 90 preferably covers the gate electrode film 64 and the gate wiring film 65 across the third slits 73 in plan view.

The plurality of trench resistive structures 51 are preferably formed at intervals in the first principal surface 3. In this case, the resistive film 60 preferably covers the plurality of trench resistive structures 51. According to this arrangement, the resistance value of the gate resistance RG can be adjusted using the plurality of trench resistive structures 51.

The resistive film 60 preferably has the first covering portion 61 covering the first principal surface 3 outside the trench resistive structures 51 and the second covering portion 62 covering the trench resistive structures 51. In this case, the gate terminal electrode 90 is preferably electrically connected to the resistive film 60 at a portion that covers the first covering portion 61. Also, the gate wiring electrode 93 is preferably electrically connected to the resistive film 60 at a portion that covers the second covering portion 62. According to this arrangement, a part of the resistive film 60 and a part of the trench resistive structures 51 can be appropriately interposed in the region between the gate terminal electrode 90 and the gate wiring electrode 93.

The semiconductor device 1A preferably includes the interlayer insulating film 74, the first resistance connection electrode 81, and the second resistance connection electrode 82. The interlayer insulating film 74 covers the resistive film 60. The first resistance connection electrode 81 is embedded in the interlayer insulating film 74 such as to be electrically connected to the resistive film 60. The second resistance connection electrode 82 is embedded in the interlayer insulating film 74 such as to be electrically connected to the resistive film 60 at a different position from the first resistance connection electrode 81.

In such an arrangement, the gate terminal electrode 90 is preferably disposed on the interlayer insulating film 74 such as to be electrically connected to the resistive film 60 via the first resistance connection electrode 81. Also, the gate wiring electrode 93 is preferably disposed on the interlayer insulating film 74 such as to be electrically connected to the resistive film 60 via the second resistance connection electrode 82. According to this arrangement, the gate resistance RG can be arranged in the region between the first resistance connection electrode 81 and the second resistance connection electrode 82. The resistance value of the gate resistance RG can be adjusted by adjusting the distance between the first resistance connection electrode 81 and the second resistance connection electrode 82.

The second resistance connection electrode 82 may extend in a different direction from the first resistance connection electrode 81. For example, the first resistance connection electrode 81 may extend in the first direction X (one direction) in plan view, and the second resistance connection electrode 82 may extend in the second direction Y (intersecting direction) intersecting the first direction X (one direction) in plan view.

A plurality of the first resistance connection electrodes 81 are preferably embedded in the interlayer insulating film 74. A plurality of the second resistance connection electrodes 82 are preferably embedded in the interlayer insulating film 74. The second connection area S2 of the second resistance connection electrodes 82 with respect to the resistive film 60 may be smaller than the first connection area S1 of the first resistance connection electrodes 81 with respect to the resistive film 60.

The gate terminal electrode 90 preferably has the first electrode portion 91 positioned outside the first resistance connection electrodes 81 in plan view and the second electrode portion 92 protruding from the first electrode portion 91 toward the first resistance connection electrodes 81 to be narrower than the first electrode portion 91. In this case, the first electrode portion 91 is preferably formed as a terminal main body portion of the gate terminal electrode 90. Also, the second electrode portion 92 is preferably formed as a terminal lead-out portion led out from the terminal main body portion.

According to these arrangements, the region to which the gate potential is applied can be secured by the first electrode portion 91, and the region electrically connected to the resistive film 60 can be secured by the second electrode portion 92. For example, when a conductive bonding material such as a bonding wire is bonded to the gate terminal electrode 90, the conductive bonding material can be bonded to the first electrode portion 91. Stress caused by the conductive bonding material can thereby be suppressed from being generated in the resistive film 60 or the trench resistive structures 51. Degradation of electrical characteristics of the gate resistance RG can thus be suppressed.

The semiconductor device 1A preferably includes the p-type boundary well region 40 formed in the surface layer portion of the first principal surface 3. According to this arrangement, the breakdown voltage can be improved by the boundary well region 40. In this case, the trench resistive structures 51 are preferably formed at intervals from the bottom portion of the boundary well region 40 toward the first principal surface 3 side. According to this arrangement, the electric field concentration on the bottom wall of the trench resistive structure 51 can be suppressed by the boundary well region 40. The breakdown voltage can thus be improved appropriately.

The semiconductor device 1A preferably includes the active region 6 provided in the first principal surface 3, the non-active region 7 provided outside the active region 6 in the first principal surface 3, and the first trench structure 21 (the trench gate structure) formed in the active region 6. In this case, the trench resistive structures 51 are preferably formed in the non-active region 7. Also, the resistive film 60 preferably covers the trench resistive structures 51 in the non-active region 7.

Also, the gate terminal electrode 90 is preferably electrically connected to the resistive film 60 in the non-active region 7. Also, the gate wiring electrode 93 is preferably electrically connected to the first trench structure 21 in the active region 6 and is electrically connected to the resistive film 60 in the non-active region 7. According to these arrangements, since the gate resistance RG is formed in the non-active region 7, reduction of the active region 6 can be suppressed.

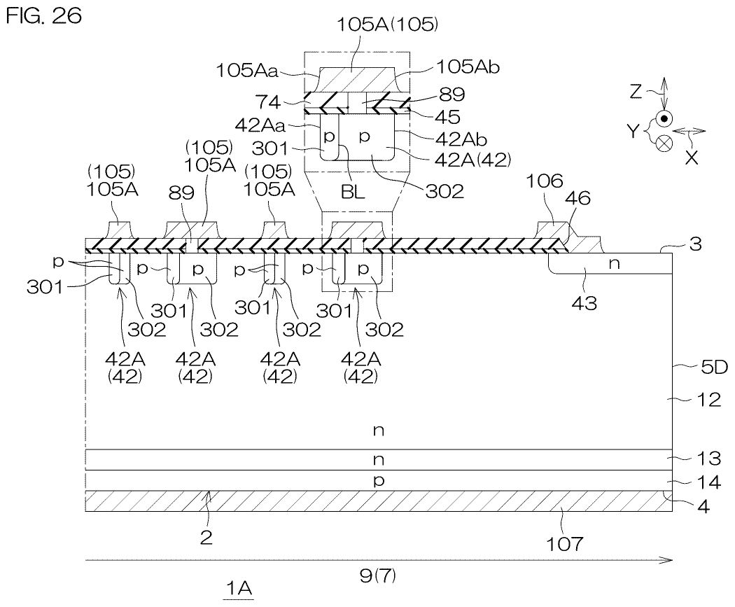

FIG. 25 is an illustrative plan view for describing a modification example of the FLRs 42, the FLR electrodes 105, and the FLR connection electrode 89 and is an illustrative plan view mainly showing the structure of the second corner portion 202 of the outer peripheral region 9. FIG. 26 is an illustrative sectional view taken along line XXVI-XXVI shown in FIG. 25.

In FIG. 25, arrangements other than the FLRs 42 and the FLR electrodes 105 (the outer peripheral well region 41, the channel stop region 43, the channel stop electrode 106, etc.) are omitted for convenience of description. However, in FIG. 26, the channel stop electrode 106 is illustrated for clarity.

The plurality of FLRs 42 are each formed in an annular shape (quadrangle annular shape) in the outer peripheral region 9 such as to surround the active regions 6. In the four corner portions 201 to 204, each FLR 42 has the FLR curve portions 42A with each of which the inner edge 42Aa and the outer edge 42Ab are circular arcs in plan view shape. Between the four corner portions 201 to 204, each FLR 42 has the FLR rectilinear portions 42B that are rectilinear in plan view shape.

Each FLR curve portion 42A has the double-diffused structure including the first diffusion region 301 at the inner side and the second diffusion region 302 at the outer side that is lower in p-type impurity concentration than the first diffusion region 301. Each FLR rectilinear portion 42B has the single-diffused structure constituted of just the diffusion region having the same p-type impurity concentration as the first diffusion region 301. A detailed structure of the plurality of FLRs 42 shall be described later.

The plurality of FLR electrodes 105 are each formed in a band shape extending along the corresponding FLR 42. The plurality of FLR electrodes 105 are each formed in an annular shape (quadrangle annular shape) extending along the corresponding FLR 42. The plurality of FLR electrodes 105 are formed in an electrically floating state.

The plurality of FLR electrodes 105 face the corresponding FLRs 42 with the laminated film of the principal surface insulating film 45 and the interlayer insulating film 74 interposed therebetween. With this modification example, the plurality of FLR electrodes 105 cover the corresponding FLRs 42.

In the four corner portions 201 to 204, each FLR electrode 105 has the electrode curve portions 105A with each of which the inner edge and the outer edge thereof are circular arcs in plan view shape. Between the four corner portions 201 to 204, each FLR electrode 105 has the electrode rectilinear portions 105B that are rectilinear in plan view shape.

In each of the corner portions 201 to 204, each electrode curve portion 105A has the inner edge 105Aa and the outer edge 105Ab that differ in the centers of curvature thereof and the curvatures thereof. Also, with mutually adjacent two of the electrode curve portions 105A, relationships of magnitudes of the curvatures of the inner edge 105Aa and the outer edge 105Ab are opposite of each other.

The structure of the FLR electrodes 105 in the second corner portion 202 shall now be described with reference to FIG. 25 and FIG. 26.

In the second corner portion 202, the center of curvature of the inner edge 105Aa and the center of curvature of the outer edge 105Ab of each electrode curve portion 105A are present at different positions on the dividing line L0 that is the straight line dividing the apex angle of the second corner portion 202 in ½ and a radius of curvature of the inner edge 105Aa and a radius of curvature of the outer edge 105Ab differ. Also, with any mutually adjacent two of the electrode curve portions 105A, the relationships of magnitudes of the curvatures of the inner edge 105Aa and the outer edge 105Ab are opposite of each other.

With the example of FIG. 25, the center of curvature of the inner edge 105Aa of the innermost electrode curve portion 105A is Q1 and the center of curvature of the outer edge 105Ab of that electrode curve portion 105A is Q2. The radius of curvature of the inner edge 105Aa is r1 and the radius of curvature of the outer edge 105Ab is r2 (r2>r1). The curvature of the inner edge 105Aa is thus larger than the curvature of the outer edge 105Ab.

The center of curvature of the inner edge 105Aa of the second electrode curve portion 105A from the inner side is Q2 and the center of curvature of the outer edge 105Ab of that electrode curve portion 105A is Q1. The radius of curvature of the inner edge 105Aa is larger than the radius of curvature of the outer edge 105Ab. The curvature of the inner edge 105Aa is thus smaller than the curvature of the outer edge 105Ab.

The center of curvature of the inner edge 105Aa of the third electrode curve portion 105A from the inner side is Q1 and the center of curvature of the outer edge 105Ab of that electrode curve portion 105A is Q2. The radius of curvature of the inner edge 105Aa is smaller than the radius of curvature of the outer edge 105Ab. The curvature of the inner edge 105Aa is thus larger than the curvature of the outer edge 105Ab.

The center of curvature of the inner edge 105Aa of the outermost electrode curve portion 105A is Q2 and the center of curvature of the outer edge 105Ab of that electrode curve portion 105A is Q1. The radius of curvature of the inner edge 105Aa is larger than the radius of curvature of the outer edge 105Ab. The curvature of the inner edge 105Aa is thus smaller than the curvature of the outer edge 105Ab.

Each electrode curve portion 105A has a region of wide width and a region of narrow width between its inner edge 105Aa and outer edge 105Ab. And a part of the region of wide width in each electrode curve portion 105A is physically and electrically connected to the corresponding FLR 42 via the FLR connection electrode 89 penetrating continuously through the interlayer insulating film 74 and the principal surface insulating film 45.

Specifically, with each of the innermost electrode curve portion 105A and the third electrode curve portion 105A from the inner side, the width of a length central portion thereof is the narrowest and the width widens as both ends are approached from the length central portion. Therefore, these electrode curve portions 105A each have wide portions 211 at both end portions.

On the other hand, with each of the second electrode curve portion 105A from the inner side and the outermost electrode curve portion 105A, the width of a length central portion thereof is the widest and the width narrows as both ends are approached from the length central portion. Therefore, these electrode curve portions 105A each have a wide portion 211 at the length central portion.

In the second corner portion 202, with respect to a straight line joining the center of curvature Q1 and an apex of the second corner portion 202, a counterclockwise angle centered at the center of curvature Q1 shall be deemed to be negative and a clockwise angle centered at the center of curvature Q1 shall be deemed to be positive.

With this modification example, in the second corner portion 202, one end of each of the inner edge 105Aa and the outer edge 105Ab of each electrode curve portion 105A is disposed on a straight line L1 with which a rotation angle centered at the center of curvature Q1 is −45 degrees with respect to the straight line joining the center of curvature Q1 and the apex of the second corner portion 202.

Also, with this modification example, in the second corner portion 202, another end of each of the inner edge 105Aa and the outer edge 105Ab of each electrode curve portion 105A is disposed on a straight line L2 with which an angle centered at the center of curvature Q1 is +45 degrees with respect to the straight line joining the center of curvature Q1 and the apex of the second corner portion 202.

With the example of FIG. 25, the widths at both ends of the innermost electrode curve portion 105A and the third electrode curve portion 105A from the inner side are respectively larger than the widths at both ends of the second electrode curve portion 105A from the inner side and the outermost electrode curve portion 105A.

Widths of the electrode rectilinear portion 105B connected to both ends of each electrode curve portion 105A are equal to the widths at both ends of the electrode curve portion 105A.

The structure of the FLRs 42 shall now be described in detail.

In each of the corner portions 201 to 204, each FLR curve portion 42A has the inner edge 42Aa and the outer edge 42Ab that differ in the centers of curvature thereof and the curvatures thereof. Also, with two mutually adjacent FLR curve portions 42A, relationships of magnitudes of the curvatures of the inner edge 42Aa and the outer edge 42Ab are opposite of each other.

The structure of the FLRs 42 in the second corner portion 202 shall now be described with reference to FIG. 25 and FIG. 26.

In the second corner portion 202, the center of curvature of the inner edge 42Aa and the center of curvature of the outer edge 42Ab of each FLR curve portion 42A are present at different positions on the dividing line L0 that is the straight line dividing the apex angle of the second corner portion 202 in ½ and a radius of curvature of the inner edge 42Aa and a radius of curvature of the outer edge 42Ab differ. Also, with any two mutually adjacent FLR curve portions 42A, the relationships of magnitudes of the curvatures of the inner edge 42Aa and the outer edge 42Ab are opposite of each other.

With the innermost FLR curve portion 42A in the example of FIG. 25, the center of curvature of the inner edge 42Aa is Q1 and the center of curvature of the outer edge 42Ab is Q2. The radius of curvature of the inner edge 42Aa is smaller than the radius of curvature of the outer edge 42Ab. The curvature of the inner edge 42Aa is thus larger than the curvature of the outer edge 42Ab.

With the second FLR curve portion 42A from the inner side, the center of curvature of the inner edge 42Aa is Q2 and the center of curvature of the outer edge 42Ab is Q1. The radius of curvature of the inner edge 42Aa is larger than the radius of curvature of the outer edge 42Ab. The curvature of the inner edge 42Aa is thus smaller than the curvature of the outer edge 42Ab.

With the third FLR curve portion 42A from the inner side, the center of curvature of the inner edge 42Aa is Q1 and the center of curvature of the outer edge 42Ab is Q2. The radius of curvature of the inner edge 42Aa is smaller than the radius of curvature of the outer edge 42Ab. The curvature of the inner edge 42Aa is thus larger than the curvature of the outer edge 42Ab.

With the outermost FLR curve portion 42A, the center of curvature of the inner edge 42Aa is Q2 and the center of curvature of the outer edge 42Ab is Q1. The radius of curvature of the inner edge 42Aa is larger than the radius of curvature of the outer edge 42Ab. The curvature of the inner edge 42Aa is thus smaller than the curvature of the outer edge 42Ab.

With this modification example, the center of curvature of the inner edge 42Aa of each FLR curve portion 42A coincides with the center of curvature of the inner edge 105Aa of the corresponding electrode curve portion 105A. Similarly, the center of curvature of the outer edge 42Ab of each FLR curve portion 42A coincides with the center of curvature of the outer edge 105Ab of the corresponding electrode curve portion 105A.

Also, in plan view, the inner edge 42Aa of each FLR curve portion 42A is receded further inside the corresponding electrode curve portion 105A than the inner edge 105Aa of the electrode curve portion 105A and the outer edge 42Ab of each FLR curve portion 42A is receded further inside the corresponding electrode curve portion 105A than the outer edge 105Ab of the electrode curve portion 105A. Therefore, the width of each FLR curve portion 42A at every length direction position is narrower than the width of the corresponding electrode curve portion 105A at the corresponding length direction position.

Here, the inner edge 42Aa of each FLR curve portion 42A may instead be advanced further outside the corresponding electrode curve portion 105A than the inner edge 105Aa of the electrode curve portion 105A. Also, the outer edge 42Ab of each FLR curve portion 42A may be advanced further outside the corresponding electrode curve portion 105A than the outer edge 105Ab of the electrode curve portion 105A.

Just one of either the inner edge 42Aa or the outer edge 42Ab of each FLR curve portion 42A may be advanced further outside the corresponding electrode curve portion 105A than the corresponding edge 105Aa or 105Ab of the electrode curve portion 105A. Also, both the inner edge 42Aa and the outer edge 42Ab of each FLR curve portion 42A may be advanced further outside the corresponding electrode curve portion 105A than the corresponding edges 105Aa and 105Ab of the electrode curve portion 105A.

With each of the innermost FLR curve portion 42A and the third FLR curve portion 42A from the inner side, the width of a length central portion thereof is the narrowest and the width widens as both ends are approached from the length central portion. Therefore, these FLR curve portions 42A each have wide portions 221 at both end portions.

On the other hand, with each of the second FLR curve portion 42A from the inner side and the outermost FLR curve portion 42A, the width of a length central portion thereof is the widest and the width narrows as both ends are approached from the length central portion. Therefore, these FLR curve portions 42A each have a wide portion 221 at the length central portion.

With this modification example, in the second corner portion 202, one end of each of the inner edge 42Aa and the outer edge 42Ab of each FLR curve portion 42A is disposed on the straight line L1.

Also, with this modification example, in the second corner portion 202, another end of each of the inner edge 42Aa and the outer edge 42Ab of each FLR curve portion 42A is disposed on the straight line L2.

With the example of FIG. 25, the widths at both ends of the innermost FLR curve portion 42A and the third FLR curve portion 42A from the inner side are respectively larger than the widths at both ends of the second FLR curve portion 42A from the inner side and the outermost FLR curve portion 42A.

The widths of the FLR rectilinear portions 42B connected to both ends of each FLR curve portion 42A are equal to the widths at both ends of the FLR curve portion 42A.

With this modification example, the diffusion region boundary line BL in each FLR curve portion 42A has the same center of curvature as the center of curvature of the inner edge 42Aa of the FLR curve portion 42A. Here, the diffusion region boundary line BL in each FLR curve portion 42A may have the same center of curvature as the center of curvature of the outer edge 42Ab of the FLR curve portion 42A instead.

With this modification example, among the first diffusion region 301 and the second diffusion region 302 of each FLR curve portion 42A, the first diffusion region 301 is fixed in width in a length direction. Here, among the first diffusion region 301 and the second diffusion region 302 of each FLR curve portion 42A, the second diffusion region 302 may be fixed in width in the length direction.

Also, with this modification example, a plan view shape of the boundary line BL between the first diffusion region 301 and the second diffusion region 302 of each FLR curve portion 42A is a circular arc having the same center of curvature as the center of curvature of the inner edge of the corresponding electrode curve portion 105A.

In each of the innermost electrode curve portion 105A and the third electrode curve portion 105A from the inner side, parts of the wide portions 211 at both end portions thereof are physically and electrically connected respectively to the wide portions 221 at both end portions of the corresponding FLR curve portion 42A via the FLR connection electrodes 89 penetrating continuously through the interlayer insulating film 74 and the principal surface insulating film 45.

In each of the second electrode curve portion 105A from the inner side and the outermost electrode curve portion 105A, a part of a length central portion of the wide portion 211 is physically and electrically connected to a length central portion of the wide portion 221 of the corresponding FLR curve portion 42A via the FLR connection electrode 89 penetrating continuously through the interlayer insulating film 74 and the principal surface insulating film 45.

With this modification example, the FLR connection electrode 89 is not formed in portions (the electrode rectilinear portions 105B) of the plurality of FLR electrodes 105 other than the electrode curve portions 105A. Here, the FLR connection electrode 89 may be formed in the electrode rectilinear portions 105B of the plurality of FLR electrodes 105. Each FLR connection electrode 89 may be formed integrally with the corresponding FLR electrode 105 (electrode curve portion 105A).

The plurality of FLR connection electrodes 89 each have a circular shape in plan view. The plurality of FLR connection electrodes 89 may each have a quadrangle shape or other polygonal shape in plan view or may have an elliptical shape in plan view instead. In this modification example, the plurality of FLR connection electrodes 89 are formed in an electrically floating state.

With this modification example, the FLRs 42, the FLR electrodes 105, and the FLR connection electrodes 89 in the first corner portion 201 have plan view shapes that are line symmetrical to the plan view shapes of those in the second corner portion 202 with respect to a straight line passing through a center of the chip 2 in the first direction X and extending in the second direction Y.

With this modification example, the FLRs 42, the FLR electrodes 105, and the FLR connection electrodes 89 in the third corner portion 203 have plan view shapes that are line symmetrical to the plan view shapes of those in the second corner portion 202 with respect to a straight line passing through a center of the chip 2 in the second direction Y and extending in the first direction X.

With this modification example, the FLRs 42, the FLR electrodes 105, and the FLR connection electrodes 89 in the fourth corner portion 204 have plan view shapes that are line symmetrical to the plan view shapes of those in the third corner portion 203 with respect to the straight line passing through the center of the chip 2 in the first direction X and extending in the second direction Y.

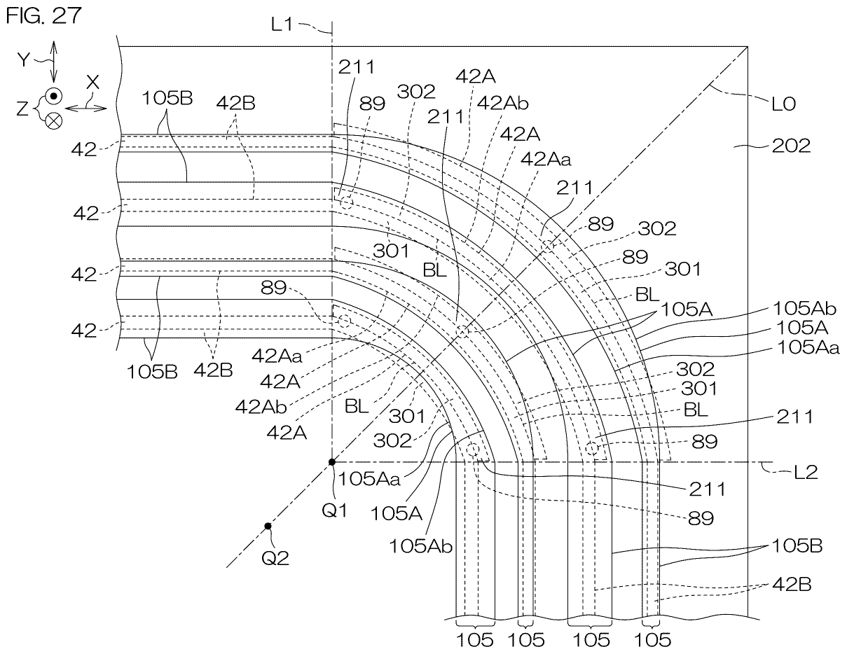

Here, as shown in FIG. 27, each FLR curve portion 42A may differ in shape from the corresponding electrode curve portion 105A. FIG. 27 is an illustrative plan view showing the structures of the FLRs 42, the FLR electrodes 105, and the FLR connection electrodes 89 in the second corner portion 202.

In FIG. 27, the plan view shapes of the plurality of electrode curve portions 105A are the same as the plan view shapes in FIG. 25. In FIG. 27, the inner edges 42Aa, the outer edges 42Ab, and the diffusion region boundary lines BL of the plurality of FLR curve portions 42A have the same center of curvature. Specifically, the center of curvature of these is Q2.

Even in the three corner portions 201, 202, and 203 other than the second corner portion 202, the plurality of electrode curve portions 105A and the plurality of FLR curve portions 42A have the same structures as the structures of those in the second corner portion 202.

In FIG. 27, with each FLR curve portion 42A, the width of the first diffusion region 301 is fixed in the length direction and the width of the second diffusion region 302 is fixed in the length direction.

Also, in FIG. 27, the inner edge 42Aa and the outer edge 42Ab of each of the innermost and third FLR curve portions 42A from the inner side have the same center of curvature as the center of curvature of the outer edge 105Ab of the corresponding electrode curve portion 105A.

On the other hand, the inner edge 42Aa and the outer edge 42Ab of each of the second and outermost FLR curve portions 42A from the inner side have the same center of curvature as the center of curvature of the inner edge 105Aa of the corresponding electrode curve portion 105A.

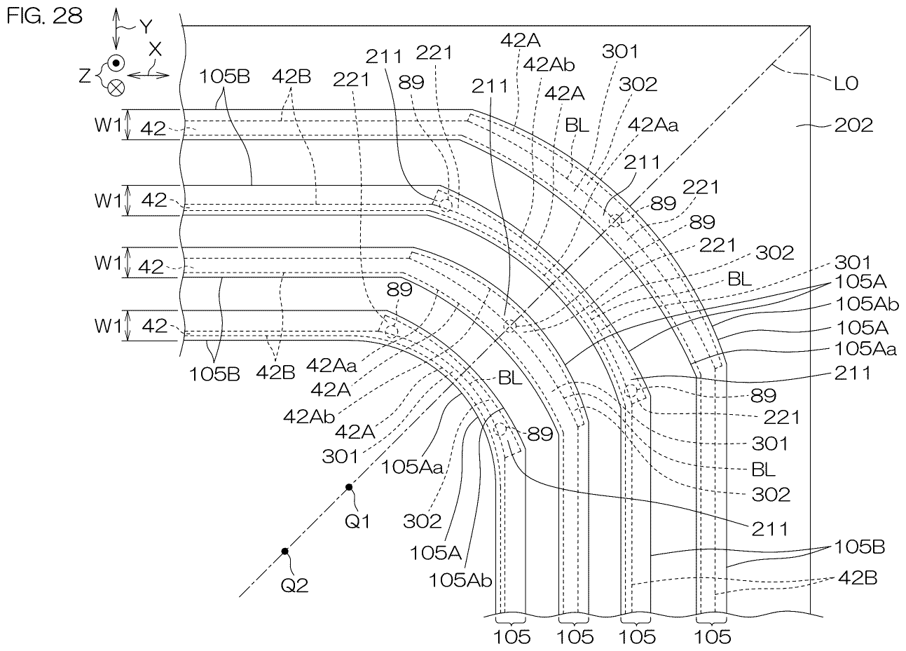

Also, the plan view shapes of the FLRs 42, the FLR electrodes 105, and the FLR connection electrodes 89 in the second corner portion 202 may be the plan view shapes such as shown in FIG. 28. In FIG. 28, portions corresponding to respective portions of FIG. 25 are provided with the same reference symbols as in FIG. 25.

Although the structure of each electrode curve portion 105A in FIG. 28 is substantially the same as the structure of the corresponding electrode curve portion 105A in FIG. 25, the positions of both ends of each electrode curve portion 105A differ from the positions of both ends of the corresponding electrode curve portion 105A in FIG. 25.

In FIG. 28, an angle formed by a straight line joining one end of the inner edge 105Aa of each electrode curve portion 105A and the center of curvature of the inner edge 105Aa and the dividing line L0 and an angle formed by a straight line joining one end of the outer edge 105Ab of each electrode curve portion 105A and the center of curvature of the outer edge 105Ab and the dividing line L0 are set such that a width of the one end of each electrode curve portion 105A is a predetermined width W1.

Also, an angle formed by a straight line joining the other end of the inner edge 105Aa of each electrode curve portion 105A and the center of curvature of the inner edge 105Aa and the dividing line L0 and an angle formed by a straight line joining the other end of the outer edge 105Ab of each electrode curve portion 105A and the center of curvature of the outer edge 105Ab and the dividing line L0 are set such that a width of the other end of each electrode curve portion 105A is the predetermined width W1.

The widths of the electrode rectilinear portions 105B connected to both ends of each electrode curve portion 105A are also formed to the predetermined width W1.

Although the structure of each FLR curve portion 42A in FIG. 28 is substantially the same as the structure of the corresponding FLR curve portion 42A in FIG. 25, the positions of both ends of each FLR curve portion 42A differ from the positions of both ends of the corresponding FLR curve portion 42A in FIG. 25.

In FIG. 28, an angle formed by a straight line joining one end of the inner edge 42Aa of each FLR curve portion 42A and the center of curvature of the inner edge 42Aa and the dividing line L0 and an angle formed by a straight line joining one end of the outer edge 42Ab of each FLR curve portion 42A and the center of curvature of the outer edge 42Ab and the dividing line L0 are set such that a width of the one end of each FLR curve portion 42A is a predetermined width.

Also, an angle formed by a straight line joining the other end of the inner edge 42Aa of each FLR curve portion 42A and the center of curvature of the inner edge 42Aa and the dividing line L0 and an angle formed by a straight line joining the other end of the outer edge 42Ab of each FLR curve portion 42A and the center of curvature of the outer edge 42Ab and the dividing line L0 are set such that a width of the other end of each FLR curve portion 42A is the predetermined width.

With this modification example, the widths of the FLR rectilinear portions 42B connected to both ends of each FLR curve portion 42A are equal to the widths of the corresponding ends of the first diffusion regions 301 of the FLR curve portion 42A.

Even in the structure of FIG. 28, the diffusion region boundary line BL of each FLR curve portion 42A has the same center of curvature as the center of curvature of the inner edge 42A a of the FLR curve portion 42A as in the structure of FIG. 25. Here, the diffusion region boundary line BL of each FLR curve portion 42A may have the same center of curvature as the center of curvature of the outer edge 42Ab of the FLR curve portion 42A instead.

With the structure of FIG. 28, even when, for example, the width of each electrode rectilinear portion 105B of each FLR electrode 105 is narrower than a width required to connect the electrode rectilinear portion 105B to the FLR 42 by an FLR connection electrode 89, a region for connecting to the FLR 42 by an FLR connection electrode 89 can easily be secured in each electrode curve portion 105A.

In other words, the width of each electrode rectilinear portion 105B of each FLR electrode 105 can be made narrower than the width for connecting the electrode rectilinear portion 105B to the FLR 42 by an FLR connection electrode 89. An overall width of the plurality of FLR electrodes 105 can thereby be made narrow and therefore, miniaturization of the chip can be achieved.

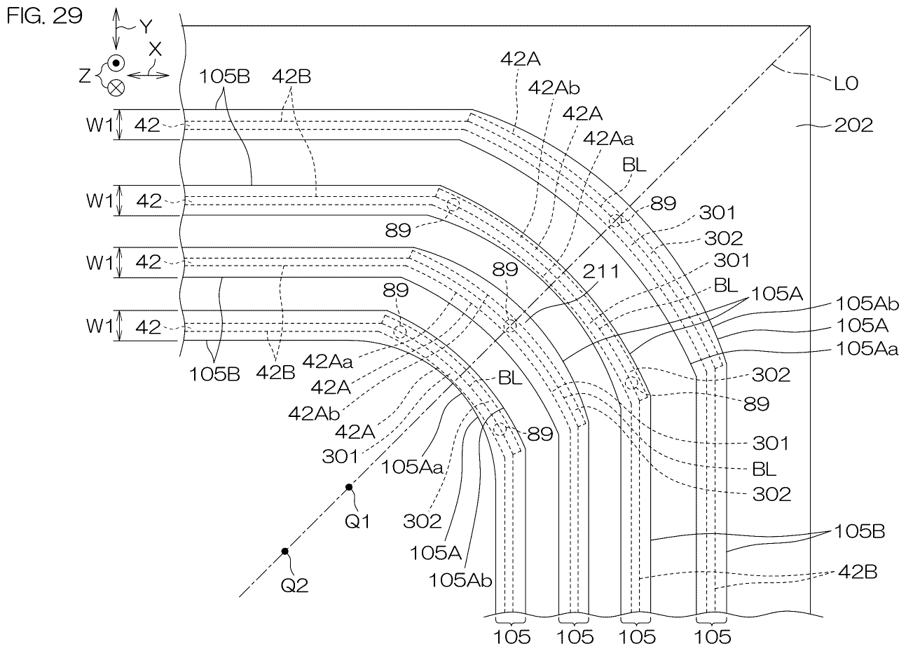

Here, as shown in FIG. 29, each FLR curve portion 42A may differ in shape from the corresponding electrode curve portion 105A. FIG. 29 is an illustrative plan view showing the structures of the FLRs 42, the FLR electrodes 105, and the FLR connection electrodes 89 in the second corner portion 202.

In FIG. 29, the plan view shapes of the plurality of electrode curve portions 105A are the same as the plan view shapes in FIG. 28. In FIG. 29, the inner edges 42Aa, the outer edges 42Ab, and the diffusion region boundary lines BL of the plurality of FLR curve portions 42A have the same center of curvature. Specifically, the center of curvature of these is Q2.

In FIG. 29, the width of the first diffusion region 301 of each FLR curve portion 42A is fixed in the length direction and the width of the second diffusion region 302 is fixed in the length direction.

Also, in FIG. 29, the inner edge 42Aa and the outer edge 42Ab of each of the innermost and third FLR curve portions 42A from the inner side have the same center of curvature as the center of curvature of the outer edge 105Ab of the corresponding electrode curve portion 105A. On the other hand, the inner edge 42Aa and the outer edge 42Ab of each of the second and outermost FLR curve portions 42A from the inner side have the same center of curvature as the center of curvature of the inner edge 105Aa of the corresponding electrode curve portion 105A.

Even in the three corner portions 201, 202, and 203 other than the second corner portion 202, the plurality of electrode curve portions 105A and the plurality of FLR curve portions 42A have the same structures as the structures of those in the second corner portion 202.

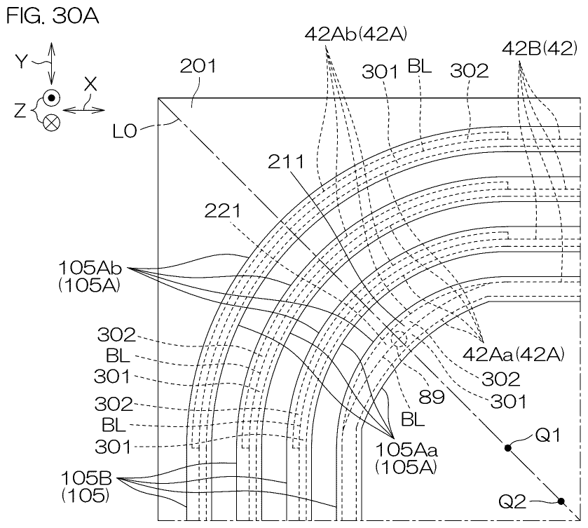

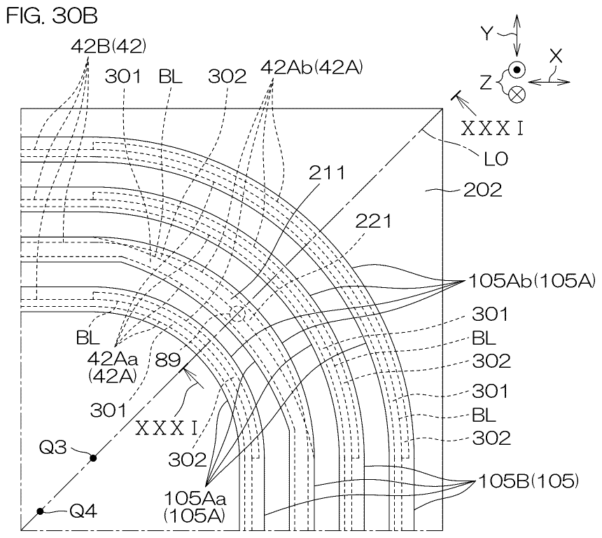

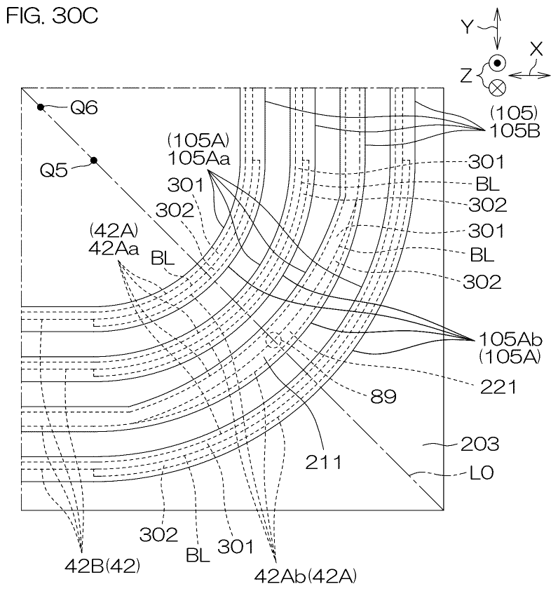

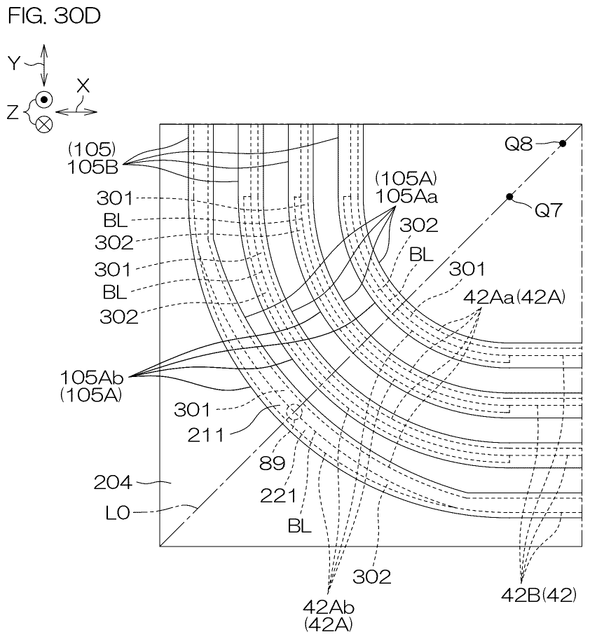

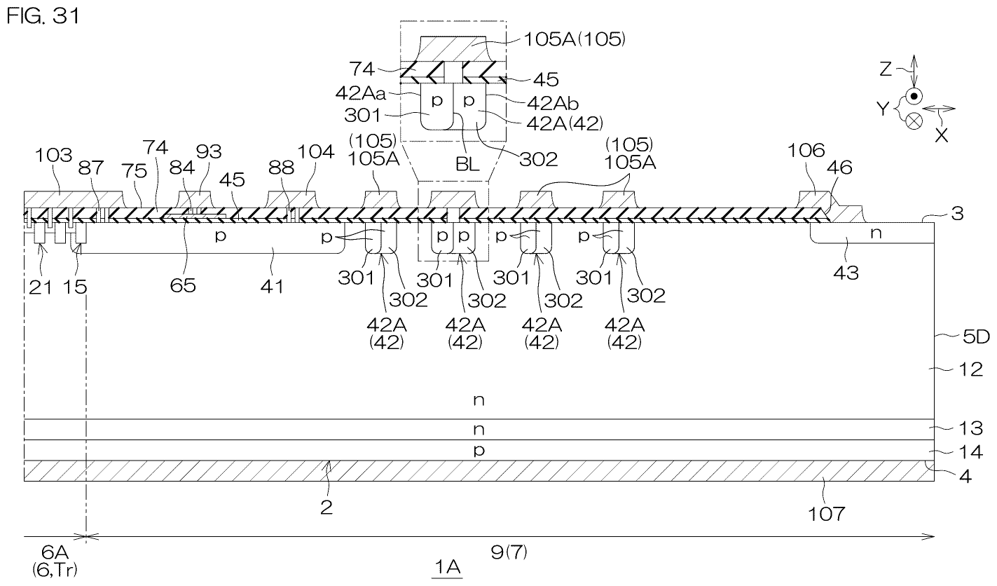

FIG. 30A to FIG. 30D are illustrative plan views for describing yet another modification example of the FLRs 42, the FLR electrodes 105, and the FLR connection electrodes 89 and are illustrative plan views mainly showing the structures of the four corner portions 201 to 204 of the outer peripheral region 9. FIG. 31 is an illustrative sectional view taken along line XXXI-XXXI shown in FIG. 30B. In FIG. 30A to FIG. 30D, the arrangements other than the FLRs 42 and the FLR electrodes 105 (the outer peripheral well region 41, the channel stop region 43, the channel stop electrode 106, etc.) are omitted for convenience of description. However, in FIG. 31, the channel stop electrode 106 is illustrated for clarity.

With reference to FIG. 30A to FIG. 30D and FIG. 31, the plurality of FLRs 42 are each formed in an annular shape (quadrangle annular shape) in the outer peripheral region 9 such as to surround the active regions 6. In the four corner portions 201 to 204, each FLR 42 has the FLR curve portions 42A with each of which the inner edge 42Aa and the outer edge 42Ab are circular arcs in plan view shape. Between the four corner portions 201 to 204, each FLR 42 has FLR rectilinear portions 42B that are rectilinear in plan view shape.

Each FLR curve portion 42A has the double-diffused structure including the first diffusion region 301 at the inner side and the second diffusion region 302 at the outer side that is lower in p-type impurity concentration than the first diffusion region 301. Each FLR rectilinear portion 42B has the single-diffused structure constituted of just the diffusion region having the same p-type impurity concentration as the first diffusion region 301.

The plurality of FLR electrodes 105 are each formed in a band shape extending along the corresponding FLR 42. The plurality of FLR electrodes 105 are each formed in an annular shape (quadrangle annular shape) extending along the corresponding FLR 42. The plurality of FLR electrodes 105 are formed in an electrically floating state.

The plurality of FLR electrodes 105 face the corresponding FLRs 42 with the laminated film of the principal surface insulating film 45 and the interlayer insulating film 74 interposed therebetween. With this modification example, the plurality of FLR electrodes 105 cover the corresponding FLRs 42.

At each of the corner portions 201 to 204, each FLR electrode 105 has the electrode curve portion 105A with which the inner edge and the outer edge thereof are circular arcs in plan view shape. Between the four corner portions 201 to 204, each FLR electrode 105 has the electrode rectilinear portions 105B that are rectilinear in plan view shape.

With this modification example, in each of the corner portions 201 to 204, the centers of curvature of the inner edge 105Aa and the outer edge 105Ab of each electrode curve portion 105A are present on the dividing line L0 that is the straight line dividing the apex angle of the corner portion in ½.

With this modification example, the plurality of electrode rectilinear portions 105B between the corner portions 201 to 204 have the same width and the same interval.

With this modification example, in each of the corner portions 201 to 204, the centers of curvature of the inner edge 42Aa and the outer edge 42Ab of each FLR curve portion 42A are present on the dividing line L0 that is the straight line dividing the apex angle of the corner portion in ½.

With this modification example, the plurality of FLR rectilinear portions 42B between the corner portions 201 to 204 have the same width and the same interval.

With this modification example, both edges of each of the plurality of FLR rectilinear portions 42B between the corner portions 201 to 204 are receded further inside the corresponding electrode rectilinear portion 105B than the corresponding edges of the electrode rectilinear portion 105B in plan view. Thus, with this modification example, the width of each FLR rectilinear portion 42B is narrower than the width of the corresponding electrode rectilinear portion 105B.

In the following, a structure in which the inner edges 105Aa and the outer edges 105Ab of the four electrode curve portions 105A in each of the corner portions 201 to 204 have the same center of curvature and the widths and intervals of these electrode curve portions 105A are the same as the widths and intervals of the respectively corresponding eight electrode rectilinear portions 105B shall be referred to as a basic electrode corner structure.

Also, a structure in which the inner edges 42Aa and the outer edges 42Ab of the four FLR curve portions 42A in each of the corner portions 201, 202, 203, and 204 have the same center of curvature and the widths and intervals of these FLR curve portions 42A are respectively fixed shall be referred to as a basic FLR corner structure.

The electrode curve portions 105A of the plurality of FLR electrodes 105 are physically and electrically connected to the corresponding FLR curve portions 42A of the FLRs 42 via the FLR connection electrodes 89 penetrating continuously through the interlayer insulating film 74 and the principal surface insulating film 45 at connection positions that are predetermined according to each FLR electrode 105.

First, the structures of the FLR electrodes 105, the FLRs 42, and the FLR connection electrode 89 in the first corner portion 201 shall be described with reference to FIG. 30A.

In the first corner portion 201, the innermost electrode curve portion 105A among the four electrode curve portions 105A differs from the structure of the corresponding electrode curve portion of the basic electrode corner structure. The other three electrode curve portions 105A are the same in structure as the corresponding electrode curve portions of the basic electrode corner structure.

The center of curvature of the inner edges 105Aa and the outer edges 105Ab of the second, third, and outermost electrode curve portions 105A from the inner side is Q1. These electrode curve portions 105A have an equal width. The width of these electrode curve portions 105A is fixed regardless of the length direction position.

With the innermost electrode curve portion 105A, the center of curvature of the inner edge 105Aa is Q2, the center of curvature of the outer edge 105Ab is Q1, and the curvature of the inner edge 105Aa and the curvature of the outer edge 105Ab differ. Specifically, the curvature of the inner edge 105Aa is smaller than the curvature of the outer edge 105Ab. In other words, the radius of curvature of the inner edge 105Aa is larger than the radius of curvature of the outer edge 105Ab.

The width of the innermost electrode curve portion 105A differs according to the length direction position. Specifically, the width of the innermost electrode curve portion 105A is widest at the length central portion and narrows as both ends are approached from the length central portion.

The innermost electrode curve portion 105A has the wide portion 211 of larger width than the corresponding electrode curve portions 105A of the three corner portions 202, 203, and 204 other than the first corner portion 201. A length intermediate portion of the innermost electrode curve portion 105A is the wide portion 211.

With this modification example, the curvature of the inner edge 105Aa of the innermost electrode curve portion 105A is set such that the width at both ends of the electrode curve portion 105A coincides with the width of the electrode rectilinear portions 105B.

In the first corner portion 201, the innermost FLR curve portion 42A among the four FLR curve portions 42A differs from the structure of the corresponding FLR curve portion of the basic FLR corner structure. The other three FLR curve portions 42A are the same in structure as the corresponding FLR curve portions of the basic FLR corner structure.

The center of curvature of the inner edges 42Aa and the outer edges 42Ab of the second, third, and outermost FLR curve portions 42A from the inner side is Q1. These FLR curve portions 42A have an equal width. The width of these FLR curve portions 42A is fixed regardless of the length direction position.

With the innermost FLR curve portion 42A, the center of curvature of the inner edge 42Aa is Q2, the center of curvature of the outer edge 42Ab is Q1, and the curvature of the inner edge 42Aa and the curvature of the outer edge 42Ab differ. Specifically, the curvature of the inner edge 42Aa is smaller than the curvature of the outer edge 42Ab. In other words, the radius of curvature of the inner edge 42Aa is larger than the radius of curvature of the outer edge 42Ab.

The width of the innermost FLR curve portion 42A differs according to the length direction position. Specifically, the width of the innermost FLR curve portion 42A is widest at the length central portion and narrows as both ends are approached from the length central portion.

The innermost FLR curve portion 42A has the wide portion 221 of larger width than the FLR curve portions 42A of the corresponding FLR curve portions 42A of the three corner portions 202, 203, and 204 other than the first corner portion 201. A length intermediate portion of the innermost FLR curve portion 42A is the wide portion 221.

With this modification example, among the first diffusion region 301 and the second diffusion region 302 of the innermost FLR curve portion 42A, the first diffusion region 301 is fixed in width in the length direction.

Also, with this modification example, the plan view shape of the boundary line BL between the first diffusion region 301 and the second diffusion region 302 of the innermost FLR curve portion 42A is a circular arc having the same center of curvature as the center of curvature of the inner edge of the corresponding electrode curve portion 105A.

With this modification example, in the first corner portion 201, both edges of each FLR curve portion 42A are receded further inside the corresponding electrode curve portion 105A than the corresponding edges of the electrode curve portion 105A. That is, the width of each FLR curve portion 42A at every length direction position is narrower than the width of the corresponding electrode curve portion 105A at the corresponding length direction position.

In the first corner portion 201, a part of the wide portion 211 of the innermost electrode curve portion 105A is physically and electrically connected to the wide portion 221 of the corresponding FLR curve portion 42A via the FLR connection electrode 89 penetrating continuously through the interlayer insulating film 74 and the principal surface insulating film 45.

With reference to FIG. 30B, in the second corner portion 202, the second electrode curve portion 105A from the inner side among the four electrode curve portions 105A differs from the structure of the corresponding electrode curve portion of the basic electrode corner structure. The other three electrode curve portions 105A are the same in structure as the corresponding electrode curve portions of the basic electrode corner structure.

The center of curvature of the inner edges 105Aa and the outer edges 105Ab of the innermost electrode curve portion 105A, the third electrode curve portion 105A from the inner side, and the outermost electrode curve portion 105A is Q3. These electrode curve portions 105A have an equal width. The width of these electrode curve portions 105A is fixed regardless of the length direction position.

With the second electrode curve portion 105A from the inner side, the center of curvature of the inner edge 105Aa is Q4, the center of curvature of the outer edge 105Ab is Q3, and the curvature of the inner edge 105Aa and the curvature of the outer edge 105Ab differ. Specifically, the curvature of the inner edge 105Aa is smaller than the curvature of the outer edge 105Ab. In other words, the radius of curvature of the inner edge 105Aa is larger than the radius of curvature of the outer edge 105Ab.

The width of the second electrode curve portion 105A from the inner side differs according to the length direction position. Specifically, the width of the second electrode curve portion 105A from the inner side is widest at the length central portion and narrows as both ends are approached from the length central portion.

The second electrode curve portion 105A from the inner side has the wide portion 211 of larger width than the corresponding electrode curve portions 105A of the three corner portions 201, 203, and 204 other than the second corner portion 202. A length intermediate portion of the second electrode curve portion 105A from the inner side is the wide portion 211.

With this modification example, the curvature of the inner edge 105Aa of the second electrode curve portion 105A from the inner side is set such that the width at both ends of the electrode curve portion 105A coincides with the width of the electrode rectilinear portions 105B.

In the second corner portion 202, the second FLR curve portion 42A from the inner side among the four FLR curve portions 42A differs from the structure of the corresponding FLR curve portion of the basic FLR corner structure. The other three FLR curve portions 42A are the same in structure as the corresponding FLR curve portions of the basic FLR corner structure.

The center of curvature of the inner edges 42Aa and the outer edges 42Ab of the innermost FLR curve portion 42A, the third FLR curve portion 42A from the inner side, and the outermost FLR curve portion 42A is Q3. These FLR curve portions 42A have an equal width. The width of these FLR curve portions 42A is fixed regardless of the length direction position.

With the second FLR curve portion 42A from the inner side, the center of curvature of the inner edge 42Aa is Q4, the center of curvature of the outer edge 42Ab is Q3, and the curvature of the inner edge 42Aa and the curvature of the outer edge 42Ab differ. Specifically, the curvature of the inner edge 42Aa is smaller than the curvature of the outer edge 42Ab. In other words, the radius of curvature of the inner edge 42Aa is larger than the radius of curvature of the outer edge 42Ab.

The width of the second FLR curve portion 42A from the inner side differs according to the length direction position. Specifically, the width of the second FLR curve portion 42A from the inner side is widest at the length central portion and narrows as both ends are approached from the length central portion.

The second FLR curve portion 42A from the inner side has the wide portion 221 of larger width than the FLR curve portions 42A of the corresponding FLR curve portions 42A of the three corner portions 201, 203, and 204 other than the second corner portion 202. A length intermediate portion of the second FLR curve portion 42A from the inner side is the wide portion 221.

With this modification example, among the first diffusion region 301 and the second diffusion region 302 of the second FLR curve portion 42A from the inner side, the first diffusion region 301 is fixed in width in the length direction.

Also, with this modification example, the plan view shape of the boundary line BL between the first diffusion region 301 and the second diffusion region 302 of the second FLR curve portion 42A from the inner side is a circular arc having the same center of curvature as the center of curvature of the inner edge of the corresponding electrode curve portion 105A.

With this modification example, in the second corner portion 202, both edges of each FLR curve portion 42A are receded further inside the corresponding electrode curve portion 105A than the corresponding edges of the electrode curve portion 105A. That is, the width of each FLR curve portion 42A at every length direction position is narrower than the width of the corresponding electrode curve portion 105A at the corresponding length direction position.

In the second corner portion 202, a part of the wide portion 211 of the second electrode curve portion 105A from the inner side is physically and electrically connected to the wide portion 221 of the corresponding FLR curve portion 42A via the FLR connection electrode 89 penetrating continuously through the interlayer insulating film 74 and the principal surface insulating film 45.

With reference to FIG. 30C, in the third corner portion 203, the third electrode curve portion 105A from the inner side among the four electrode curve portions 105A differs from the structure of the corresponding electrode curve portion of the basic electrode corner structure. The other three electrode curve portions 105A are the same in structure as the corresponding electrode curve portions of the basic electrode corner structure.

The center of curvature of the inner edges 105Aa and the outer edges 105Ab of the innermost electrode curve portion 105A, the second electrode curve portion 105A from the inner side, and the outermost electrode curve portion 105A is Q5. These electrode curve portions 105A have an equal width. The width of these electrode curve portions 105A is fixed regardless of the length direction position.

With the third electrode curve portion 105A from the inner side, the center of curvature of the inner edge 105Aa is Q6, the center of curvature of the outer edge 105Ab is Q5, and the curvature of the inner edge 105Aa and the curvature of the outer edge 105Ab differ. Specifically, the curvature of the inner edge 105Aa is smaller than the curvature of the outer edge 105Ab. In other words, the radius of curvature of the inner edge 105Aa is larger than the radius of curvature of the outer edge 105Ab.

The width of the third electrode curve portion 105A from the inner side differs according to the length direction position. Specifically, the width of the third electrode curve portion 105A from the inner side is widest at the length central portion and narrows as both ends are approached from the length central portion.

The third electrode curve portion 105A from the inner side has the wide portion 211 of larger width than the corresponding electrode curve portions 105A of the three corner portions 201, 202, and 204 other than the third corner portion 203. A length intermediate portion of the third electrode curve portion 105A from the inner side is the wide portion 211.

With this modification example, the curvature of the inner edge 105Aa of the third electrode curve portion 105A from the inner side is set such that the width at both ends of the electrode curve portion 105A coincides with the width of the electrode rectilinear portions 105B.

In the third corner portion 203, the third FLR curve portion 42A from the inner side among the four FLR curve portions 42A differs from the structure of the corresponding FLR curve portion of the basic FLR corner structure. The other three FLR curve portions 42A are the same in structure as the corresponding FLR curve portions of the basic FLR corner structure.

The center of curvature of the inner edges 42Aa and the outer edges 42Ab of the innermost FLR curve portion 42A, the second FLR curve portion 42A from the inner side, and the outermost FLR curve portion 42A is Q5. These FLR curve portions 42A have an equal width. The width of these FLR curve portions 42A is fixed regardless of the length direction position.

With the third FLR curve portion 42A from the inner side, the center of curvature of the inner edge 42Aa is Q6, the center of curvature of the outer edge 42Ab is Q5, and the curvature of the inner edge 42Aa and the curvature of the outer edge 42Ab differ. Specifically, the curvature of the inner edge 42Aa is smaller than the curvature of the outer edge 42Ab. In other words, the radius of curvature of the inner edge 42Aa is larger than the radius of curvature of the outer edge 42Ab.

The width of the third FLR curve portion 42A from the inner side differs according to the length direction position. Specifically, the width of the third FLR curve portion 42A from the inner side is widest at the length central portion and narrows as both ends are approached from the length central portion.

The third FLR curve portion 42A from the inner side has the wide portion 221 of larger width than the FLR curve portions 42A of the corresponding FLR curve portions 42A of the three corner portions 201, 202, and 204 other than the third corner portion 203. A length intermediate portion of the third FLR curve portion 42A from the inner side is the wide portion 221.

With this modification example, among the first diffusion region 301 and the second diffusion region 302 of the third FLR curve portion 42A from the inner side, the first diffusion region 301 is fixed in width in the length direction.

Also, with this modification example, the plan view shape of the boundary line BL between the first diffusion region 301 and the second diffusion region 302 of the third FLR curve portion 42A from the inner side is a circular arc having the same center of curvature as the center of curvature of the inner edge of the corresponding electrode curve portion 105A.

With this modification example, in the third corner portion 203, both edges of each FLR curve portion 42A are receded further inside the corresponding electrode curve portion 105A than the corresponding edges of the electrode curve portion 105A. That is, the width of each FLR curve portion 42A at every length direction position is narrower than the width of the corresponding electrode curve portion 105A at the corresponding length direction position.

In the third corner portion 203, a part of the wide portion 211 of the third electrode curve portion 105A from the inner side is physically and electrically connected to the wide portion 221 of the corresponding FLR curve portion 42A via the FLR connection electrode 89 penetrating continuously through the interlayer insulating film 74 and the principal surface insulating film 45.

With reference to FIG. 30D, in the fourth corner portion 204, the outermost electrode curve portion 105A among the four electrode curve portions 105A differs from the structure of the corresponding electrode curve portion of the basic electrode corner structure. The other three electrode curve portions 105A are the same in structure as the corresponding electrode curve portions of the basic electrode corner structure.

The center of curvature of the inner edges 105Aa and the outer edges 105Ab of the innermost electrode curve portion 105A and the second and third electrode curve portions 105A from the inner side is Q7. These electrode curve portions 105A have an equal width. The width of these electrode curve portions 105A is fixed regardless of the length direction position.

With the outermost electrode curve portion 105A, the center of curvature of the inner edge 105Aa is Q8, the center of curvature of the outer edge 105Ab is Q7, and the curvature of the inner edge 105Aa and the curvature of the outer edge 105Ab differ. Specifically, the curvature of the inner edge 105Aa is smaller than the curvature of the outer edge 105Ab. In other words, the radius of curvature of the inner edge 105Aa is larger than the radius of curvature of the outer edge 105Ab.

The width of the outermost electrode curve portion 105A differs according to the length direction position. Specifically, the width of the outermost electrode curve portion 105A is widest at the length central portion and narrows as both ends are approached from the length central portion.

The outermost electrode curve portion 105A has the wide portion 211 of larger width than the corresponding electrode curve portions 105A of the three corner portions 201, 202, and 203 other than the fourth corner portion 204. A length intermediate portion of the outermost electrode curve portion 105A is the wide portion 211.

With this modification example, the curvature of the inner edge 105Aa of the outermost electrode curve portion 105A is set such that the width at both ends of the electrode curve portion 105A coincides with the width of the electrode rectilinear portions 105B.

In the fourth corner portion 204, just the outermost FLR curve portion 42A among the four FLR curve portions 42A differs from the structure of the corresponding FLR curve portion of the basic FLR corner structure. The other three FLR curve portions 42A are the same in structure as the corresponding FLR curve portions of the basic FLR corner structure.

The center of curvature of the inner edges 42Aa and the outer edges 42Ab of the innermost FLR curve portion 42A and the second and third FLR curve portions 42A from the inner side is Q7. These FLR curve portions 42A have an equal width. The width of these FLR curve portions 42A is fixed regardless of the length direction position.

With the outermost FLR curve portion 42A, the center of curvature of the inner edge 42Aa is Q8, the center of curvature of the outer edge 42Ab is Q7, and the curvature of the inner edge 42Aa and the curvature of the outer edge 42Ab differ. Specifically, the curvature of the inner edge 42Aa is smaller than the curvature of the outer edge 42Ab. In other words, the radius of curvature of the inner edge 42Aa is larger than the radius of curvature of the outer edge 42Ab.

The width of the outermost FLR curve portion 42A differs according to the length direction position. Specifically, the width of the outermost FLR curve portion 42A is widest at the length central portion and narrows as both ends are approached from the length central portion.

The outermost FLR curve portion 42A has the wide portion 221 of larger width than the FLR curve portions 42A of the corresponding FLR curve portions 42A of the three corner portions 201, 202, and 203 other than the fourth corner portion 204. A length intermediate portion of the outermost FLR curve portion 42A is the wide portion 221.

With this modification example, among the first diffusion region 301 and the second diffusion region 302 of the outermost FLR curve portion 42A, the first diffusion region 301 is fixed in width in the length direction.

Also, with this modification example, the plan view shape of the boundary line BL between the first diffusion region 301 and the second diffusion region 302 of the outermost FLR curve portion 42A is a circular arc having the same center of curvature as the center of curvature of the inner edge of the corresponding electrode curve portion 105A.

With this modification example, in the fourth corner portion 204, both edges of each FLR curve portion 42A are receded further inside the corresponding electrode curve portion 105A than the corresponding edges of the electrode curve portion 105A. That is, the width of each FLR curve portion 42A at every length direction position is narrower than the width of the corresponding electrode curve portion 105A at the corresponding length direction position.

In the fourth corner portion 204, a part of the wide portion 211 of the outermost electrode curve portion 105A is physically and electrically connected to the wide portion 221 of the corresponding FLR curve portion 42A via the FLR connection electrode 89 penetrating continuously through the interlayer insulating film 74 and the principal surface insulating film 45.

The plurality of FLR connection electrodes 89 each have a circular shape in plan view. The plurality of FLR connection electrodes 89 may each have a quadrangle shape or other polygonal shape in plan view or may have an elliptical shape in plan view instead. In this modification example, the plurality of FLR connection electrodes 89 are formed in an electrically floating state.

The inner edge 42Aa of each FLR curve portion 42A is the inner edge of the first diffusion region 301 of the FLR curve portion 42A. The outer edge 42Ab of each FLR curve portion 42A is the outer edge of the second diffusion region 302 of the FLR curve portion 42A. The diffusion region boundary line BL is formed in the width intermediate portion between the inner edge 42Aa and the outer edge 42Ab of the FLR curve portion 42A.

With this modification example, the diffusion region boundary line BL in each FLR curve portion 42A has the same center of curvature as the center of curvature of the inner edge 42Aa of the FLR curve portion 42A. Here, the diffusion region boundary line BL in each FLR curve portion 42A may have the same center of curvature as the center of curvature of the outer edge 42Ab of the FLR curve portion 42A instead.

With this modification example, in each of the corner portions 201 to 204, both edges of each of the plurality of FLR curve portions 42A are receded further inside the corresponding electrode curve portion 105A than the corresponding edges of the electrode curve portion 105A in plan view. Thus, with this modification example, the width of each FLR curve portion 42A is narrower than the width of the corresponding electrode rectilinear portions 105B.

Here, the inner edge 42Aa of each FLR curve portion 42A may instead be advanced further outside the corresponding electrode curve portion 105A than the inner edge 105Aa of the electrode curve portion 105A. Also, the outer edge 42Ab of each FLR curve portion 42A may be advanced further outside the corresponding electrode curve portion 105A than the outer edge 105Ab of the electrode curve portion 105A.

Just the inner edge 42Aa of each FLR curve portion 42A may be advanced further outside the corresponding electrode curve portion 105A than the inner edge 105Aa of the electrode curve portion 105A. In this case, just the inner edge of each FLR rectilinear portion 42B may be advanced further outside the corresponding electrode rectilinear portion 105B than the inner edge of the electrode rectilinear portion 105B.

Just the outer edge 42Ab of each FLR curve portion 42A may be advanced further outside the corresponding electrode curve portion 105A than the outer edge 105Ab of the electrode curve portion 105A. In this case, just the outer edge of each FLR rectilinear portion 42B may be advanced further outside the corresponding electrode rectilinear portion 105B than the outer edge of the electrode rectilinear portion 105B.

Both the inner edge 42Aa and the outer edge 42Ab of each FLR curve portion 42A may be advanced further outside the corresponding electrode curve portion 105A than the corresponding edges 105Aa and 105Ab of the electrode curve portion 105A. In this case, both the inner edge and outer edge of each FLR rectilinear portion 42B may be advanced further outside the corresponding electrode rectilinear portion 105B than the corresponding inner edge and outer edge of the electrode rectilinear portion 105B.

Also, although in each of the corner portions 201 to 204 in FIG. 30A to 30D, the electrode curve portion 105A connected to the FLR 42 via the FLR connection electrode 89 is arranged such that the curvature of the inner edge 105Aa thereof is smaller than the curvature of the outer edge 105Ab thereof, the curvature of the inner edge 105Aa may instead be made larger than the curvature of the outer edge 105Ab. In this case, the width of the electrode curve portion 105A connected to the FLR 42 via the FLR connection electrode 89 increases toward both ends from the length central portion thereof.

In this case, the electrode curve portion 105A connected to the FLR 42 via the FLR connection electrode 89 may have the wide portions 211 at both end portions thereof. In this case, a part of at least one of either of the wide portions 211 at both end portions of the electrode curve portion 105A suffices to be connected to the FLR 42 via the FLR connection electrode 89.

With this modification example, even when, for example, the width of each electrode rectilinear portion 105B of each FLR electrode 105 is narrower than the width required to connect the electrode rectilinear portion 105B to the FLR 42 by an FLR connection electrode 89, a region for connecting to the FLR 42 by an FLR connection electrode 89 can easily be secured in an electrode curve portion 105A.

In other words, the width of each electrode rectilinear portion 105B of each FLR electrode 105 can be made narrower than the width for connecting the electrode rectilinear portion 105B to the FLR 42 by an FLR connection electrode 89. An overall width of the plurality of FLR electrodes 105 can thereby be made narrow and therefore, miniaturization of the chip can be achieved.

With the structures shown in FIG. 30A to FIG. 30D and FIG. 31, the above-described four pairs constituted of respective combinations of an FLR 42 and the corresponding FLR electrode 105 satisfy the following first condition and second condition.

The first condition is the condition that, in the four corner portions 201 to 204, the pair in which the electrode curve portion 105A is connected to the FLR 42 via the FLR connection electrode 89 differs according to each of the four corner portions 201 to 204.

The second condition is the condition that, in each of the corner portions 201 to 204, the one electrode curve portion 105A connected to the FLR curve portion 42A via the FLR connection electrode 89 has the wide portion 211 of larger width than the electrode curve portions 105A of the three corners other than the corner and a part of the wide portion 211 is physically and electrically connected to the corresponding FLR 42 via the FLR connection electrode 89.

The above-described four pairs further satisfy a third condition that, in each of the corner portions 201 to 204, the one electrode curve portion 105A connected to the FLR 42 via the FLR connection electrode 89 has the inner edge 105Aa and the outer edge 105Ab differing in the centers of curvature thereof and the curvatures thereof.

The above-described four pairs further satisfy a fourth condition that, in each of the corner portions 201 to 204, the center of curvature of the inner edge 105Aa and the center of curvature of the outer edge 105Ab of the one electrode curve portion 105A connected to the FLR 42 via the FLR connection electrode 89 are present at different positions on the dividing line L0 that is the straight line dividing the apex angle of the corner portion in ½ and the radius of curvature of the inner edge 105Aa and the radius of curvature of the outer edge 105Ab differ.

The above-described four pairs further satisfy a fifth condition that, in each of the corner portions 201 to 204, the one FLR curve portion 42A that is connected to the electrode curve portion 105A via the FLR connection electrode 89 has the inner edge 42Aa and the outer edge 42Ab that differ in the centers of curvature thereof and the curvatures thereof.

The above-described four pairs further satisfy a sixth condition that, in each of the corner portions 201 to 204, the center of curvature of the inner edge 42Aa and the center of curvature of the outer edge 42Ab of the one FLR curve portion 42A connected to the electrode curve portion 105A via the FLR connection electrode 89 are present at different positions on the dividing line L0 that is the straight line dividing the apex angle of the corner portion in ½ and the radius of curvature of the inner edge 42Aa and the radius of curvature of the outer edge 42Ab differ.

The semiconductor device 1A suffices to have four pairs, each constituted of an FLR 42 and an FLR electrode 105, that satisfy the first condition and the second condition described above. Also, these four pairs may further satisfy the third condition. Also, these four pairs may further satisfy the fourth condition. Also, these four pairs may further satisfy the fifth condition. Also, these four pairs may further satisfy the sixth condition.

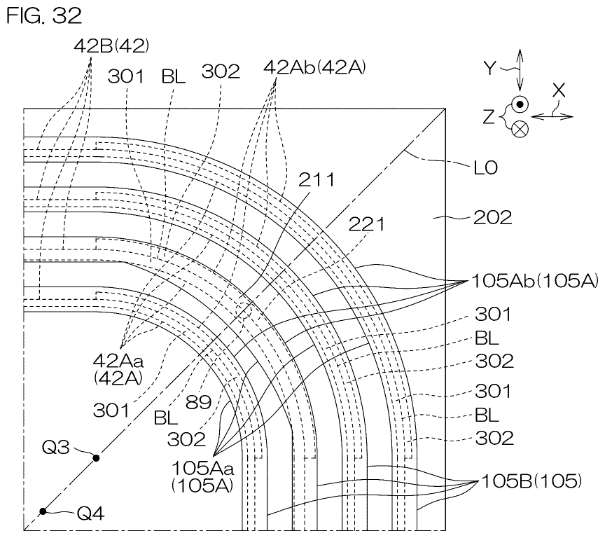

Also, as shown in FIG. 32, in each of the corner portions 201 to 204, the FLR curve portion 42A that is connected to the electrode curve portion 105A via the FLR connection electrode 89 may differ in shape from the electrode curve portion 105A. FIG. 32 is an illustrative plan view showing the structures of the FLRs 42, the FLR electrodes 105, and the FLR connection electrode 89 in the second corner portion 202. In FIG. 32, the plan view shapes of the plurality of electrode curve portions 105A are the same as the plan view shapes in FIG. 30B.

Specifically, in FIG. 32, the inner edge 42Aa, the outer edge 42Ab, and the diffusion region boundary line BL of the second FLR curve portion 42A from the inner side have the same center of curvature. Specifically, in the second corner portion 202, the center of curvature of these is Q3.

That is, the inner edge 42Aa, the outer edge 42Ab, and the diffusion region boundary line BL of the FLR curve portion 42A connected to the corresponding electrode curve portion 105A via the FLR connection electrode 89 have the same center of curvature as the center of curvature of the inner edge 105Aa of the electrode curve portion 105A. The same applies to the other corner portions 201, 203, and 204.

Here, in each of the corner portions 201 to 204, the inner edge 42Aa, the outer edge 42Ab, and the diffusion region boundary line BL of the FLR curve portion 42A connected to the corresponding electrode curve portion 105A via the FLR connection electrode 89 may instead have same center of curvature as the center of curvature of the outer edge 105Ab of the electrode curve portion 105A.

In FIG. 32, with the FLR curve portion 42A connected to the electrode curve portion 105A via the FLR connection electrode 89, the width of the first diffusion region 301 is fixed in the length direction and the width of the second diffusion region 302 is fixed in the length direction.

Also, in FIG. 32, the inner edge 42Aa and the outer edge 42Ab of the FLR curve portion 42A connected to the corresponding electrode curve portion 105A via the FLR connection electrode 89 have the same center of curvature as the center of curvature of the outer edge 105Ab of the corresponding electrode curve portion 105A.

Although the preferred embodiment and modification examples of the present disclosure have been described above, the present disclosure can be implemented in yet other embodiments. For example, in the embodiment described above, an example in which the chip 2 is constituted of a silicon monocrystal substrate was described. However, the chip 2 may be constituted of an SiC (silicon carbide) monocrystal substrate instead.

In the embodiment described above, the semiconductor regions of the n-type may be replaced with semiconductor regions of the p-type, and the semiconductor regions of the p-type may be replaced with semiconductor regions of the n-type. A specific arrangement in this case can be obtained by replacing the “n-type” with the “p-type” at the same time as replacing the “p-type” with the “n-type” in the above descriptions and accompanying drawings.

In the above embodiment, the collector region 14 of the p-type was described. However, a drain region of the n-type may be adopted instead of the collector region 14 of the p-type. In this case, the buffer region 13 is omitted. The drain region of the n-type may be formed by a semiconductor substrate of the n-type, and the drift region 12 of the n-type may be formed by an epitaxial layer of the n-type. The n-type impurity concentration of the drift region 12 is preferably less than the n-type impurity concentration of the drain region.

In this case, a MISFET (metal insulator semiconductor field effect transistor) structure is formed instead of the IGBT. A specific arrangement in this case can be obtained by replacing “emitter” with “source” and “collector” with “drain” in the above description.

In each embodiment described above, the first direction X and the second direction Y were defined by the extending directions of the first to fourth side surfaces 5A to 5D. However, the first direction X and the second direction Y may be arbitrary directions as long as the directions maintain an intersecting (specifically, orthogonal) relationship with each other. For example, the first direction X may be an extending direction of the third side surface 5C (the fourth side surface 5D), and the second direction Y may be an extending direction of the first side surface 5A (the second side surface 5B). Also, the first direction X may be a direction intersecting the first to fourth side surfaces 5A to 5D, and the second direction Y may be a direction intersecting the first to fourth side surfaces 5A to 5D.

Examples of features extracted from the present Description and the attached drawings shall be indicated below. Hereinafter, the alphanumeric characters, etc., in parentheses represent the corresponding components, etc., in the embodiment described above, but are not intended to limit the scope of each clause to the embodiment. The “semiconductor device” according to the following clauses may be replaced with a “semiconductor switching device,” an “IGBT semiconductor device,” an “RC-IGBT semiconductor device,” or a “MISFET semiconductor device.”
[A1] A semiconductor device including a chip (2) that has a first principal surface (3) and a second principal surface (4) at an opposite side thereto of quadrangle plan view shapes,
an active region (6) that is provided in the first principal surface (3) and has an element structure formed therein,
an outer peripheral region (9) that is a region outside the active region (6), is provided in an outer peripheral portion of the first principal surface (3), and has four corner portions (201 to 204),
a drift region of a first conductivity type that is formed in an interior of the chip (2), and
a plurality of field limiting rings (referred to hereinafter as “FLRs (42)”) of a second conductivity type that are formed in a surface layer portion of the first principal surface (3) in the outer peripheral region (9) such as to surround the active region (6), and
where each of the FLRs (42) has FLR curve portions (42A), each being of a curve shape in plan view shape, in the four corner portions (201 to 204),
each of the FLRs (42) has FLR rectilinear portions (42B), each being of a rectilinear shape in plan view shape, between the four corner portions (201 to 204), and
each of the FLR curve portions (42A) has a double-diffused structure including a first diffusion region (301) at an inner side and a second diffusion region (302) at an outer side that is lower in impurity concentration of the second conductivity type than the first diffusion region (301).
[A2] The semiconductor device according to [A1], where each of the FLR rectilinear portions (42B) has a single-diffused structure constituted of just a diffusion region having the same impurity concentration of the second conductivity type as the first diffusion region (301).
[A3] The semiconductor device according to [A1] or [A2], where, in each of the corner portions (201 to 204), each of the FLR curve portions (42A) has an inner edge (42Aa) and an outer edge (42Ab) that are circular arcs in plan view shape and,
in each of the corner portions (201 to 204), the first diffusion region (301) and the second diffusion region (302) in each of the FLR curve portions (42A) each have an inner edge that is a circular arc in plan view shape and an outer edge that is a circular arc in plan view shape.
[A4] The semiconductor device according to [A3], where, in each of the corner portions (201 to 204), the inner edge and the outer edge of the first diffusion region (301) and the inner edge and the outer edge of the second diffusion region (302) in each of the FLR curve portions (42A) have the same center of curvature.
[A5] The semiconductor device according to [A4], where, in each of the corner portions (201 to 204), the center of curvature of the inner edge and the outer edge of the first diffusion region (301) and the inner edge and the outer edge of the second diffusion region (302) in each of the FLR curve portions (42A) is present at a position on a dividing line (L0) that is a straight line dividing an apex angle of the corner portion in ½.
[A6] The semiconductor device according to [A5], where, in each of the corner portions (201 to 204), each of the FLR curve portions (42A) has the same width, a width of the first diffusion region (301) inside each of the FLR curve portions (42A) is fixed in a length direction thereof, and a width of the second diffusion region (302) inside each of the FLR curve portions (42A) is fixed in a length direction thereof.
[A7] The semiconductor device according to [A1] or [A2], including an insulating film (45, 74) that is formed on the first principal surface (3) and covers the plurality of FLRs (42) and
a plurality of FL electrodes (105) that are disposed to respectively face the plurality of FLRs (42) with the insulating film (45, 74) interposed therebetween and are each physically and electrically connected to the corresponding FLR (42) via an FLR connection electrode (89) penetrating through the insulating film (45, 74) and
where each of the FLR electrodes (105) has, in each of the corner portions (201 to 204), an electrode curve portion (105A) with an inner edge and an outer edge thereof being circular arcs in plan view shape, and
in each of the corner portions (201 to 204), centers of curvature of the inner edge (105Aa) and the outer edge (105Ab) of each of the electrode curve portions (105A) are present at positions on a dividing line (L0) that is a straight line dividing an apex angle of the corner portion in ½, and
in at least one corner portion (201 to 204) among the at least four corner portions (201 to 204), the plurality of electrode curve portions (105A) include at least one first electrode curve portion (105A) having the inner edge (105Aa) and the outer edge (105Ab) that differ in the centers of curvature thereof and the curvatures thereof.
[A8] The semiconductor device according to [A7], where the first electrode curve portion (105A) has a region of large width and a region of narrow width between the inner edge (105Aa) and the outer edge (105Ab) thereof and
a part of the region of large width in the first electrode curve portion (105A) is connected to the corresponding FLR (42) via the FLR connection electrode (89) penetrating through the insulating film (45, 74).
[A9] The semiconductor device according to [A8], where the inner edge (42Aa) of the FLR curve portion (42A) corresponding to the first electrode curve portion (105A) has the same center of curvature as the center of curvature of the inner edge (105Aa) of the first electrode curve portion (105A) and
the outer edge (42Ab) of the FLR curve portion (42A) corresponding to the first electrode curve portion (105A) has the same center of curvature as the center of curvature of the outer edge (105Ab) of the first electrode curve portion (105A).
[A10] The semiconductor device according to [A9], where a width of one of either of the first diffusion region (301) and the second diffusion region (302) of the FLR curve portion (42A) corresponding to the first electrode curve portion (105A) is fixed in a length direction.
[A11] The semiconductor device according to [A10], where a plan view shape of a boundary line (BL) between the first diffusion region (301) and the second diffusion region (302) of the FLR curve portion (42A) corresponding to the first electrode curve portion (105A) is a circular arc having the same center of curvature as the center of curvature of the inner edge (105Aa) of the first electrode curve portion (105A).
[A12] The semiconductor device according to [A7], where a width of the first diffusion region (301) of the FLR curve portion (42A) corresponding to the first electrode curve portion (105A) is fixed in a length direction and
a width of the second diffusion region (302) of the FLR curve portion (42A) corresponding to the first electrode curve portion (105A) is fixed in a length direction.
[A13] The semiconductor device according to [A12], where the inner edge (42Aa) and the outer edge (42Ab) of the FLR curve portion (42A) corresponding to the first electrode curve portion (105A) has the same center of curvature as the center of curvature of the inner edge (105Aa) of the first electrode curve portion (105A) or has the same center of curvature as the center of curvature of the outer edge of the first electrode curve portion (105A).
[A14] The semiconductor device according to [A13], where a plan view shape of a boundary line (BL) between the first diffusion region (301) and the second diffusion region (302) of the FLR curve portion (42A) corresponding to the first electrode curve portion (105A) is a circular arc having the same center of curvature as the center of curvature of the inner edge (105Aa) of the first electrode curve portion (105A) or is a circular arc having the same center of curvature as the center of curvature of the outer edge of the first electrode curve portion (105A).
[A15] The semiconductor device according to any one of [A7] to [A14], where the FLR connection electrode (89) for electrically connecting the first electrode curve portion (105A) to the corresponding FLR (42) is formed integrally with the first electrode curve portion (105A).
[A16] The semiconductor device according to any one of [A1] to [A15], including a channel stop region (43) that is formed in a surface layer portion of the first principal surface (3) in the outer peripheral region (9) such as to surround the plurality of FLRs (42) and is covered by the insulating film (45, 74) and
a channel stop electrode (106) that is formed on the insulating film (45, 74) in the outer peripheral region (9) such as to cover a part of the channel stop region (43) and is electrically connected to the channel stop region (43).
[A17] The semiconductor device according to any one of [A1] to [A16], where the element structure includes an IGBT structure.
[A18] The semiconductor device according to any one of [A1] to [A17], including a channel region (20) of the second conductivity type that is formed in a surface layer portion of the first principal surface (3) in the active region,
an emitter region (29) of the first conductivity type that is formed in a surface layer portion of the channel region (20) and is higher in first conductivity type impurity concentration than the drift region (12), and
a trench gate structure (21) that, in the active region (6), passes through the emitter region (29) and the channel region (20) and reaches the drift region (12).
[A19] The semiconductor device according to [A18], where a conductivity type of the FLRs (42) is the second conductivity type.

While the preferred embodiment was described in detail above, this is merely a specific example used to clarify the technical contents and the present disclosure should not be interpreted as being limited to this specific example and the scope of the present disclosure is limited only by the appended claims.

What is claimed is:

1. A semiconductor device comprising:
a chip that has a first principal surface and a second principal surface at an opposite side thereto of quadrangle plan view shapes;
an active region that is provided in the first principal surface and has an element structure formed therein;
an outer peripheral region that is a region outside the active region, is provided in an outer peripheral portion of the first principal surface, and has four corner portions;
a drift region of a first conductivity type that is formed in an interior of the chip; and
a plurality of field limiting rings (referred to hereinafter as “FLRs”) of a second conductivity type that are formed in a surface layer portion of the first principal surface in the outer peripheral region such as to surround the active region; and
wherein each of the FLRs has FLR curve portions, each being of a curve shape in plan view shape, in the four corner portions,
each of the FLRs has FLR rectilinear portions, each being of a rectilinear shape in plan view shape, between the four corner portions, and
each of the FLR curve portions has a double-diffused structure including a first diffusion region at an inner side and a second diffusion region at an outer side that is lower in impurity concentration of the second conductivity type than the first diffusion region.

2. The semiconductor device according to claim 1, wherein each of the FLR rectilinear portions has a single-diffused structure constituted of just a diffusion region having the same impurity concentration of the second conductivity type as the first diffusion region.

3. The semiconductor device according to claim 1, wherein, in each of the corner portions, each of the FLR curve portions has an inner edge and an outer edge that are circular arcs in plan view shape and,
in each of the corner portions, the first diffusion region and the second diffusion region in each of the FLR curve portions each have an inner edge that is a circular arc in plan view shape and an outer edge that is a circular arc in plan view shape.

4. The semiconductor device according to claim 3, wherein, in each of the corner portions, the inner edge and the outer edge of the first diffusion region and the inner edge and the outer edge of the second diffusion region in each of the FLR curve portions have the same center of curvature.

5. The semiconductor device according to claim 4, wherein, in each of the corner portions, the center of curvature of the inner edge and the outer edge of the first diffusion region and the inner edge and the outer edge of the second diffusion region in each of the FLR curve portions is present at a position on a dividing line that is a straight line dividing an apex angle of the corner portion in ½.

6. The semiconductor device according to claim 5, wherein, in each of the corner portions, each of the FLR curve portions has the same width, a width of the first diffusion region inside each of the FLR curve portions is fixed in a length direction thereof, and a width of the second diffusion region inside each of the FLR curve portions is fixed in a length direction thereof.

7. The semiconductor device according to claim 1, comprising: an insulating film that is formed on the first principal surface and covers the plurality of FLRs; and
a plurality of FLR electrodes that are disposed to respectively face the plurality of FLRs with the insulating film interposed therebetween and are each physically and electrically connected to the corresponding FLR via an FLR connection electrode penetrating through the insulating film; and
wherein each of the FLR electrodes has, in each of the corner portions, an electrode curve portion with an inner edge and an outer edge thereof being circular arcs in plan view shape, and
in each of the corner portions, centers of curvature of the inner edge and the outer edge of each of the electrode curve portions are present at positions on a dividing line that is a straight line dividing an apex angle of the corner portion in ½, and
in at least one corner portion among the at least four corner portions, the plurality of electrode curve portions include at least one first electrode curve portion having the inner edge and the outer edge that differ in the centers of curvature thereof and the curvatures thereof.

8. The semiconductor device according to claim 7, wherein the first electrode curve portion has a region of large width and a region of narrow width between the inner edge and the outer edge thereof and
a part of the region of large width in the first electrode curve portion is connected to the corresponding FLR via the FLR connection electrode penetrating through the insulating film.

9. The semiconductor device according to claim 8, wherein the inner edge of the FLR curve portion corresponding to the first electrode curve portion has the same center of curvature as the center of curvature of the inner edge of the first electrode curve portion and
the outer edge of the FLR curve portion corresponding to the first electrode curve portion has the same center of curvature as the center of curvature of the outer edge of the first electrode curve portion.

10. The semiconductor device according to claim 9, wherein a width of one of either of the first diffusion region and the second diffusion region of the FLR curve portion corresponding to the first electrode curve portion is fixed in a length direction.

11. The semiconductor device according to claim 10, wherein a plan view shape of a boundary line between the first diffusion region and the second diffusion region of the FLR curve portion corresponding to the first electrode curve portion is a circular arc having the same center of curvature as the center of curvature of the inner edge of the first electrode curve portion.

12. The semiconductor device according to claim 7, wherein a width of the first diffusion region of the FLR curve portion corresponding to the first electrode curve portion is fixed in a length direction and
a width of the second diffusion region of the FLR curve portion corresponding to the first electrode curve portion is fixed in a length direction.

13. The semiconductor device according to claim 12, wherein the inner edge and the outer edge of the FLR curve portion corresponding to the first electrode curve portion has the same center of curvature as the center of curvature of the inner edge of the first electrode curve portion or has the same center of curvature as the center of curvature of the outer edge of the first electrode curve portion.

14. The semiconductor device according to claim 13, wherein a plan view shape of a boundary line between the first diffusion region and the second diffusion region of the FLR curve portion corresponding to the first electrode curve portion is a circular arc having the same center of curvature as the center of curvature of the inner edge of the first electrode curve portion or is a circular arc having the same center of curvature as the center of curvature of the outer edge of the first electrode curve portion.

15. The semiconductor device according to claim 7, wherein the FLR connection electrode for electrically connecting the first electrode curve portion to the corresponding FLR is formed integrally with the first electrode curve portion.

16. The semiconductor device according to claim 1, comprising: a channel stop region that is formed in a surface layer portion of the first principal surface in the outer peripheral region such as to surround the plurality of FLRs and is covered by the insulating film and
a channel stop electrode that is formed on the insulating film in the outer peripheral region such as to cover a part of the channel stop region and is electrically connected to the channel stop region.

17. The semiconductor device according to claim 1, wherein the element structure includes an IGBT structure.

18. The semiconductor device according to claim 1, comprising: a channel region of the second conductivity type that is formed in a surface layer portion of the first principal surface in the active region;
an emitter region of the first conductivity type that is formed in a surface layer portion of the channel region and is higher in first conductivity type impurity concentration than the drift region; and
a trench gate structure that, in the active region, passes through the emitter region and the channel region and reaches the drift region.

19. The semiconductor device according to claim 18, wherein a conductivity type of the FLRs is the second conductivity type.
